(19) United States
(12) Patent Application Publication
(10) Pub. No.: US 2025/0089384 A1
(43) Pub. Date: Mar. 13, 2025

(54) SENSOR

(71) Applicant: SONY SEMICONDUCTOR SOLUTIONS CORPORATION, KANAGAWA (JP)

(72) Inventor: NOBUO NAKAMURA, KANAGAWA (JP)

(21) Appl. No.: 18/248,628

(22) PCT Filed: Oct. 6, 2021
(86) PCT No.: PCT/JP2021/036932

§ 371 Date: Apr. 11, 2023

(30) Foreign Application Priority Data
Oct. 19, 2020 (JP) 2020-175243

(51) Int. Cl. H01L 27/148

(52) U.S. Cl. CPC H10F 39/1538

(57) ABSTRACT

A sensor that can reduce kTC noise and can be miniaturized is provided. A sensor according to the present embodiment is a sensor including a plurality of pixels, in which each of the pixels includes a semiconductor layer of a first conductivity type having a first surface, a photoelectric conversion section that is provided in the semiconductor layer and converts light incident on the semiconductor layer into a charge, a first channel layer of the first conductivity type that is provided on a side of the first surface in the semiconductor layer, a first gate electrode provided above the first channel layer, and a first capacitor layer of a second conductivity type that is provided below the first channel layer and accumulates the charge.

### TECHNICAL FIELD

The present disclosure relates to a sensor.

### BACKGROUND ART

A distance measuring device using an indirect time of flight (iToF) method has been developed. The distance measuring device of the iToF method indirectly calculates the distance from the distance measuring device to a target on the basis of a phase difference between irradiation light and reflected light.

### CITATION LIST

### Patent Document

Patent Document 1: Japanese Patent Application Laid-Open No. 2019-004149

### SUMMARY OF THE INVENTION

### Problems to be Solved by the Invention

Such an iToF sensor may include a memory element that accumulates signal charges inside a pixel in order to reduce noise of signal charges. However, in a case where such a memory element is used, the number of elements constituting each pixel increases, and the pixel cannot be miniaturized.

On the other hand, in a case where the memory element is deleted from the pixel and the signal charge is accumulated in a floating diffusion, the iToF sensor reads a reset state after reading a signal state. In this case, correlated double sampling (CDS) cannot be performed. In addition, in a case where the floating diffusion is used, large kTC noise (random noise) is generated, and distance measurement accuracy is deteriorated.

Accordingly, the present disclosure has been made in view of such a problem, and provides a sensor that can reduce kTC noise and can be miniaturized.

### Solutions to Problems

A sensor according to one aspect of the present disclosure is a sensor including a plurality of pixels, in which each of the pixels includes a semiconductor layer of a first conductivity type having a first surface, a photoelectric conversion section that is provided in the semiconductor layer and converts light incident on the semiconductor layer into a charge, a first channel layer of the first conductivity type that is provided on a side of the first surface in the semiconductor layer, a first gate electrode provided above the first channel layer, and a first capacitor layer of a second conductivity type that is provided below the first channel layer and accumulates the charge.

The pixel may further include a second channel layer of the first conductivity type that is provided on the side of the first surface in the semiconductor layer, a second gate electrode provided above the second channel layer, and a second capacitor layer of the second conductivity type that is provided below the second channel layer and accumulates the charge.

The pixel may further include a first amplification transistor that includes the first channel layer and the first gate electrode and is electrically connected to a first signal line, and a threshold value of the first amplification transistor is modulated by an amount of the charge accumulated in the first capacitor layer.

The pixel may further include a second amplification transistor that includes the second channel layer and the second gate electrode and is electrically connected to a second signal line, and a threshold value of the second amplification transistor is modulated by an amount of the charge accumulated in the second capacitor layer.

The pixel may further include a first power supply diffusion layer of a second conductivity type provided on the side of the first surface in the semiconductor layer and connected to a power supply.

The pixel may further include a second power supply diffusion layer of a second conductivity type provided on the side of the first surface in the semiconductor layer and connected to the power supply.

The pixel may further include a charge discharge transistor that discharges a charge of the photoelectric conversion section.

The pixel may further include a first comparator connected to the first signal line, a first current circuit that causes a current to flow through the first comparator, a second comparator connected to the second signal line, and a second current circuit that causes a current to flow through the second comparator.

The pixel may further include a first capacitive element that is connected to one end of the first amplification transistor and accumulates a charge from the first amplification transistor, a first source follower circuit that is connected between the first capacitive element and the first signal line and transmits a voltage corresponding to a charge of the first capacitive element to the first signal line, a second capacitive element that is connected to one end of the second amplification transistor and accumulates a charge from the second amplification transistor, and a second source follower circuit that is connected between the second capacitive element and the second signal line and transmits a voltage corresponding to a charge of the second capacitive element to the second signal line.

The first and second capacitor layers may be arranged on one side and another side of the photoelectric conversion section, respectively, in plan view as viewed from an incident direction of light to the semiconductor layer, and the first and second amplification transistors may also be arranged on the one side and the another side of the photoelectric conversion section, respectively.

The light may be incident from a second surface of the semiconductor layer opposite to the first surface.

The sensor may include a light shielding film that is provided so as to overlap the first and second capacitor layers and does not overlap the photoelectric conversion section in plan view as viewed from an incident direction of light to the semiconductor layer.

The sensor may include a reflecting portion that is provided so as to overlap the first and second capacitor layers in plan view as viewed from an incident direction of light to the semiconductor layer and reflects light to the photoelectric conversion section.

The pixel may include a first transfer transistor that transfers a charge from the photoelectric conversion section to the first capacitor layer, and a second transfer transistor that transfers the charge from the photoelectric conversion section to the second capacitor layer.

The pixel may further include a first selection transistor connected between the first amplification transistor and the first signal line, and a second selection transistor connected between the second amplification transistor and the second signal line.

The pixel may further include a first reset transistor provided between the first capacitor layer and the first power supply diffusion layer, and a second reset transistor provided between the second capacitor layer and the second power supply diffusion layer.

The sensor may include a first semiconductor chip including the plurality of pixels, and a second semiconductor chip including a first comparator connected to the first signal line, a first current circuit that causes a current to flow through the first comparator, a second comparator connected to the second signal line, and a second current circuit that causes a current to flow through the second comparator, in which the first semiconductor chip and the second semiconductor chip may be bonded together.

The first and second semiconductor chips may be electrically connected by joining the respective first signal lines of the first and second semiconductor chips and joining the respective second signal lines of the first and second semiconductor chips.

The plurality of pixels may include a distance measuring pixel that measures a distance to a target by an imaging pixel that acquires an image of the target.

The pixel may transmit a signal voltage corresponding to a signal state in which signal charges are accumulated in the first and second capacitor layers to the first and second signal lines, and thereafter transmit a reset voltage corresponding to a reset state of the first and second capacitor layers from which the signal charges have been discharged to the first and second signal lines, and the signal voltage and the reset voltage may be subjected to correlated double sampling processing.

The pixel may further include a first floating diffusion region of a second conductivity type that is provided on the side of the first surface in the semiconductor layer and accumulates a charge from the first capacitor layer, and a second floating diffusion region of a second conductivity type that is provided on the side of the first surface in the semiconductor layer and accumulates a charge from the second capacitor layer, and the sensor may further include a first signal line that transmits a signal corresponding to the accumulated charge of the first capacitor layer, a second signal line that transmits a signal corresponding to the accumulated charge of the second capacitor layer, a third signal line that transmits a signal corresponding to the accumulated charge of the first floating diffusion region, and a fourth signal line that transmits a signal corresponding to the accumulated charge of the second floating diffusion region.

The first floating diffusion region may accumulate a charge having overflowed from the first capacitor layer, and the second floating diffusion region may accumulate a charge having overflowed from the second capacitor layer.

The first and second capacitor layers may accumulate charges from the photoelectric conversion section distributed at a first frequency, and then transfer the charges to the first and second floating diffusion regions, respectively, and thereafter, the first and second capacitor layers may accumulate charges from the photoelectric conversion section distributed at a second frequency.

A sensor according to another aspect of the present disclosure is a sensor including a plurality of pixels, in which each of the pixels includes a photoelectric conversion section that converts incident light into a charge, a first and a second distribution transistor that alternately distribute charges from the photoelectric conversion section and a first and a second memory section that accumulate charges distributed by the first and the second distribution transistor, respectively, and a third and a fourth memory section that accumulate charges from the first and the second memory section, respectively.

The sensor may further include a first floating diffusion region that individually or collectively accumulates the charges of the first and second memory sections, a second floating diffusion region that individually or collectively accumulates the charges of the third and fourth memory sections, a first amplification transistor that outputs a voltage corresponding to a charge of the first floating diffusion region to a first signal line, and a second amplification transistor that outputs a voltage corresponding to a charge of the second floating diffusion region to a second signal line.

The sensor may further include a common floating diffusion region that individually or collectively accumulates the charges of the first and second memory sections and individually or collectively accumulates the charges of the third and fourth memory sections, and a common amplification transistor that outputs a voltage corresponding to a charge of the floating diffusion region to a signal line.

The first and second memory sections may be connected in series between the first distribution transistor and the first amplification transistor, and the third and fourth memory sections may be connected in series between the second distribution transistor and the second amplification transistor. The first and second memory sections may be connected in parallel, and the third and fourth memory sections may be connected in parallel.

The first and second memory sections may transfer charges by CCD, and the third and fourth memory sections transfer charges by CCD.

The sensor may further include a first floating diffusion region of a second conductivity type that is provided on the side of the first surface in the semiconductor layer and accumulates charges from the first capacitor layer, a first signal line that transmits a signal corresponding to the accumulated charge of the first capacitor layer, and a third signal line that transmits a signal corresponding to the accumulated charge of the first floating diffusion region.

The sensor may further include a source follower circuit provided between the first floating diffusion region and the third signal line.

The pixel may further include a first transfer transistor that transfers a charge from the photoelectric conversion section to the first capacitor layer.

The pixel may further include a first selection transistor connected between the first amplification transistor and the first signal line.

The pixel may further include a first reset transistor provided between the first capacitor layer and the first floating diffusion region, and a second reset transistor provided between the first floating diffusion region and a power supply.

The pixel may further include a first transfer transistor connected between the photoelectric conversion section and the first floating diffusion region, and an overflow transistor and a second transfer transistor connected in series between the photoelectric conversion section and the first floating diffusion region, and a third capacitive element connected between a node between the overflow transistor and the second transfer transistor and a reference power supply.

The pixel may further include a first transfer transistor connected between the photoelectric conversion section and the first floating diffusion region, and an overflow transistor and a second transfer transistor provided between the photoelectric conversion section and the first floating diffusion region, and a CCD element provided between the overflow transistor and the second transfer transistor.

A sensor according to another aspect of the present disclosure is a sensor including a plurality of pixels, in which each of the pixels includes a photoelectric conversion section that converts incident light into a charge, a first capacitor layer that accumulates a charge from the photoelectric conversion section, a first charge transistor that is provided above the first capacitor layer and accumulates charges from the photoelectric conversion section to the first capacitor layer, a first floating diffusion region that accumulates a charge from the first capacitor layer, and a first transfer transistor provided between the first floating diffusion region and the first charge transistor.

The sensor may further include a second capacitor layer that is provided between the first charge transistor and the first transfer transistor and accumulates a charge from the first capacitor layer, and a second charge transistor that is provided above the second capacitor layer and sends a charge from the first capacitor layer to the second capacitor layer.

The sensor may further include a second transfer transistor provided between the photoelectric conversion section and the first charge transistor.

The plurality of pixels may be arranged in such a manner that the photoelectric conversion section is unevenly distributed to a center side of a pixel region.

A sensor according to another aspect of the present disclosure is a sensor that converts incident light into a charge and acquires an image according to the charge, the sensor including a photoelectric conversion section that accumulates a charge generated in a part of shutter periods among a plurality of shutter periods obtained by dividing an imaging period of one frame constituting the image, and a signal processing section that estimates a signal of the entire frame from a charge in the part of the shutter period.

The signal processing section may estimate that there is a signal of the entire frame on a substantially linear extension line from a signal corresponding to a charge in the part of the shutter periods.

A sensor according to another aspect of the present disclosure is a sensor that converts incident light into a charge and acquires an image according to the charge, the sensor including a photoelectric conversion section that accumulates charges generated in imaging periods of a plurality of frames constituting the image, and a signal processing section that estimates a signal of a first frame of the plurality of frames from charges of the plurality of frames.

The signal processing section may estimate an average value of signals corresponding to charges in the periods of the plurality of frames as the signal of the first frame.

### BRIEF DESCRIPTION OF DRAWINGS

FIG. 1 is a block diagram illustrating a configuration example of a distance measuring device according to a first embodiment.

FIG. 2 is a block diagram illustrating a schematic configuration example of a light receiving element of the distance measuring device according to the first embodiment.

FIG. 3 is an equivalent circuit diagram illustrating an example of a configuration of a pixel according to the first embodiment.

FIG. 4 is a plan view illustrating an example of a layout of the pixel according to the first embodiment.

FIG. 5 is a conceptual diagram illustrating an operation of the pixel.

FIG. 6 is a timing chart illustrating an example of an operation of the pixel according to the first embodiment.

FIG. 7 is a cross-sectional view illustrating a configuration example of a back-illuminated iTOF sensor according to a modification of the first embodiment.

FIG. 8 is a cross-sectional view illustrating a configuration example of the back-illuminated iTOF sensor according to another modification of the first embodiment.

FIG. 9 is a cross-sectional view illustrating a configuration example of the back-illuminated iTOF sensor according to still another modification of the first embodiment.

FIG. 10 is an equivalent circuit diagram illustrating an example of a configuration of the pixel according to a second embodiment.

FIG. 11 is a plan view illustrating an example of a layout of the pixel according to the second embodiment.

FIG. 12 is an equivalent circuit diagram illustrating an example of a configuration of the pixel according to a third embodiment.

FIG. 13 is an equivalent circuit diagram illustrating an example of a configuration of the pixel according to a fourth embodiment.

FIG. 14 is an equivalent circuit diagram illustrating an example of a configuration of the pixel according to a fifth embodiment.

FIG. 15 is an equivalent circuit diagram illustrating an example of a configuration of the pixel according to a sixth embodiment.

FIG. 16 is a plan view illustrating an example of a layout of the pixel according to the sixth embodiment.

FIG. 17 is a timing chart illustrating an example of an operation of the pixel according to the sixth embodiment.

FIG. 18 is an equivalent circuit diagram illustrating an example of a configuration of the pixel according to a seventh embodiment.

FIG. 19 is a plan view illustrating an example of a layout of the pixel according to the seventh embodiment.

FIG. 20 is a timing chart illustrating an example of an operation of the pixel according to the seventh embodiment.

FIG. 21 is an equivalent circuit diagram illustrating an example of a configuration of the pixel according to an eighth embodiment.

FIG. 22 is an equivalent circuit diagram illustrating an example of a configuration of the pixel according to a ninth embodiment.

FIG. 23 is an equivalent circuit diagram illustrating an example of a configuration of the pixel according to a tenth embodiment.

FIG. 24 is a plan view illustrating an example of a layout of the pixel according to the tenth embodiment.

FIG. 25 is a timing chart illustrating an example of an operation of the pixel according to the tenth embodiment.

FIG. 26 is an equivalent circuit diagram illustrating an example of a configuration of the pixel according to an 11th embodiment.

FIG. 27 is an equivalent circuit diagram illustrating an example of a configuration of the pixel according to a 12th embodiment.

FIG. 28 is an equivalent circuit diagram illustrating an example of a configuration of the pixel according to a 13th embodiment.

FIG. 29 is a schematic diagram illustrating a chip configuration example of the pixel according to a 14th embodiment.

FIG. 30 is a schematic diagram illustrating a chip configuration example of the pixel according to a 15th embodiment.

FIG. 31 is a schematic diagram illustrating a chip configuration example of the pixel according to a 16th embodiment.

FIG. 32 is a schematic diagram illustrating a chip configuration example of the pixel according to a 17th embodiment.

FIG. 33 is a schematic diagram illustrating a chip configuration example of the pixel according to a 18th embodiment.

FIG. 34 is a schematic diagram illustrating a chip configuration example of the pixel according to a 19th embodiment.

FIG. 35 is a schematic diagram illustrating a chip configuration example of the pixel according to a 20th embodiment.

FIG. 36 is a schematic diagram illustrating a chip configuration example of the pixel according to a 21st embodiment.

FIG. 37 is a schematic diagram illustrating a chip configuration example of the pixel according to a 22nd embodiment.

FIG. 38 is a plan view illustrating an example of a pixel array of a pixel region according to a 23rd embodiment.

FIG. 39 is a plan view illustrating an example of a pixel array of the pixel region according to a 24th embodiment.

FIG. 40 is a plan view illustrating an example of a pixel array of the pixel region according to a 25th embodiment.

FIG. 41 is a plan view illustrating an example of a pixel array of the pixel region according to a 26th embodiment.

FIG. 42 is a plan view illustrating an example of a pixel array of the pixel region according to a 27th embodiment.

FIG. 43 is a plan view illustrating an example of a pixel array of the pixel region according to a 28th embodiment.

FIG. 44 is a plan view illustrating an example of a pixel array of the pixel region according to a 29th embodiment.

FIG. 45 is a conceptual diagram illustrating a configuration example of the pixel region according to a 30th embodiment.

FIG. 46 is a conceptual diagram illustrating a configuration example of the pixel region according to a 31st embodiment.

FIG. 47 is a conceptual diagram illustrating a configuration example of the pixel region according to a 32nd embodiment.

FIG. 48 is a conceptual diagram illustrating a configuration example of the pixel region according to a 33rd embodiment.

FIG. 49 is a conceptual diagram illustrating a configuration example of the pixel region according to a 34th embodiment.

FIG. 50 is a conceptual diagram illustrating a configuration example of the pixel region according to a 35th embodiment.

FIG. 51 is a conceptual diagram illustrating a configuration example of the pixel region according to a 36th embodiment.

FIG. 52 is a conceptual diagram illustrating a configuration example of the pixel region according to a 37th embodiment.

FIG. 53 is a conceptual diagram illustrating a configuration example of the pixel region according to a 38th embodiment.

FIG. 54 is an equivalent circuit diagram illustrating a configuration example of the pixel according to a 39th embodiment.

FIG. 55 is a conceptual diagram illustrating an operation in a cross section taken along line 55-55 in FIG. 54.

FIG. 56 is a plan view illustrating an example of a layout of the pixel according to the 39th embodiment.

FIG. 57 is a timing chart illustrating an example of an operation of the pixel according to the 39th embodiment.

FIG. 58 is a timing chart illustrating another example of the operation of the pixel according to the 39th embodiment.

FIG. 59 is an equivalent circuit diagram illustrating a configuration example of the pixel according to a 40th embodiment.

FIG. 60 is a timing chart illustrating an example of an operation of the pixel according to the 40th embodiment.

FIG. 61 is a timing chart illustrating another example of the operation of the pixel according to the 40th embodiment.

FIG. 62 is a circuit diagram illustrating an example of a configuration of the pixel according to a 41st embodiment.

FIG. 63A is a timing chart illustrating an operation example of the pixel according to the 41st embodiment.

FIG. 63B is a timing chart illustrating another example of the operation of the pixel according to the 41st embodiment.

FIG. 64 is a circuit diagram illustrating an example of a configuration of the pixel according to a 42nd embodiment.

FIG. 65 is a circuit diagram illustrating an example of a configuration of the pixel according to a 43rd embodiment.

FIG. 66 is a circuit diagram illustrating an example of a configuration of the pixel according to a 44th embodiment.

FIG. 67 is a circuit diagram illustrating an example of a configuration of the pixel according to a 45th embodiment.

FIG. 68 is a circuit diagram illustrating an example of a configuration of the pixel according to a 46th embodiment.

FIG. 69 is a circuit diagram illustrating an example of a configuration of the pixel according to a 47th embodiment.

FIG. 70 is a circuit diagram illustrating an example of a configuration of the pixel according to a 48th embodiment.

FIG. 71 is an equivalent circuit diagram illustrating an example of a configuration of the pixel according to a 49th embodiment.

FIG. 72 is a plan view illustrating an example of a layout of the pixel according to the 49th embodiment.

FIG. 73 is an equivalent circuit diagram illustrating an example of a configuration of the pixel according to a 50th embodiment.

FIG. 74 is an equivalent circuit diagram illustrating an example of a configuration of the pixel according to a 51st embodiment.

FIG. 75 is an equivalent circuit diagram illustrating an example of a configuration of the pixel according to a 52nd embodiment.

FIG. 76 is a timing chart illustrating an example of a read operation of the pixel according to the 52nd embodiment.

FIG. 77 is a timing chart illustrating another example of the read operation of the pixel according to the 52nd embodiment.

FIG. 78 is an equivalent circuit diagram illustrating an example of a configuration of the pixel according to a 53rd embodiment.

FIG. 79 is an equivalent circuit diagram illustrating an example of a configuration of the pixel according to a 54th embodiment.

FIG. 80 is an equivalent circuit diagram illustrating an example of a configuration of the pixel according to a 55th embodiment.

FIG. 81 is a timing chart illustrating an example of a read operation of the pixel according to the 55th embodiment.

FIG. 82 is a timing chart illustrating another example of the read operation of the pixel according to the 55th embodiment.

FIG. 83 is an equivalent circuit diagram illustrating an example of a configuration of the pixel according to a 56th embodiment.

FIG. 84 is a timing chart illustrating an example of a read operation of the pixel according to the 56th embodiment.

FIG. 85 is a timing chart illustrating an example of the read operation of the pixel according to the 56th embodiment.

FIG. 86 is an equivalent circuit diagram illustrating an example of a configuration of the pixel according to a 57th embodiment.

FIG. 87 is an equivalent circuit diagram illustrating an example of a configuration of the pixel according to a 58th embodiment.

FIG. 88 is a plan view illustrating an example of a layout of the pixel according to the 58th embodiment.

FIG. 89 is a potential diagram illustrating an operation of the pixel according to the 58th embodiment.

FIG. 90 is a potential diagram illustrating an operation of the pixel according to the 58th embodiment.

FIG. 91 is a potential diagram illustrating an operation of the pixel according to the 58th embodiment.

FIG. 92 is a potential diagram illustrating an operation of the pixel according to the 58th embodiment.

FIG. 93 is a potential diagram illustrating an operation of the pixel according to the 58th embodiment.

FIG. 94 is a potential diagram illustrating an operation of the pixel according to the 58th embodiment.

FIG. 95 is a potential diagram illustrating an operation of the pixel according to the 58th embodiment.

FIG. 96 is a potential diagram illustrating an operation of the pixel according to the 58th embodiment.

FIG. 97 is an equivalent circuit diagram illustrating an example of a configuration of the pixel according to a 59th embodiment.

FIG. 98 is a plan view illustrating an example of a layout of the pixel according to the 59th embodiment.

FIG. 99 is a potential diagram illustrating an operation of the pixel according to the 59th embodiment.

FIG. 100 is a potential diagram illustrating an operation of the pixel according to the 59th embodiment.

FIG. 101 is a potential diagram illustrating an operation of the pixel according to the 59th embodiment.

FIG. 102 is a potential diagram illustrating an operation of the pixel according to the 59th embodiment.

FIG. 103 is a potential diagram illustrating an operation of the pixel according to the 59th embodiment.

FIG. 104 is a potential diagram illustrating an operation of the pixel according to the 59th embodiment.

FIG. 105 is a potential diagram illustrating an operation of the pixel according to the 59th embodiment.

FIG. 106 is a potential diagram illustrating an operation of the pixel according to the 59th embodiment.

FIG. 107 is a potential diagram illustrating an operation of the pixel according to the 59th embodiment.

FIG. 108 is a potential diagram illustrating an operation of the pixel according to the 59th embodiment.

FIG. 109 is an equivalent circuit diagram illustrating an example of a configuration of the pixel according to a 60th embodiment.

FIG. 110 is a plan view illustrating an example of a layout of the pixel according to the 60th embodiment.

FIG. 111 is a timing chart illustrating an operation of the pixel according to the 60th embodiment.

FIG. 112 is a potential diagram illustrating an operation of the pixel according to the 60th embodiment.

FIG. 113 is a potential diagram illustrating an operation of the pixel according to the 60th embodiment.

FIG. 114 is a potential diagram illustrating an operation of the pixel according to the 60th embodiment.

FIG. 115 is a potential diagram illustrating an operation of the pixel according to the 60th embodiment.

FIG. 116 is a potential diagram illustrating an operation of the pixel according to the 60th embodiment.

FIG. 117 is a potential diagram illustrating an operation of the pixel according to the 60th embodiment.

FIG. 118 is a potential diagram illustrating an operation of the pixel according to the 60th embodiment.

FIG. 119 is a potential diagram illustrating an operation of the pixel according to the 60th embodiment.

FIG. 120 is a potential diagram illustrating an operation of the pixel according to the 60th embodiment.

FIG. 121 is a potential diagram illustrating an operation of the pixel according to the 60th embodiment.

FIG. 122 is a layout diagram illustrating an example of the pixel according to a 61st embodiment and a schematic diagram thereof.

FIG. 123 is a schematic diagram illustrating an arrangement example of pixels in the pixel region according to the 61st embodiment.

FIG. 124 is a view illustrating an incident direction of light with respect to a pixel.

FIG. 125 is a schematic diagram illustrating another arrangement example of the pixels in the pixel region according to the 61st embodiment.

FIG. 126 is a block diagram illustrating a configuration example of a light receiving element.

FIG. 127 is a perspective view illustrating a configuration example of a light receiving element capable of storing a digital signal corresponding to a signal charge.

FIG. 128 is a conceptual diagram illustrating an example of a method of estimating signal strength of each frame.

FIG. 129 is a conceptual diagram illustrating another example of the method of estimating the signal strength of each frame.

FIG. 130 is a conceptual diagram illustrating an example of a method of calculating a signal of each frame.

FIG. 131 is a block diagram illustrating a schematic configuration example of a vehicle control system which is an example of a moving body control system to which the technology according to the present disclosure can be applied.

FIG. 132 is a diagram depicting an example of an installation position of an imaging section.

### MODE FOR CARRYING OUT THE INVENTION

Hereinafter, specific embodiments to which the present technology is applied will be described in detail with reference to the drawings. The drawings are schematic or conceptual, and the ratio of each portion and the like are not necessarily the same as actual ones. In the description and the drawings, elements similar to those described above with respect to previously described drawings are denoted by the same reference numerals, and detailed descriptions thereof are appropriately omitted.

### First Embodiment

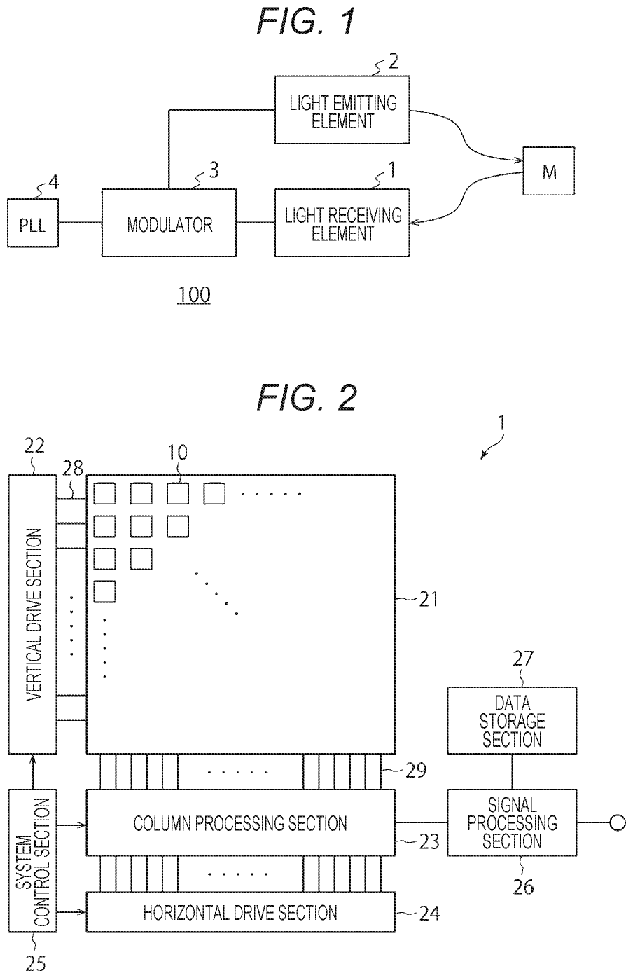

FIG. 1 is a block diagram illustrating a configuration example of a distance measuring device according to a first embodiment. The distance measuring device 100 is a distance measuring sensor based on an indirect ToF (hereinafter, also referred to as iToF) method, and is used, for example, in a vehicle-mounted system or the like that is mounted on a vehicle and measures a distance to a target outside the vehicle. Furthermore, the distance measuring device 100 may also be used in, for example, a system or the like that identifies an individual, such as face authentication.

The distance measuring device 100 includes a light receiving element 1, a light emitting element 2, a modulator 3, and a phase locked loop (PLL) 4. The PLL4 generates a pulse signal. The modulator 3 modulates the pulse signal from the PLL4 to generate a control signal. The frequency of the control signal may be, for example, 5 MHz to 200 MHz. The light emitting element 2 emits light in accordance with a control signal from the modulator. The light emitting element 2 includes, as a light source, a light emitting diode that emits infrared light having a wavelength in a range of 780 nm to 1000 nm, and generates irradiation light in synchronization with a rectangular wave or sine wave control signal. The light generated by the light emitting element 2 may be, for example, short wave infrared radiometer (SWIR) or the like. The irradiation light emitted from the light emitting element 2 is reflected by the object M and received by the light receiving element 1.

The reflected light received by the light receiving element 1 is delayed according to the distance to the object M from the timing at which the light emitting element 2 emits light. A delay time of the reflected light with respect to the irradiation light causes a phase difference to occur between the irradiation light and the reflected light. In the iToF method, the distance measuring device 100 calculates the phase difference between the irradiation light and the reflected light, and obtains the distance (depth information) from the distance measuring device 100 to the object M on the basis of the phase difference.

When the object M is far from the light emitting element 2, the reflected light becomes weak, and the influence of noise of background light such as sunlight increases. Thus, reduction of random noise such as kTC noise is desired.

FIG. 2 is a block diagram illustrating a schematic configuration example of a light receiving element of the distance measuring device according to the first embodiment. The light receiving element 1 is an element used in the distance measuring device 100 by the iToF method in FIG. 1.

The light receiving element 1 receives light (reflected light) returned after the irradiation light generated by the light emitting element 2 as a light source hits an object and is reflected, and outputs a depth image representing distance information to the object as a depth value.

The light receiving element 1 includes a pixel region 21 provided on a semiconductor substrate (not illustrated) and a peripheral circuit unit provided on the same semiconductor substrate. The peripheral circuit unit includes, for example, a vertical drive section 22, a column processing section 23, a horizontal drive section 24, and a system control section 25, as well as a signal processing section 26 and a data storage section 27, and the like. Note that all or part of the peripheral circuit unit may be provided on the same semiconductor substrate as the light receiving element 1, or may be provided on a substrate different from the light receiving element 1.

The pixel region 21 includes a plurality of pixels 10 two-dimensionally arranged in a matrix in a row direction and a column direction. The pixel 10 generates a charge corresponding to the amount of received light, and outputs a signal corresponding to the charge. That is, the pixel 10 photoelectrically converts incident light and outputs a signal corresponding to the charge obtained as a result. Details of the pixel 10 will be described later. Note that the row direction is a horizontal direction in FIG. 2, and the column direction is a vertical direction.

In the pixel region 21, a pixel drive line 28 is wired along the row direction for each pixel row and two vertical signal lines 29 are wired along the column direction for each pixel column with respect to a matrix-like pixel array. For example, the pixel drive line 28 transmits a drive signal for performing driving when reading a signal from the pixel 10. Note that, in FIG. 2, the pixel drive line 28 is illustrated as one wiring, but is not limited to one. One end of the pixel drive line 28 is connected to an output terminal corresponding to each row of the vertical drive section 22.

The vertical drive section 22 includes a shift register, an address decoder, and the like, and drives the respective pixels 10 of the pixel region 21 all at the same time, in units of rows, or the like. That is, the vertical drive section 22 constitutes a drive section that controls the operation of each pixel 10 in the pixel region 21 together with the system control section 25 that controls the vertical drive section 22.

A detection signal output from each pixel 10 of the pixel row according to drive control by the vertical drive section 22 is input to the column processing section 23 through the vertical signal line 29. The column processing section 23 performs predetermined signal processing on the detection signal output from each pixel 10 through the vertical signal line 29, and temporarily holds the detection signal after the signal processing. Specifically, the column processing section 23 performs noise removal processing, analog-to-digital (AD) conversion processing, and the like as the signal processing.

The horizontal drive section 24 includes a shift register, an address decoder, and the like, and sequentially selects a unit circuit corresponding to a pixel column of the column processing section 23. By the selective scanning by the horizontal drive section 24, the detection signals subjected to the signal processing for each unit circuit in the column processing section 23 are sequentially output.

The system control section 25 includes a timing generator or the like that generates various timing signals, and performs drive control of the vertical drive section 22, the column processing section 23, the horizontal drive section 24, and the like on the basis of the various timing signals generated by the timing generator.

The signal processing section 26 has an arithmetic processing function, and performs various signal processing such as arithmetic processing on the basis of the detection signal output from the column processing section 23. The data storage section 27 temporarily stores data necessary for signal processing in the signal processing section 26.

The light receiving element 1 configured as described above includes the distance information to an object in a pixel value as a depth value, and outputs the pixel value as a depth image. The light receiving element 1 can be mounted on, for example, a vehicle-mounted system that is mounted on a vehicle and measures a distance to a target outside the vehicle, or the like.

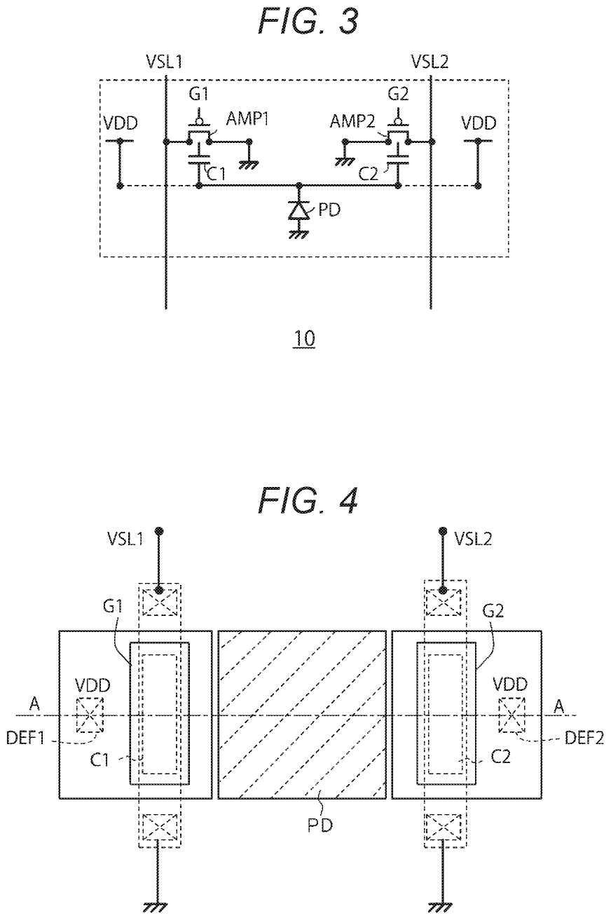

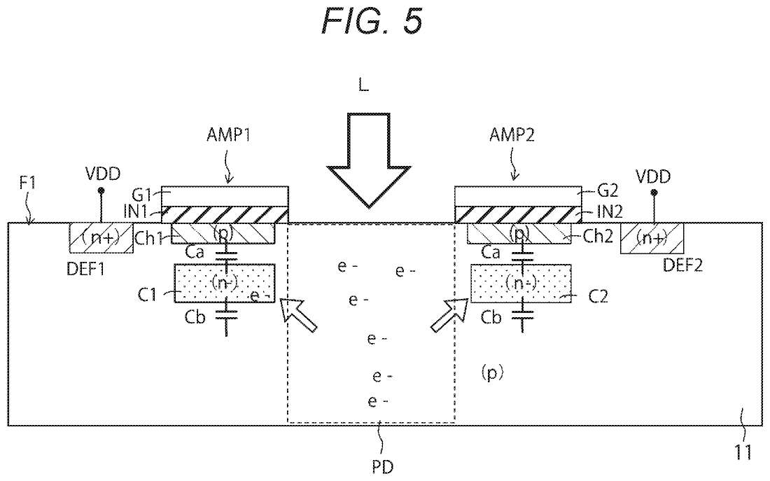

FIG. 3 is an equivalent circuit diagram illustrating an example of a configuration of the pixel 10 according to the first embodiment. FIG. 4 is a plan view illustrating an example of a layout of the pixel 10 according to the first embodiment. FIG. 5 is a conceptual diagram illustrating an operation of the pixel 10. FIG. 5 illustrates a cross section taken along line A-A in FIG. 4. The plurality of pixels 10 has the same configuration.

The pixel 10 includes a photodiode PD, amplification transistors AMP1 and AMP2, capacitor layers C1 and C2, a power supply VDD, and vertical signal lines VSL1 and VSL2.

The photodiode PD is a photoelectric conversion element that converts incident light into a charge. As illustrated in FIG. 5, the photodiode PD is provided in a p-type semiconductor layer 11 as the first conductivity type, and is provided between the amplification transistor AMP1 and the amplification transistor AMP2. The semiconductor layer 11 may be, for example, a silicon substrate, an epitaxial silicon layer, or the like.

A source electrode of the amplification transistor AMP1 is connected to the vertical signal line VSL1, and a drain electrode thereof is grounded. A source electrode of the amplification transistor AMP2 is connected to the vertical signal line VSL2, and a drain electrode thereof is grounded. As illustrated in FIG. 5, both the amplification transistors AMP1 and AMP2 are provided on the first surface F1 of the semiconductor layer 11, and are provided on both sides of the photodiode PD. Channel layers Ch1 and Ch2 of the amplification transistors AMP1 and AMP2 are p-type impurity diffusion layers provided on the first surface F1 side in the semiconductor layer 11. Gate electrodes G1 and G2 of the amplification transistors AMP1 and AMP2 are conductors provided above the channel layers Ch1 and Ch2 with gate insulating films IN1 and IN2 respectively interposed therebetween. The amplification transistors AMP1 and AMP2 receive voltages of the gate electrodes G1 and G2 and change to a conductive or non-conductive state in the channel layers Ch1 and Ch2. The amplification transistors AMP1 and AMP2 are channel modulation transistors whose threshold voltages are modulated by charges accumulated in the capacitor layers C1 and C2, respectively. The amplification transistors AMP1 and AMP2 are constituted by, for example, p-type metal-oxide-semiconductor field-effect transistors (MOSFET).

The amplification transistors AMP1 and AMP2 are channel modulation transistors, but do not have a ring structure. Thus, the areas of the channel layers Ch1 and Ch2 can be reduced, and photoelectric conversion efficiency can be increased. Consequently, kTC noise can be reduced. Furthermore, in a case where the capacitor layers C1 and C2 have a ring shape, a variation in impurity charge distribution at the center of the ring causes variations in charge collection, accumulation, and discharge performance between taps of the capacitor layer C1 and the capacitor layer C2. Since the capacitor layers C1 and C2 according to the present embodiment have a substantially rectangular parallelepiped shape, it is possible to suppress variations in charge collection, accumulation, and discharge performance.

The capacitor layers C1 and C2 are n-type impurity diffusion layers provided in the semiconductor layer 11 below the channel layers Ch1 and Ch2, respectively. The capacitor layers C1 and C2 can accumulate charges photoelectrically converted by the photodiode PD.

The capacitor layer C1 is provided in the semiconductor layer 11 immediately below the amplification transistor AMP1. The capacitor layer C1 is capacitively coupled to the channel layer Ch1 with a capacitance Ca, and capacitively coupled to the semiconductor layer 11 with a capacitance Cb. Therefore, the threshold voltage of the amplification transistor AMP1 is modulated by a back bias effect depending on the amount of charges (for example, electrons e⁻) accumulated in the capacitor layer C1. When the threshold voltage is modulated, even if the gate voltage is the same, the conductive state of the amplification transistor AMP1 changes, and the current or the voltage of the vertical signal line VSL1 changes. Therefore, the vertical signal line VSL1 can transmit a voltage corresponding to the amount of charges accumulated in the capacitor layer C1.

The capacitor layer C2 is provided in the semiconductor layer 11 immediately below the amplification transistor AMP2. The capacitor layer C2 is capacitively coupled to the channel layer Ch2 with a capacitance Ca, and capacitively coupled to the semiconductor layer 11 with a capacitance Cb. Therefore, the threshold voltage of the amplification transistor AMP2 is also modulated by the back bias effect depending on the amount of charges (for example, electrons e⁻) accumulated in the capacitor layer C2. When the threshold voltage is modulated, even if the gate voltage is the same, the conductive state of the amplification transistor AMP2 changes, and the current or the voltage of the vertical signal line VSL2 changes. Therefore, the vertical signal line VSL2 can transmit a voltage corresponding to the amount of charges accumulated in the capacitor layer C2.

The gate electrode G1 is provided immediately above the channel layer Ch1, and the capacitor layer C1 is provided immediately below the channel layer Ch1. That is, the gate electrode G1 and the capacitor layer C1 are provided on opposite sides of the channel layer Ch1. In a plan view seen from the incident direction of the light L on the semiconductor layer 11 (above the first surface F1 of the semiconductor layer 11), the gate electrode G1, the channel layer Ch1, and the capacitor layer C1 overlap as illustrated in FIG. 4. The channel layer Ch1 is a p-type impurity diffusion layer and has a conductivity type opposite to that of the capacitor layer C1.

Note that the sizes of the capacitor layers C1 and C2 are arbitrary in plan view viewed from the incident direction of L. For example, increasing the areas of the capacitor layers C1 and C2 decreases the photoelectric conversion efficiency, and decreasing the areas of the capacitor layers C1 and C2 increases the photoelectric conversion efficiency. The photoelectric conversion efficiency can be arbitrarily designed depending on layout areas of the capacitor layers C1 and C2.

The gate electrode G2 is provided immediately above the channel layer Ch2, and the capacitor layer C2 is provided immediately below the channel layer Ch2. That is, the gate electrode G2 and the capacitor layer C2 are provided on opposite sides of the channel layer Ch2. In a plan view of the semiconductor layer 11 as viewed from above the first surface F1, the gate electrode G2, the channel layer Ch2, and the capacitor layer C2 overlap as illustrated in FIG. 4. The channel layer Ch2 is a p-type impurity diffusion layer and has a conductivity type opposite to that of the capacitor layer C2.

In a plan view seen from the incident direction of the light L on the semiconductor layer 11, the capacitor layers C1 and C2 are arranged on one side and the other side of the photodiode PD, respectively. Furthermore, the amplification transistors AMP1 and AMP2 are also arranged on one side and the other side of the photodiode PD, respectively.

Power supply diffusion layers DEF1 and DEF2 illustrated in FIGS. 4 and 5 are n⁺-type impurity diffusion layers provided on the first surface F1 side in the semiconductor layer 11 and connected to the power supply VDD. In a reset operation, the power supply diffusion layers DEF1 and DEF2 extract charges in the capacitor layers C1 and C2, and bring the capacitor layers C1 and C2 into a reset state in which no charges are accumulated.

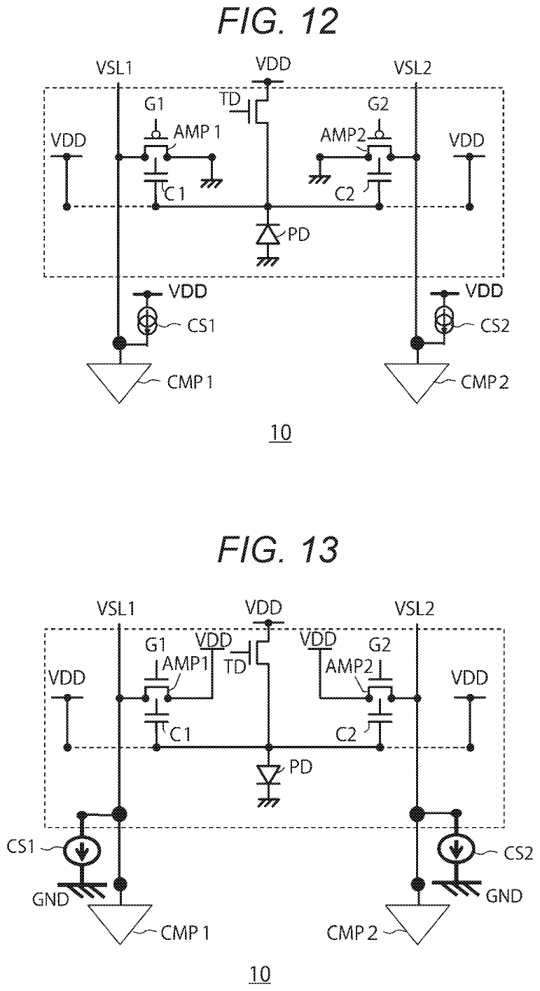

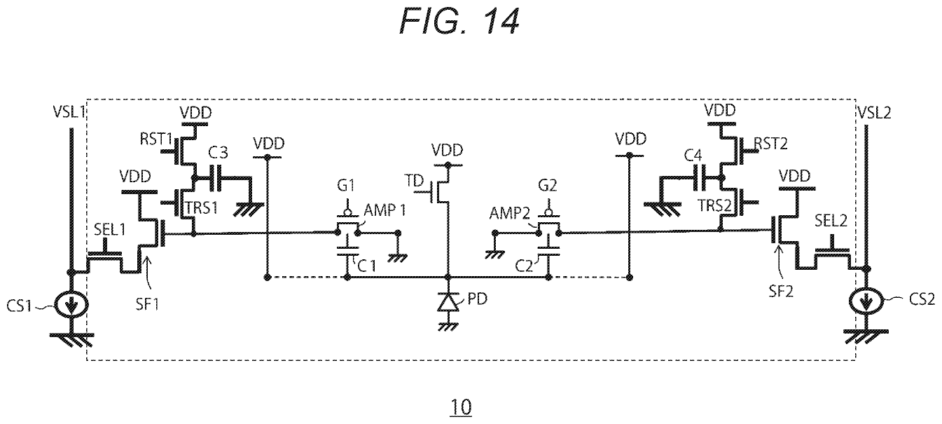

The vertical signal line VSL1 is connected to the source of the amplification transistor AMP1, and transmits a voltage corresponding to the threshold voltage of the amplification transistor AMP1 by applying a constant current. The vertical signal line VSL2 is connected to the source of the amplification transistor AMP2, and transmits a voltage corresponding to the threshold voltage of the amplification transistor AMP2 by applying a constant current. Note that, as illustrated in FIG. 12, current sources are connected to the vertical signal lines VSL1 and VSL2. Since the amplification transistors AMP1 and AMP2 are p-type transistors, the current source is connected to the power supply side of the vertical signal lines VSL1 and VSL2. Further, as illustrated in FIG. 14, source follower circuits may be provided between the amplification transistors AMP1 and AMP2 and the vertical signal lines VSL1 and VSL2, respectively. Moreover, although not illustrated, the pixel 10 may have a current reading circuit configuration using a source-grounded circuit.

Furthermore, in the present embodiment, the signal charges accumulated in the capacitor layers C1 and C2 are electrons, but the signal charges may be holes.

As illustrated in FIG. 5, in the present embodiment, the light L is incident on the semiconductor layer 11 from the first surface F1. That is, the distance measuring device 100 of the present embodiment is a surface irradiation type iTOF sensor.

Next, an operation of the pixel 10 will be briefly described.

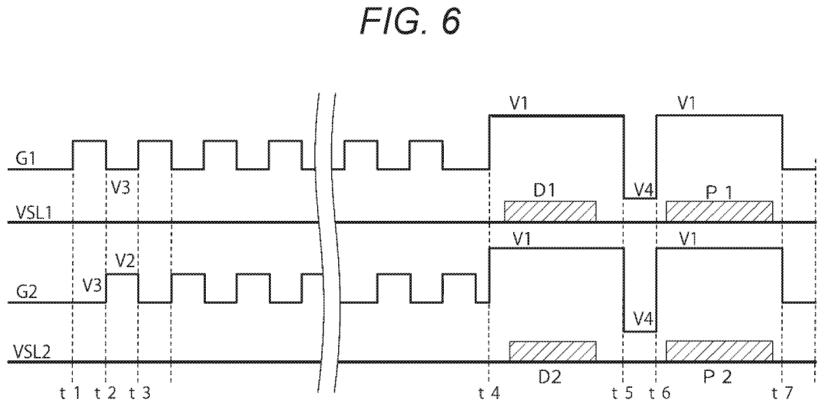

FIG. 6 is a timing chart illustrating an example of the operation of the pixel 10 according to the first embodiment. First, before light reception is started, the reset operation for resetting charges in the pixels 10 is performed in all the pixels. In the reset operation, the accumulated charges in the photodiode PD and the capacitor layers C1 and C2 are discharged to the power supply VDD side.

After the accumulated charges are discharged, light reception is started.

In the light receiving period, the amplification transistors AMP1 and AMP2 are alternately driven. For example, in the first period t1 to t2, the voltage of the gate electrode G1 rises to a high level V2 (collection voltage), and the voltage of the gate electrode G2 remains at a low level V3 (accumulated voltage). Thus, the amplification transistor AMP1 is brought into a conductive state (hereinafter, ON), and the amplification transistor AMP2 is brought into a non-conductive state (hereinafter, OFF). At this time, the charge generated in the photodiode PD is transferred to the capacitor layer C1. In the second period t2 to t3 next to the first period t1 to t2, the voltage of the gate electrode G2 rises to the high level V2, and the voltage of the gate electrode G1 falls to the low level V3. Thus, the amplification transistor AMP1 is turned off, and the amplification transistor AMP2 is turned on. In the second period t2 to t3, the charge generated in the photodiode PD is transferred to the capacitor layer C2. Thus, the charge generated in the photodiode PD is distributed and accumulated in the capacitor layers C1 and C2. Note that, in this case, the holes move to the semiconductor layer 11 and are discharged.

The first period t1 to t2 and the second period t2 to t3 are periodically and alternately repeated in synchronization with the irradiation light from the light emitting element 2. Thus, the capacitor layers C1 and C2 can accumulate charges corresponding to the phase difference between the irradiation light from the light emitting element 2 in FIG. 1 and the reflected light received by the light receiving element 1. The relationship between the phase difference and the charges accumulated in the capacitor layers C1 and C2 will be described later.

Then, when the light receiving period ends at t4, each pixel 10 of the pixel region 21 is sequentially selected. In the selected pixel 10, a read voltage V1 is applied to the gate electrodes G1 and G2 of the amplification transistors AMP1 and AMP2. The read voltage V1 is a voltage higher than the high level V2 at the time of charge accumulation. Thus, the amplification transistors AMP1 and AMP2 are brought into a conductive state corresponding to the charge amounts accumulated in the capacitor layers C1 and C2, respectively. As a result, the vertical signal lines VSL1 and VSL2 transmit voltages corresponding to the charge amounts accumulated in the capacitor layers C1 and C2, respectively. For example, in the read operation from t4 to t5, the vertical signal lines VSL1 and VSL2 transmit signal voltages D1 and D2 corresponding to the signal charges generated by the photodiode PD in response to the incident light L.

Next, in the reset operation from t5 to t6, the reset voltage V4 is applied to the gate electrodes G1 and G2 of the amplification transistors AMP1 and AMP2. The reset voltage V4 is a voltage lower than the low level V3 at the time of charge accumulation. Thus, the amplification transistors AMP1 and AMP2 extract the signal charges accumulated in the capacitor layers C1 and C2, respectively, and discharge the signal charges to the power supply VDD. As a result, signal charges are removed from the capacitor layers C1 and C2, and the capacitor layers C1 and C2 are brought into reset states. That is, the pixel 10 is brought into a reset state in which no signal charge is accumulated.

Next, when the reset operation ends at t6, each pixel 10 is sequentially selected. In the selected pixel 10, the read voltage V1 is also applied to the gate electrodes G1 and G2 of the amplification transistors AMP1 and AMP2. Thus, the amplification transistors AMP1 and AMP2 are brought into conductive states corresponding to the reset states of the capacitor layers C1 and C2, respectively. As a result, the vertical signal lines VSL1 and VSL2 transmit voltages corresponding to the reset states of the capacitor layers C1 and C2, respectively. For example, in the read operation from t6 to t7, the vertical signal lines VSL1 and VSL2 transmit reset voltages P1 and P2 corresponding to the capacitor layers C1 and C2 in the reset state in which the signal charges are not accumulated, respectively.

Thus, the signal voltages D1 and D2 are output to the column processing section 23 via the vertical signal lines VSL1 and VSL2, respectively, and thereafter, the reset voltages P1 and P2 are output to the column processing section 23 via the vertical signal lines VSL1 and VSL2, respectively. Thereafter, the column processing section 23 performs correlated double sampling (CDS) processing using the signal voltage D1 and the reset voltage P1. Thus, it is possible to extract an accurate signal component obtained by removing dark current components from the signal voltages D1 and D2.

When one light receiving operation ends in this manner, the next light receiving operation is executed.

The light L received by the pixel 10 is delayed from the timing at which the light source emits the light according to the distance to the target. A phase difference occurs between the irradiation light and the reflected light due to the delay time corresponding to the distance to the target, and the distribution ratio of the charges accumulated in the capacitor layer C1 and the capacitor layer C2 changes. Thus, the phase difference between the irradiation light and the reflected light is calculated by detecting respective potentials of the capacitor layers C1 and C2, and the distance to the object can be obtained on the basis of the phase difference.

Next, a distance measuring operation of the distance measuring device 100 will be described.

The irradiation light is reflected by the object M in FIG. 1 and received by the light receiving element 1. The frequency of the reflected light is the same as that of the irradiation light and remains Fmod. On the other hand, a time Δt taken from when the irradiation light is emitted to when the irradiation light is reflected by the object M and returns as reflected light is a delay time (ToF) of the reflected light with respect to the irradiation light. If the delay time Δt is found, the distance from the distance measuring device 100 to the object M can be calculated on the basis of light speed c. However, since a phase difference occurs between the irradiation light and the reflected light according to the delay time Δt (t1 to t2), in iToF, the distance (depth information) D from the distance measuring device 100 to the object M is calculated using the phase difference a between the irradiation light and the reflected light.

The distance D is expressed by Expression 1.

$$D = ( c \times Δ t ) / 2 = ( c \times α ) / ( 4 π \times F mod ) \qquad ( Expression 1 )$$

When the phase difference a is known, the distance D can be calculated by Expression 1.

In addition, the phase difference α is represented by Expression 2.

$$α = arc tan ( ( {Q}_{90} - {Q}_{270} ) / ( {Q}_{0} - {Q}_{180} ) ) \qquad ( Expression 2 )$$

Q_{θ} (θ=0, 90, 180, 270) indicates a difference (potential difference) between the charge amounts accumulated in the capacitor layers C1 and C2 when the phases of the gate signals S_{TRG1} and S_{TRG2} are shifted by θ with respect to the irradiation light. That is, in the iToF method, the phase difference α is calculated using four pieces of image data obtained when the phases of the gate signals S_{TRG1} and S_{TRG2} with respect to the irradiation light are shifted by a predetermined value (for example, 0 degrees, 90 degrees, 180 degrees, and 270 degrees). Then, the distance D is calculated using the phase difference a. This calculation is only required to be executed by the signal processing section 26 in FIG. 2. As described above, the distance measuring device 100 according to the present disclosure can obtain the distance D (depth information) using the iToF method.

According to the present embodiment, the amplification transistors AMP1 and AMP2 collect and accumulate charges generated by the photodiodes PD in the capacitor layers C1 and C2, and read out charge states (signal states or reset states) of the capacitor layers C1 and C2. Moreover, the amplification transistors AMP1 and AMP2 also discharge (reset) the charges accumulated in the capacitor layers C1 and C2. As described above, since the amplification transistors AMP1 and AMP2 are channel modulation transistors that also have a plurality of functions, the pixel 10 according to the present embodiment can include one photodiode PD and two transistors. Thus, each pixel 10 can be miniaturized, and the area of the pixel region 21 can be reduced.

According to the present embodiment, channel modulation transistors are used as the amplification transistors AMP1 and AMP2. The capacitor layers C1 and C2 are provided below the channel layers Ch1 and Ch2, respectively, and the threshold voltages of the amplification transistors AMP1 and AMP2 can be modulated depending on the charge amounts accumulated in the capacitor layers C1 and C2. In this case, since all the signal charges in the capacitor layers C1 and C2 can be removed, variations in the signals in the reset state are suppressed. That is, in the present embodiment, reproducibility of the reset state is favorable. Therefore, even if a reset state (P phase) in which there is no signal charge in the capacitor layers C1 and C2 is detected after a signal state (D phase) in which signal charges are accumulated in the capacitor layers C1 and C2 is detected, the CDS processing can be performed.

On the other hand, for example, in a case where charges are accumulated in the floating diffusion region connected to the photodiode PD via a metal wiring, the charges in the floating diffusion region cannot be completely removed even if the floating diffusion region is brought into the reset state. This is because some charges enter the floating diffusion region from the metal wiring because the floating diffusion region is connected to the metal wiring. In this case, every time the reset operation is performed, the amount of charges in the floating diffusion region changes, and the signals of the reset state varies. That is, the reproducibility of the reset state is poor. Therefore, when the reset state is detected after the signal state is detected, the reset state does not correspond to noise components of the signal state, and an accurate signal component cannot be extracted even if the CDS processing is performed.

On the other hand, according to the present embodiment, since the reproducibility of the reset state is favorable, the signal processing section 26 can extract an accurate signal component with less kTC noise even if the reset state detected after the signal state is excluded from the signal state. Consequently, the distance measuring device 100 according to the present embodiment can reduce the size of the pixel 10 and obtain a signal component with less kTC noise by the CDS processing.

In addition, according to the present embodiment, the amplification transistors AMP1 and AMP2 are provided with the capacitor layers C1 and C2 on the substrate side under the channel layers Ch1 and Ch2. The capacitor layers C1 and C2 are pocket regions that accumulate signal charges. The capacitor layers C1 and C2 can be formed to have a small volume and capacitance. Furthermore, the channel layers Ch1 and Ch2 and the semiconductor layer 11 are in contact with the capacitor layers C1 and C2 via the capacitances Ca and Cb of a depletion layer having a very small PN junction. Therefore, in the amplification transistors AMP1 and AMP2, the output voltage value (photoelectric conversion efficiency) per charge is very high. Thus, sensitivity of the pixel 10 can be improved. In addition, kTC noise can be reduced even when the light L has low illuminance.

Furthermore, in a case where electrons are used as signal charges, the capacitor layers C1 and C2 can be formed on a p-type substrate that is less expensive than an n-type substrate. Therefore, the present embodiment can suppress an increase in manufacturing cost.

### Modification

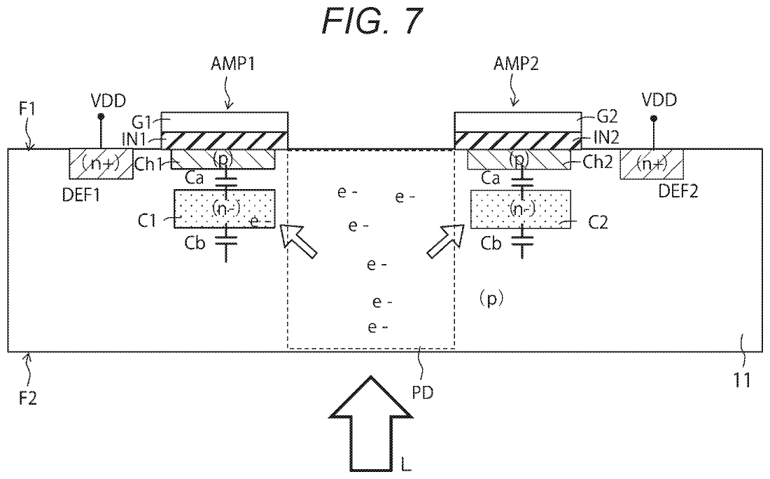

FIG. 7 is a cross-sectional view illustrating a configuration example of a back-illuminated iTOF sensor according to a modification of the first embodiment. In the back-illuminated iTOF sensor, the light L is incident from the second surface F2 of the semiconductor layer 11 on an opposite side of the first surface F1. As illustrated in FIG. 7, the present embodiment can also be applied to the back-illuminated iTOF sensor.

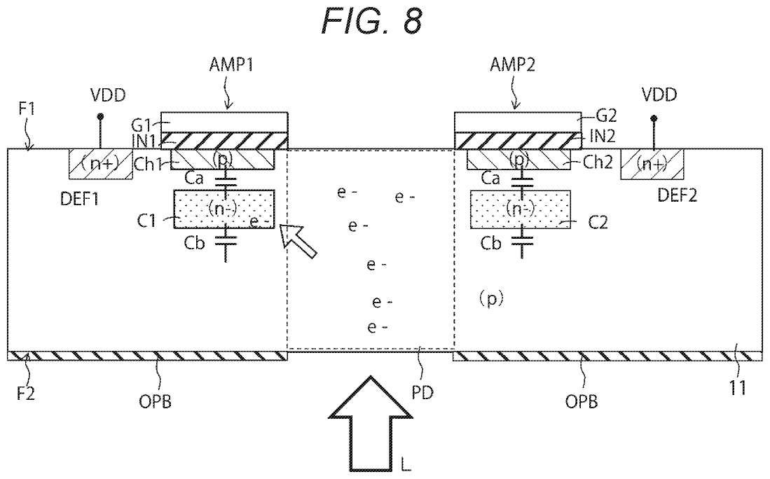

FIG. 8 is a cross-sectional view illustrating a configuration example of the back-illuminated iTOF sensor according to another modification of the first embodiment. In the modification of FIG. 8, a light shielding film OPB is provided in a region other than the photodiode PD on the second surface F2 of the semiconductor layer 11. In plan view seen from the incident direction of the light L, the light shielding film OPB is provided so as to overlap the capacitor layers C1 and C2, and is provided so as not to overlap the photodiode PD. For example, an opaque metal material or the like that does not transmit light is used for the light shielding film OPB. The light shielding film OPB does not transmit the light L in a region other than the photodiode PD. Thus, the light L can be suppressed from entering the capacitor layers C1 and C2, and parasitic light sensitivity (PLS) can be reduced.

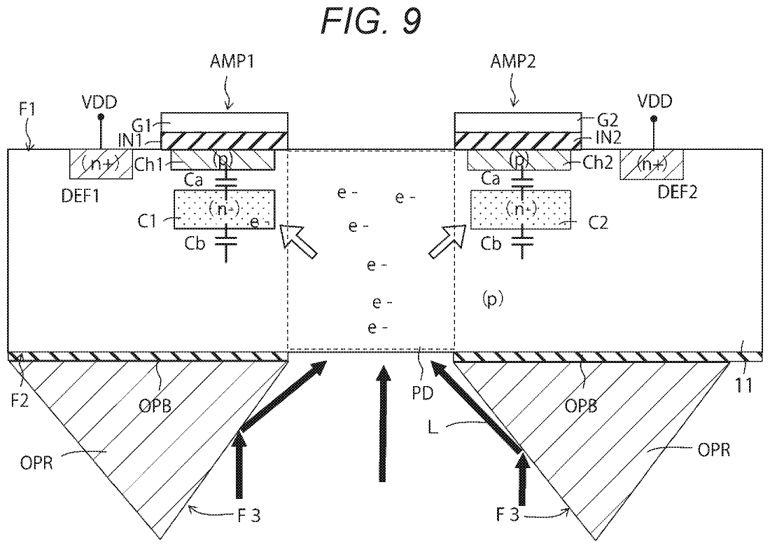

FIG. 9 is a cross-sectional view illustrating a configuration example of the back-illuminated iTOF sensor according to still another modification of the first embodiment. In the modification of FIG. 9, a reflection film OPR is provided on the light shielding film OPB. Similarly to the light shielding film OPB, the reflection film OPR is provided in a region other than the photodiode PD on the second surface F2 of the semiconductor layer 11. In plan view seen from the incident direction of the light L, the reflection film OPR is provided so as to overlap the capacitor layers C1 and C2, and reflects the light to the photodiode PD. The reflection film OPR is in contact with other materials (not illustrated) such as the atmosphere, silicon, and a silicon oxide film on the reflection surface F3, and reflects the light L at an interface thereof. The reflection surface F3 is a side surface of the reflection film OPR inclined with respect to the incident direction of the light L. For the reflection film OPR, a low refractive index material (for example, a polymer (refractive index 1.29), a low refractive index resin (refractive index 1.33), a fluororesin coating material (refractive index 1.34), a UV curable low refractive index resin (refractive index 1.40), or the like) having a refractive index lower than that of a material (for example, air, silicon, a silicon oxide film, and the like) in contact with the reflection surface F3 is used. Thus, the reflection film OPR can totally reflect the light L on the reflection surface F3. Consequently, even if there is no on-chip lens (OCL), the light L can be incident on the photodiode PD without being wasted, and pupil correction can be performed. This leads to a reduction in OCL formation steps and a reduction in PLS.

### Second Embodiment

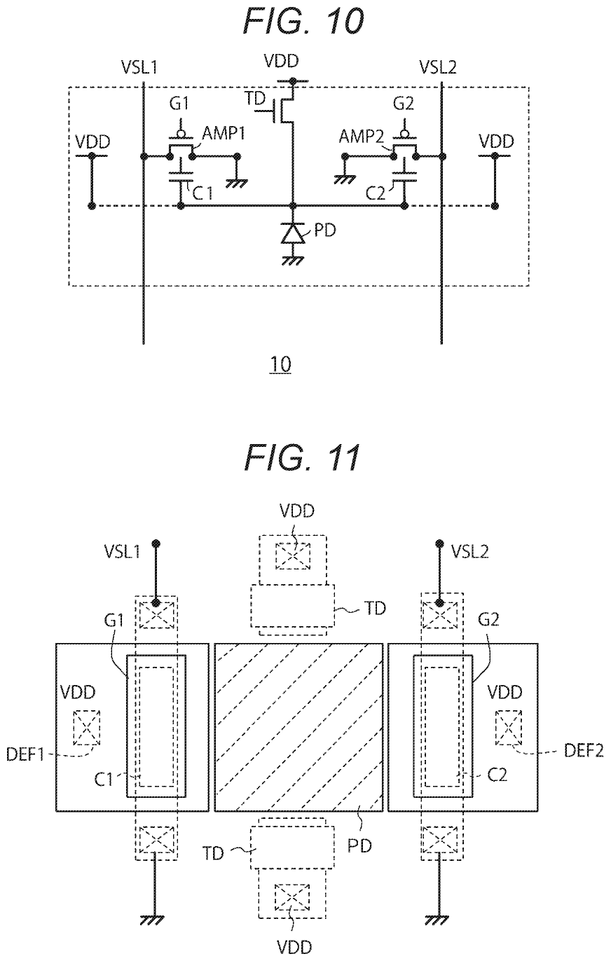

FIG. 10 is an equivalent circuit diagram illustrating an example of a configuration of the pixel 10 according to a second embodiment. FIG. 11 is a plan view illustrating an example of a layout of the pixel 10 according to the second embodiment.

In the second embodiment, each of the pixels 10 further includes a charge discharge transistor TD that discharges the charge of the photodiode PD. The charge discharge transistor TD is connected between the power supply VDD and the cathode of the photodiode PD, and can discharge the charges (for example, electrons) accumulated in the photodiode PD to the power supply VDD. In the planar layout illustrated in FIG. 11, the charge discharge transistor TD is arranged so as to be adjacent to two upper and lower sides of the photodiode PD. The charge discharge transistor TD is, for example, an n-type MOSFET. When the photodiode PD receives the light L, the charge discharge transistor TD is turned off. When the photodiode PD is not receiving the light L, the charge discharge transistor TD is turned on. For example, in the light receiving period from t1 to t4 in FIG. 6, the charge discharge transistor TD is turned off, and in the detection period from t4 to t7, the charge discharge transistor TD is turned on. Thus, it is possible to prevent unnecessary charges (noise) from being mixed into the capacitor layers C1 and C2 by background light such as sunlight. Consequently, the distance measurement accuracy of the distance measuring device 100 can be improved. In addition, since the capacitor layers C1 and C2 do not have a ring shape but have a substantially rectangular parallelepiped shape, the charge discharge transistor TD easily discharges charges from the capacitor layers C1 and C2 at the time of reset.

Other configurations of the second embodiment may be similar to the corresponding configurations of the first embodiment. Thus, the second embodiment can also obtain the effects of the first embodiment.

### Third Embodiment

FIG. 12 is an equivalent circuit diagram illustrating an example of a configuration of the pixel 10 according to a third embodiment.

The pixel 10 according to the third embodiment further includes a comparator CMP1 as a first comparator, a comparator CMP2 as a second comparator, a current circuit CS1 as a first current circuit, and a current circuit CS2 as a second current circuit. The comparators CMP1 and CMP2 are connected to the vertical signal lines VSL1 and VSL2, respectively, and are provided in each pixel 10. In addition, the current circuits CS1 and CS2 are connected between the power supply VDD and the vertical signal lines VSL1 and VSL2, respectively, and cause currents to flow through the vertical signal lines VSL1 and VSL2. By incorporating the comparators CMP1 and CMP2 in each pixel 10 in this manner, each pixel 10 can perform AD conversion on a signal and output the signal in a digital signal state.

Other configurations of the third embodiment may be similar to the corresponding configurations of the first or second embodiment. Thus, the third embodiment can also obtain the effects of the first or second embodiment.

### Fourth Embodiment

FIG. 13 is an equivalent circuit diagram illustrating an example of a configuration of the pixel 10 according to a fourth embodiment.

According to the fourth embodiment, the connection relationship between the cathode and the anode of the photodiode PD is opposite to that of the third embodiment. The capacitor layers C1 and C2 are constituted by p-type impurity diffusion layers, and accumulate holes. In this case, the amplification transistors AMP1 and AMP2 are constituted by n-type MOSFETs formed in n-type wells or n-type substrates. Furthermore, the current circuits CS1 and CS2 are connected between the power supply VDD and the vertical signal lines VSL1 and VSL2, respectively, and allow a current to flow in a direction opposite to that of the current circuits CS1 and CS2 of the third embodiment. Thus, the pixel 10 can accumulate holes as signal charges and detect signal components.

If the n-type well is formed in the p-type substrate and the capacitor layers C1 and C2 and the amplification transistors AMP1 and AMP2 are formed in the n-type well, the pixel 10 of the fourth embodiment can also be manufactured at low cost. In addition, since the amplification transistors AMP1 and AMP2 are n-type MOSFETs, reading can be performed with the same circuit configuration as the source follower circuit of a CMOS image sensor. Moreover, the capacitor layers C1 and C2 that accumulate the holes have voltages close to zero in the reset state, and there is a small dark current. Therefore, the pixel 10 according to the fourth embodiment can reduce random noise.

Other configurations of the fourth embodiment may be similar to the corresponding configurations of the third embodiment. Accordingly, the fourth embodiment can also obtain the effects of the third embodiment.

### Fifth Embodiment

FIG. 14 is an equivalent circuit diagram illustrating an example of a configuration of the pixel 10 according to a fifth embodiment. In the fifth embodiment, the pixel 10 includes transfer transistors TRS1 and TRS2, a capacitor element C3, a capacitor element C4, reset transistors RST1 and RST2, a source follower circuit SF1, a source follower circuit SF2, and selection transistors SEL1 and SEL2. In addition, current circuits CS1 and CS2 are provided in the vertical signal lines VSL1 and VSL2, respectively.

The transfer transistors TRS1 and TRS2 are provided between the sources of the amplification transistors AMP1 and AMP2 and the capacitor elements C3 and C4, respectively. The transfer transistor TRS1 is constituted by an n-type MOSFET, for example.

The capacitor element C3 as the first capacitive element is connected between the transfer transistor TRS1 and the ground, and can accumulate the charge from the amplification transistor AMP1 via the transfer transistor TRS1. The capacitor element C4 as the second capacitive element is connected between the transfer transistor TRS2 and the ground, and can accumulate the charge from the amplification transistor AMP2 via the transfer transistor TRS2. The capacitor elements C3 and C4 are only required to include, for example, a capacitive element such as a metal-on-metal (MoM), a metal-insulator-metal (MIM), or a MOS capacitor. Therefore, the capacitor elements C3 and C4 can have sufficiently larger capacitances than the capacitor layers C1 and C2 constituted by the impurity diffusion layers, and noise generation can be suppressed.

The reset transistor RST1 is connected between the capacitor element C3 and the power supply VDD, and can perform a reset operation by discharging the charge of the capacitor element C3. The reset transistor RST2 is connected between the capacitor element C4 and the power supply VDD, and can perform a reset operation by discharging the charge of the capacitor element C4.

The source follower circuit SF1 as the first source follower circuit is connected to the capacitor element C3 via the transfer transistor TRS1 and is connected to the vertical signal line VSL1 via the selection transistor SEL1. The source follower circuit SF1 transmits a voltage corresponding to the charge amount of the capacitor element C3 to the vertical signal line VSL1.

The source follower circuit SF2 as the second source follower circuit is connected to the capacitor element C4 via the transfer transistor TRS2 and is connected to the vertical signal line VSL2 via the selection transistor SEL2. The source follower circuit SF2 transmits a voltage corresponding to the charge amount of the capacitor element C4 to the vertical signal line VSL2.

In the fifth embodiment, in the pixel 10, the capacitor elements C3 and C4 and the source follower circuits SF1 and SF2 generate signal voltages converted from signal charges, and transmit the signal voltages to the vertical signal lines VSL1 and VSL2, respectively. That is, the pixel 10 according to the fifth embodiment is a voltage domain pixel. Thus, the capacitor elements C3 and C4 are not provided in the semiconductor layer 11, and it is not necessary to accumulate charges in the semiconductor layer 11. Therefore, the area of the semiconductor layer 11 can be reduced. Thus, the dark current generated in the semiconductor layer 11 can be reduced.

### Sixth Embodiment

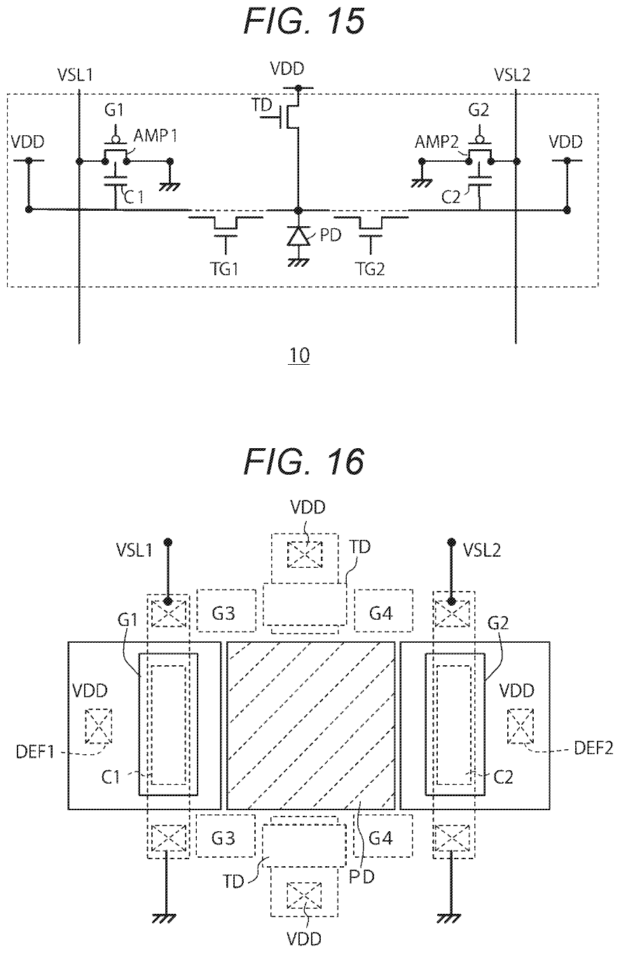

FIG. 15 is an equivalent circuit diagram illustrating an example of a configuration of the pixel 10 according to a sixth embodiment. FIG. 16 is a plan view illustrating an example of a layout of the pixel 10 according to the sixth embodiment.

In the sixth embodiment, the pixel 10 further includes transfer transistors TG1 and TG2. In the equivalent circuit, the transfer transistor TG1 is provided between the photodiode PD and the capacitor layer C1, and transfers the charge from the photodiode PD to the capacitor layer C1. The transfer transistor TG2 is provided between the photodiode PD and the capacitor layer C2, and transfers the charge from the photodiode PD to the capacitor layer C2. As illustrated in FIG. 16, in plan view as viewed from the incident direction of the light L, two transfer transistors TG1 and TG2 are provided on each of a pair of opposite sides of the photodiode PD. Thus, the potential in the photodiode PD can be inclined, and charges can be quickly collected. Further, in the present embodiment, there is no interface between the semiconductor layer 11 and the silicon oxide film in a path of the signal charge. Since the signal charge does not pass through such an interface, it is not trapped or de-trapped in the middle of the path. Therefore, the transfer transistors TG1 and TG2 can smoothly transfer signal charges. The transfer transistors TG1 and TG2 have charge collection functions among functions of the amplification transistors AMP1 and AMP2 of the second embodiment.

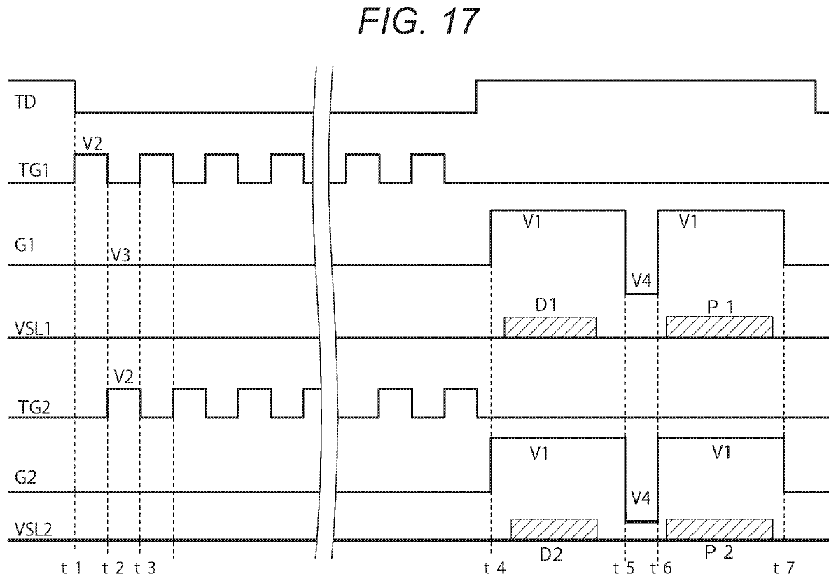

FIG. 17 is a timing chart illustrating an example of an operation of the pixel 10 according to the sixth embodiment. The transfer transistors TG1 and TG2 have charge collection functions. Therefore, in the light receiving periods t1 to t4, the gate voltages of the transfer transistors TG1 and TG2 are alternately on/off controlled by the collection voltage V2 and the low level voltage. Thus, the charge generated in the photodiode PD is distributed to the capacitor layers C1 and C2. At this time, the gate voltages of the amplification transistors AMP1 and AMP2 are maintained at the low level accumulated voltage V3, and the amplification transistors AMP1 and AMP2 accumulate charges in the capacitor layers C1 and C2.

When the light receiving periods t1 to t4 end, the charge discharge transistor TD is turned on, and charges are discharged from the photodiode PD to reset the photodiode PD.

At the same time, the read operation described with reference to FIG. 6 is executed in a readout period t4 to t7. Thus, the signal voltages D1 and D2 are output to the column processing section 23 via the vertical signal lines VSL1 and VSL2, respectively, and thereafter, the reset voltages P1 and P2 are output to the column processing section 23 via the vertical signal lines VSL1 and VSL2, respectively. The column processing section 23 executes the CDS processing using the signal voltages D1 and D2 and the reset voltages P1 and P2.

As described above, in the sixth embodiment, the number of transistors constituting each pixel 10 is increased by the quantity of the transfer transistors TG1 and TG2. However, by causing the transfer transistors TG1 and TG2 to execute the charge collection function, the gate voltages of the amplification transistors AMP1 and AMP2 do not need to be the collection voltage V2. Therefore, operation margins of the amplification transistors AMP1 and AMP2 can be expanded, and dynamic ranges of the signal voltages of the vertical signal lines VSL1 and VSL2 can be expanded. In addition, since the drive voltages of the transfer transistors TG1 and TG2 can be reduced, the power consumption can be reduced.

Other configurations of the sixth embodiment may be similar to the corresponding configurations of the second embodiment. Therefore, the sixth embodiment can also obtain the effects of the second embodiment. The sixth embodiment may be combined with another embodiment other than the second embodiment.

### Seventh Embodiment

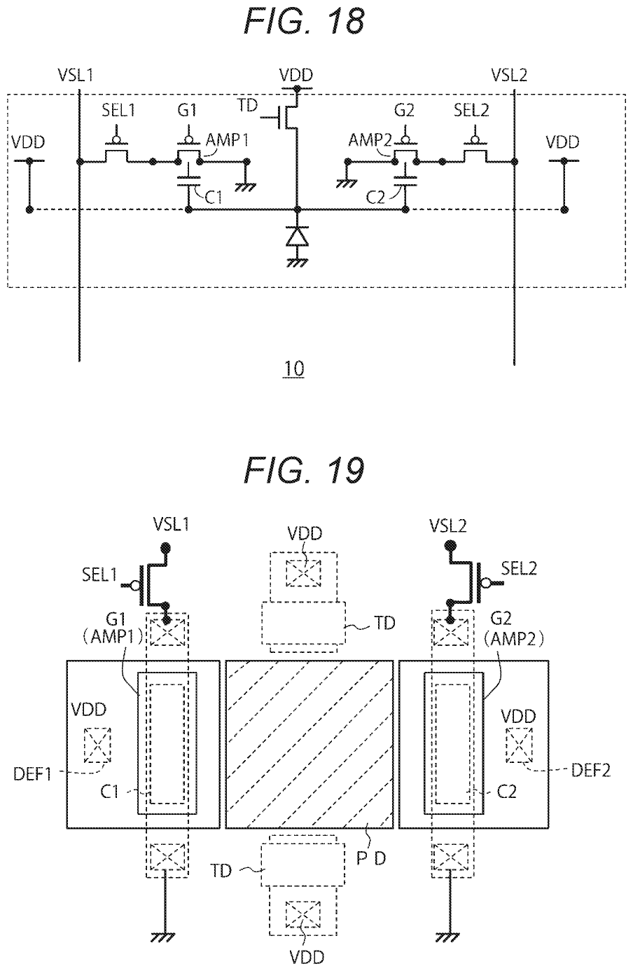

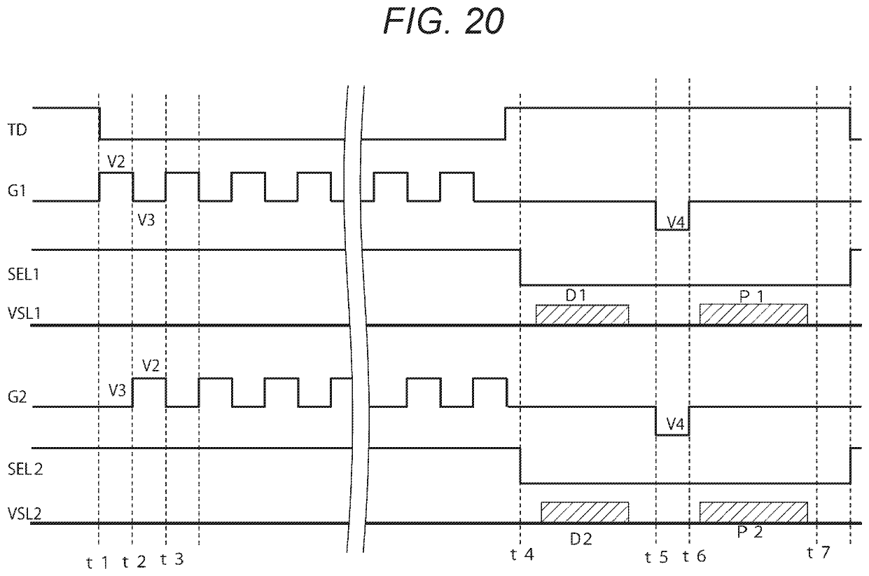

FIG. 18 is an equivalent circuit diagram illustrating an example of a configuration of the pixel 10 according to a seventh embodiment. FIG. 19 is a plan view illustrating an example of a layout of the pixel 10 according to the seventh embodiment.

In the seventh embodiment, the pixel 10 further includes the selection transistors SEL1 and SEL2. In the equivalent circuit, the selection transistor SEL1 as a first selection transistor is provided between the amplification transistor AMP1 and the vertical signal line VSL1, and connects the amplification transistor AMP1 and the vertical signal line VSL1 when the pixel 10 is selected. Thus, the selection transistor SEL1 can transmit a voltage corresponding to the conductive state of the amplification transistor AMP1 to the vertical signal line VSL1. The selection transistor SEL2 as the second selection transistor is provided between the amplification transistor AMP2 and the vertical signal line VSL2, and connects the amplification transistor AMP2 and the vertical signal line VSL2 when the pixel 10 is selected. Thus, the selection transistor SEL2 can transmit a voltage corresponding to the conductive state of the amplification transistor AMP2 to the vertical signal line VSL2. As illustrated in FIG. 19, in plan view as viewed from the incident direction of the light L, the selection transistors SEL1 and SEL2 are provided between the amplification transistors AMP1 and AMP2 and the vertical signal lines VSL1 and VSL2, respectively. The selection transistors SEL1 and SEL2 are constituted by p-type MOSFETs, for example.

FIG. 20 is a timing chart illustrating an example of an operation of the pixel 10 according to the seventh embodiment. Note that, since the selection transistors SEL1 and SEL2 are p-type MOSFETs, the selection transistors SEL1 and SEL2 perform row active switching.

The selection transistors SEL1 and SEL2 have a function of reading a signal state and a reset state. Therefore, in the light receiving periods t1 to t4, the selection transistors SEL1 and SEL2 are turned off, and the collection and accumulation operation described with reference to FIG. 6 is executed. Thereafter, in the readout period t4 to t7, the selection transistors SEL1 and SEL2 of the selected pixel 10 are turned on, and accordingly, the signal voltages D1 and D2 are read out to the vertical signal lines VSL1 and VSL2, respectively. Next, after the reset operation, the reset voltages P1 and P2 are read out to the vertical signal lines VSL1 and VSL2, respectively. The column processing section 23 executes the CDS processing using the signal voltages D1 and D2 and the reset voltages P1 and P2.

As described above, in the seventh embodiment, the number of transistors constituting each pixel 10 is increased by the quantity of the selection transistors SEL1 and SEL2. However, by independently providing the selection transistors SEL1 and SEL2, row selection in the pixel region 21 is facilitated, and crosstalk between rows can be suppressed. Thus, the distance measuring device 100 can obtain highly accurate distance measurement performance. In addition, by causing the selection transistors SEL1 and SEL2 to execute the read function, the gate voltages of the amplification transistors AMP1 and AMP2 do not need to be set to the read voltage V1. Therefore, the operation margins of the amplification transistors AMP1 and AMP2 can be expanded, and the dynamic ranges of the signal voltages of the vertical signal lines VSL1 and VSL2 can be expanded.

Other configurations of the seventh embodiment may be similar to the corresponding configurations of the second embodiment. Therefore, the seventh embodiment can also obtain the effects of the second embodiment. The seventh embodiment may be combined with another embodiment other than the second embodiment.

### Eighth Embodiment

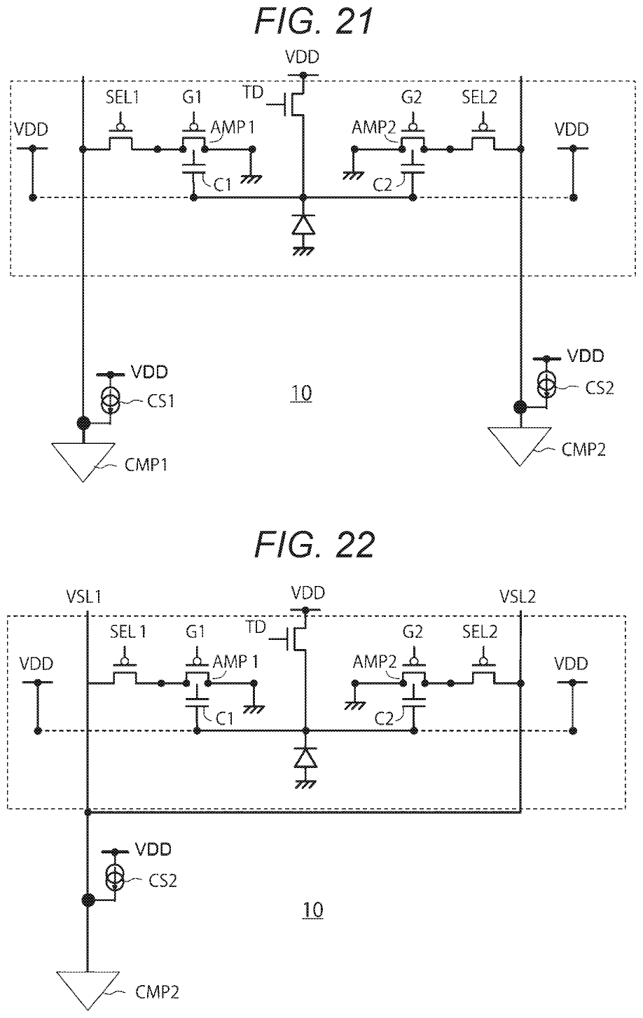

FIG. 21 is an equivalent circuit diagram illustrating an example of a configuration of the pixel 10 according to an eighth embodiment. According to the eighth embodiment, the vertical signal lines VSL1 and VSL2 are connected to the comparators CMP1 and CMP2 and the current circuits CS1 and CS2 of the third embodiment, respectively.

In the CMOS image sensor, a comparator and a constant current source may be arranged for each pixel. In this case, since the movement is for each pixel, reading can be performed in a random access manner, and there is no need to perform reading in order. Of course, the eighth embodiment may be applied to the distance measuring device 100 that simultaneously accumulates charges in all the pixels 10.

Other configurations of the eighth embodiment may be similar to the corresponding configurations of the seventh embodiment. Therefore, the eighth embodiment can also obtain the effects of the seventh embodiment. The eighth embodiment may be combined with other embodiments other than the seventh embodiment.

### Ninth Embodiment

FIG. 22 is an equivalent circuit diagram illustrating an example of a configuration of the pixel 10 according to a ninth embodiment. According to the ninth embodiment, the vertical signal lines VSL1 and VSL2 share the comparator CMP2 and the current circuit CS2, and are connected to the common comparator CMP2 and the current circuit CS2. Thus, a variation in gain and a variation in offset of the comparator are made common.

Other configurations of the ninth embodiment may be similar to the corresponding configurations of the seventh embodiment. Therefore, the ninth embodiment can also obtain the effects of the seventh embodiment. The ninth embodiment may be combined with other embodiments other than the seventh embodiment.

### Tenth Embodiment

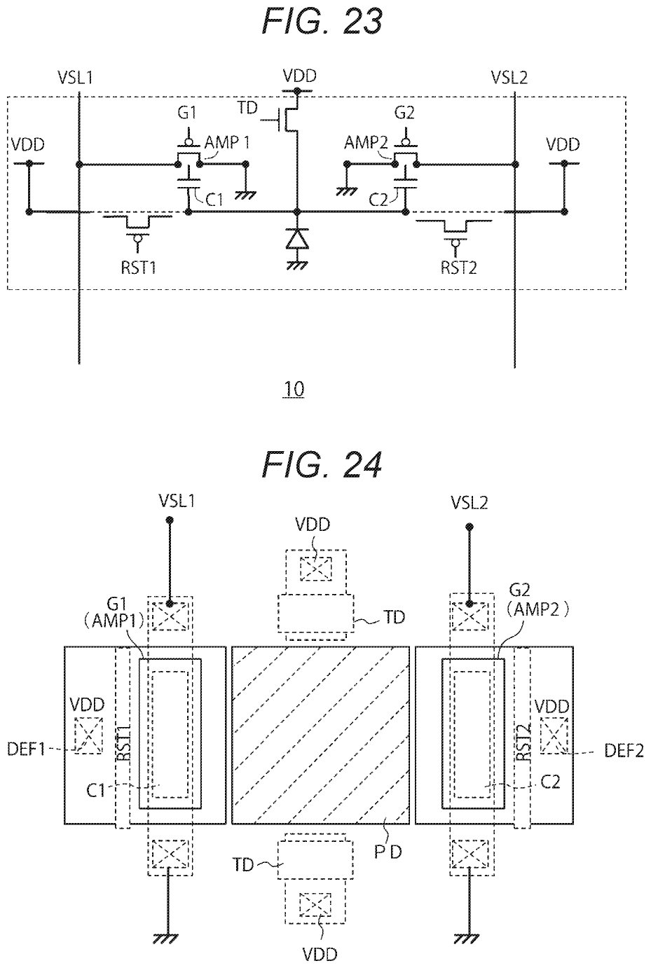

FIG. 23 is an equivalent circuit diagram illustrating an example of a configuration of the pixel 10 according to a tenth embodiment. FIG. 24 is a plan view illustrating an example of a layout of the pixel 10 according to the tenth embodiment.

In the tenth embodiment, the pixel 10 further includes reset transistors RST1 and RST2. In the equivalent circuit, the reset transistor RST1 as the first reset transistor is provided between the capacitor layer C1 and the power supply VDD, and connects the capacitor layer C1 and the power supply VDD when resetting the capacitor layer C1. Thus, the reset transistor RST1 discharges charges from the capacitor layer C1 and resets the capacitor layer C1. The reset transistor RST2 as the second reset transistor is provided between the capacitor layer C2 and the power supply VDD, and connects the capacitor layer C2 and the power supply VDD when the capacitor layer C2 is reset. Thus, the reset transistor RST2 discharges charges from the capacitor layer C2 and resets the capacitor layer C2.

As illustrated in FIG. 24, in plan view as viewed from the incident direction of the light L, the reset transistors RST1 and RST2 are arranged between the capacitor layers C1 and C2 and the power supply VDD, respectively. Since the amplification transistors AMP1 and AMP2 are immediately above the capacitor layers C1 and C2, it may be said that the reset transistors RST1 and RST2 are arranged between the amplification transistors AMP1 and AMP2 and the power supply VDD, respectively. The reset transistors RST1 and RST2 are constituted by p-type MOSFETs, for example.

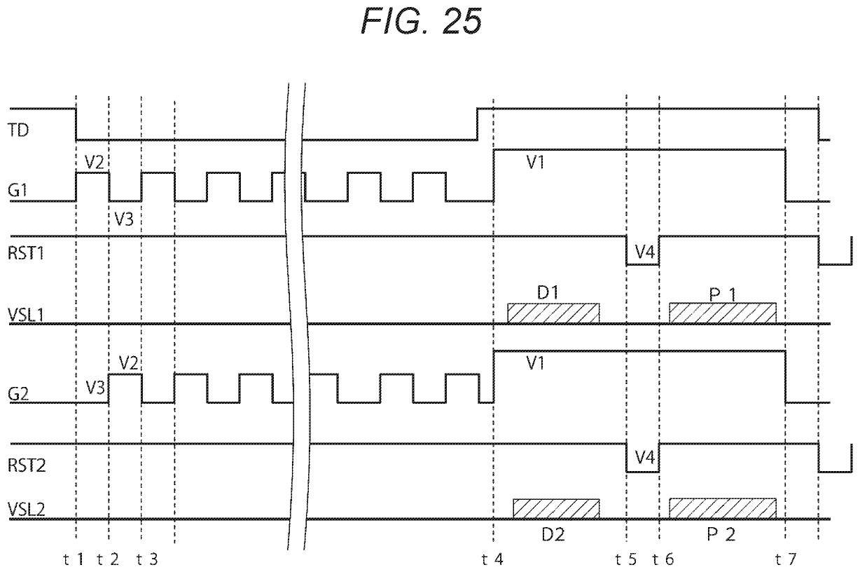

FIG. 25 is a timing chart illustrating an example of an operation of the pixel 10 according to the tenth embodiment. Note that since the reset transistors RST1 and RST2 are p-type MOSFETs, the reset transistors RST1 and RST2 perform low active switching.

The reset transistors RST1 and RST2 perform reset operation. Therefore, in the light receiving periods t1 to t4, the reset transistors RST1 and RST2 are turned off, and the collection and accumulation operation described with reference to FIG. 6 is executed. Thereafter, in the readout period t4 to t5, the amplification transistors AMP1 and AMP2 of the selected pixel 10 are turned on, so that the signal voltages D1 and D2 are read out to the vertical signal lines VSL1 and VSL2, respectively.

Next, in reset periods t5 to t6, the reset transistors RST1 and RST2 execute the reset operation. The reset transistors RST1 and RST2 discharge the charges of the capacitor layers C1 and C2 to the power supply VDD. At this time, the gate voltages of the amplification transistors AMP1 and AMP2 maintain the high level V1, and the amplification transistors AMP1 and AMP2 maintain the ON state.

Next, in the readout period t6 to t7 in the reset state, when the reset transistors RST1 and RST2 are turned off, the reset voltages P1 and P2 are read out to the vertical signal lines VSL1 and VSL2, respectively. The column processing section 23 executes the CDS processing using the signal voltages D1 and D2 and the reset voltages P1 and P2.

As described above, in the tenth embodiment, the number of transistors constituting each pixel 10 is increased the quantity of by the reset transistors RST1 and RST2. However, by causing the reset transistors RST1 and RST2 to execute the reset function, the gate voltages of the amplification transistors AMP1 and AMP2 do not need to be the reset voltage V4. Therefore, the operation margins of the amplification transistors AMP1 and AMP2 can be expanded, and the dynamic ranges of the signal voltages of the vertical signal lines VSL1 and VSL2 can be expanded. Furthermore, operation margins of the reset transistors RST1 and RST2 can be expanded.

Other configurations of the tenth embodiment may be similar to the corresponding configurations of the second embodiment. Therefore, the tenth embodiment can also obtain the effects of the second embodiment. The tenth embodiment may be combined with another embodiment other than the second embodiment.

### 11th Embodiment

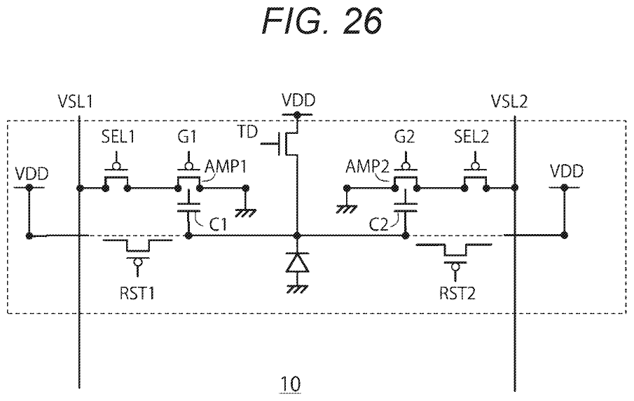

FIG. 26 is an equivalent circuit diagram illustrating an example of a configuration of the pixel 10 according to an 11th embodiment.

In the 11th embodiment, the pixel 10 further includes the selection transistors SEL1 and SEL2 and the reset transistors RST1 and RST2. That is, the 11th embodiment is a combination of the seventh and tenth embodiments. Therefore, the 11th embodiment can obtain the effects of the seventh and tenth embodiments.

Here, the amplification transistors AMP1 and AMP2, the selection transistors SEL1 and SEL2, and the reset transistors RST1 and RST2 are all constituted by p-type MOSFETs. In the present embodiment, the signal charges are electrons, and the capacitor layers C1 and C2 that accumulate the electrons are constituted by n-type impurity diffusion layers. For this reason, each channel of the amplification transistors AMP1 and AMP2, the selection transistors SEL1 and SEL2, and the reset transistors RST1 and RST2 needs to be a p-type conductivity type opposite to those of the capacitor layers C1 and C2. Therefore, the amplification transistors AMP1 and AMP2, the selection transistors SEL1 and SEL2, and the reset transistors RST1 and RST2 are all constituted by p-type MOSFETs.

A planar configuration and operation of the 11th embodiment can be easily understood from the seventh and tenth embodiments. Therefore, a plan view and a timing chart of the 11th embodiment are omitted here.

### 12th Embodiment

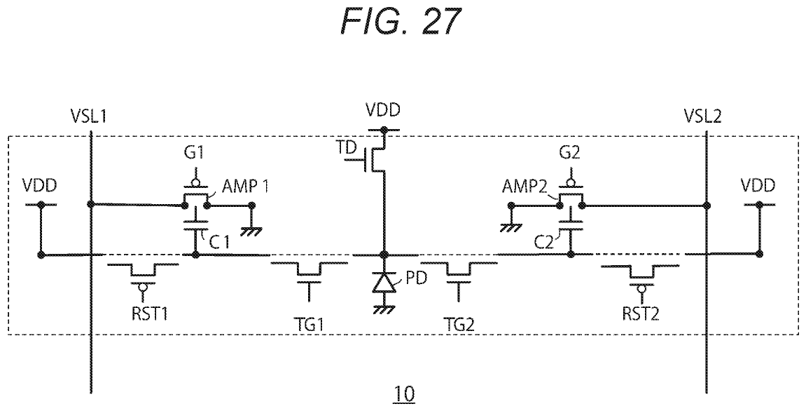

FIG. 27 is an equivalent circuit diagram illustrating an example of a configuration of the pixel 10 according to a 12th embodiment.

In the 12th embodiment, the pixel 10 further includes the transfer transistors TG1 and TG2 and the reset transistors RST1 and RST2. That is, the 12th embodiment is a combination of the sixth and tenth embodiments. Therefore, the 12th embodiment can obtain the effects of the sixth and tenth embodiments.

A planar configuration and operation of the 12th embodiment can be easily understood from the sixth and tenth embodiments. Therefore, a plan view and a timing chart of the 12th embodiment are omitted here.

### 13th Embodiment

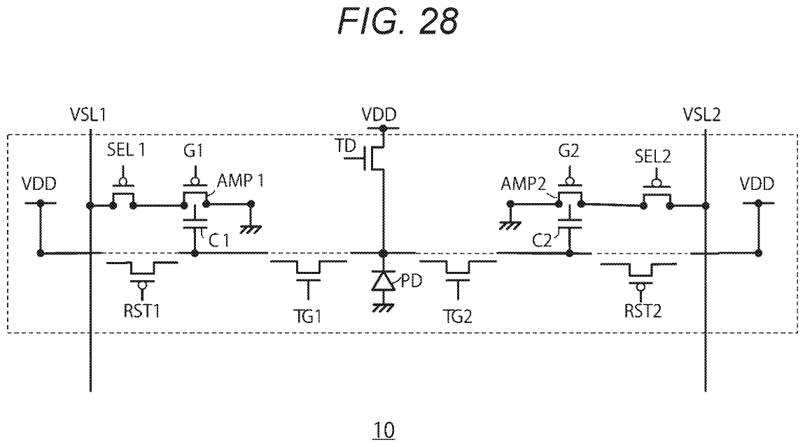

FIG. 28 is an equivalent circuit diagram illustrating an example of a configuration of the pixel 10 according to a 13th embodiment.

In the 13th embodiment, the pixel 10 further includes the transfer transistors TG1 and TG2, the reset transistors RST1 and RST2, and the selection transistors SEL1 and SEL2. That is, the 13th embodiment is a combination of the sixth, seventh, and tenth embodiments. Therefore, the 13th embodiment can obtain the effects of the sixth, seventh, and tenth embodiments.

A planar configuration and the operation of the 13th embodiment can be easily understood from the sixth, seventh, and tenth embodiments. Therefore, a plan view and a timing chart of the 13th embodiment are omitted here.

### 14th Embodiment

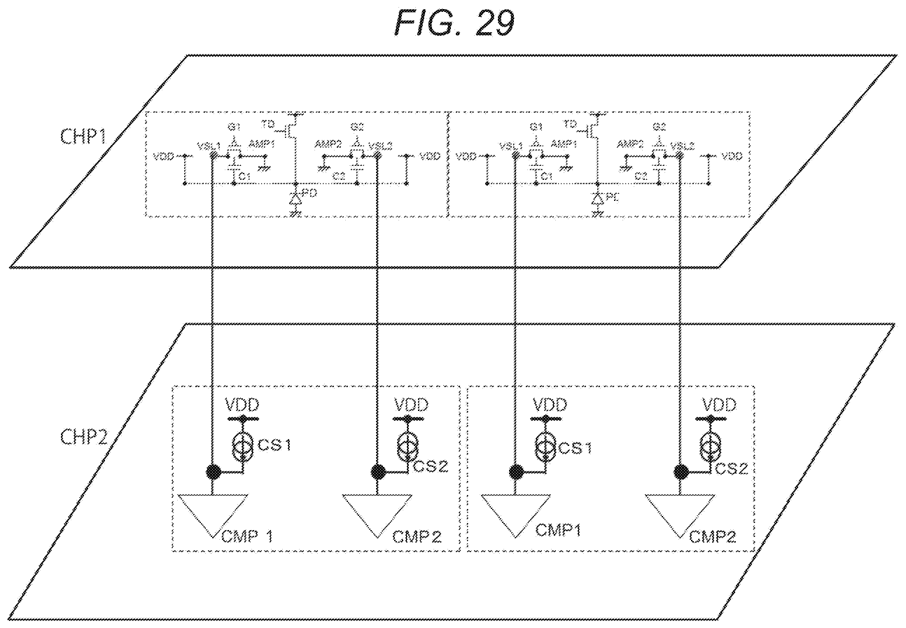

FIG. 29 is a schematic diagram illustrating a chip configuration example of the pixel 10 according to a 14th embodiment. The pixel 10 is formed in a semiconductor chip CHP1, and circuits other than the pixel 10 are formed in the semiconductor chip CHP2. That is, the distance measuring device 100 is divided into the semiconductor chips CHP1 and CHP2. The semiconductor chips CHP1, CHP2 are bonded to each other to be connected by wiring. FIG. 29 illustrates the pixel 10 according to the third embodiment.

The semiconductor chip CHP1 includes the pixel 10 including the photodiode PD, the amplification transistors AMP1 and AMP2, the capacitor layers C1 and C2, and the charge discharge transistor TD. The semiconductor chip CHP2 includes the comparators CMP1 and CMP2 and the current circuits CS1 and CS2.

The vertical signal lines VSL1 and VSL2 are respectively wired and bonded on the bonding surface between the semiconductor chip 1 and the semiconductor chip 2. For example, the amplification transistor AMP1 of the semiconductor chip CHP1 is connected to the comparator CMP1 and the current circuit CS1 of the semiconductor chip CHP2 via the wiring-joined vertical signal line VSL1. The amplification transistor AMP2 of the semiconductor chip CHP2 is connected to the comparator CMP2 and the current circuit CS2 of the semiconductor chip CHP2 via the wiring-joined vertical signal line VSL2. As described above, the semiconductor chips CHP1, CHP2 are electrically connected by joining the vertical signal lines VSL1, VSL2 of the semiconductor chips CHP1, CHP2, respectively.

In the 14th embodiment, the vertical signal lines VSL1 and VSL2 are provided for each pixel column, and are provided as many as the number of pixels 10 in one pixel column. Therefore, in the semiconductor chip CHP2, the comparators CMP1 and CMP2 and the current circuits CS1 and CS2 are also provided for each pixel column, and are provided as many as the number of pixels 10 included in one pixel column. In this manner, the comparators CMP1 and CMP2 and the current circuits CS1 and CS2 are shared by the respective pixel columns, and thus layout areas of the comparators CMP1 and CMP2 and the current circuits CS1 and CS2 are reduced. Furthermore, the comparators CMP1 and CMP2 and the current circuits CS1 and CS2 can simultaneously detect signals from the plurality of pixels 10 included in one pixel row.

The vertical signal lines VSL1 and VSL2 may be provided as many as the number of pixels 10 included in the plurality of pixel rows. In this case, the comparators CMP1 and CMP2 and the current circuits CS1 and CS2 are arranged as many as the number of pixels 10 of the plurality of pixel rows corresponding to the vertical signal lines VSL1 and VSL2.

Moreover, the vertical signal lines VSL1 and VSL2 may be provided corresponding to each pixel 10 of the semiconductor chip CHP1. In this case, the comparators CMP1 and CMP2 and the current circuits CS1 and CS2 are arranged as many as the number of pixels 10 of the semiconductor chip CHP1 corresponding to the vertical signal lines VSL1 and VSL2. In a case where the vertical signal lines VSL1 and VSL2, the comparators CMP1 and CMP2, and the current circuits CS1 and CS2 are provided for each pixel 10 of the semiconductor chip CHP1, a global shutter operation can be executed in the pixel 10 without dropping a saturation signal. Furthermore, in this case, the distance measuring device 100 can be used as a dynamic vision sensor that outputs a signal when a signal change of each pixel 10 is equal to or greater than a certain threshold value.

The 14th embodiment can also be applied to embodiments other than the second embodiment. For example, it is only required to mount the configurations of dashed line portions illustrated in FIGS. 13 to 15, 18, 21 to 23, and 26 to 28 on the semiconductor chip CHP1, and mount the other configurations of the comparator, the current circuit, and the like on the semiconductor chip CHP2.

As illustrated in FIG. 18, in a case where the selection transistors SEL1 and SEL2 are independent of the amplification transistors AMP1 and AMP2, one of the selection transistors SEL1 and SEL2 can be selectively turned on to read a signal from the pixel 10. In this case, crosstalk between the adjacent vertical signal lines VSL1 and VSL2 can be suppressed.

### 15th Embodiment

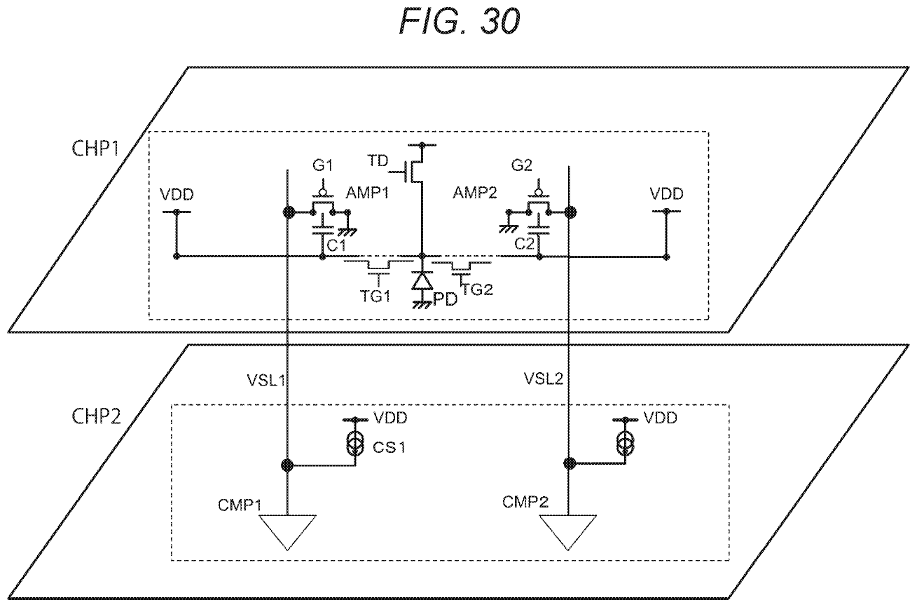

FIG. 30 is a schematic diagram illustrating a chip configuration example of the pixel 10 according to a 15th embodiment. FIG. 30 illustrates the pixel 10 according to the sixth embodiment. The semiconductor chip CHP1 includes the photodiode PD, the amplification transistors AMP1 and AMP2, the transfer transistors TG1 and TG2, the capacitor layers C1 and C2, and the charge discharge transistor TD. The semiconductor chip CHP2 includes the comparators CMP1 and CMP2 and the current circuits CS1 and CS2.

The configurations of the transfer transistors TG1 and TG2 may be similar to those of the sixth embodiment. In addition, other configurations of the 15th embodiment may be similar to those of the 14th embodiment. Therefore, in the 15th embodiment, the vertical signal lines VSL1 and VSL2, the comparators CMP1 and CMP2, and the current circuits CS1 and CS2 may be provided corresponding to each pixel column, and may be provided as many as the number of pixels 10 in one pixel column. Furthermore, the vertical signal lines VSL1 and VSL2, the comparators CMP1 and CMP2, and the current circuits CS1 and CS2 may be provided corresponding to the pixels 10 included in the plurality of pixel rows. Moreover, the vertical signal lines VSL1 and VSL2, the comparators CMP1 and CMP2, and the current circuits CS1 and CS2 may be provided corresponding to each pixel 10 of the semiconductor chip CHP1, and may be provided as many as the number of pixels 10 in the semiconductor chip CHP1.

### 16th Embodiment

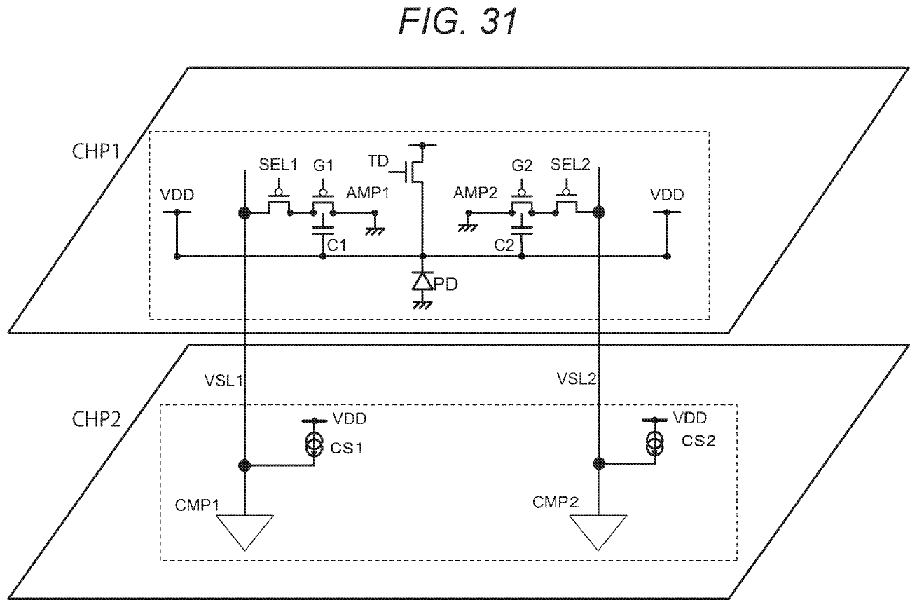

FIG. 31 is a schematic diagram illustrating a chip configuration example of the pixel 10 according to a 16th embodiment. FIG. 31 illustrates the pixel 10 according to the seventh embodiment. The semiconductor chip CHP1 includes the photodiode PD, the amplification transistors AMP1 and AMP2, the selection transistors SEL1 and SEL2, the capacitor layers C1 and C2, and the charge discharge transistor TD. The semiconductor chip CHP2 includes the comparators CMP1 and CMP2 and the current circuits CS1 and CS2.

The configurations of the selection transistors SEL1 and SEL2 may be similar to those of the seventh embodiment. In addition, other configurations of the 16th embodiment may be similar to those of the 14th embodiment. Therefore, in the 16th embodiment, the vertical signal lines VSL1 and VSL2, the comparators CMP1 and CMP2, and the current circuits CS1 and CS2 may be provided corresponding to each pixel column, and may be provided as many as the number of pixels 10 in one pixel column. Furthermore, the vertical signal lines VSL1 and VSL2, the comparators CMP1 and CMP2, and the current circuits CS1 and CS2 may be provided corresponding to the pixels 10 included in the plurality of pixel rows. Moreover, the vertical signal lines VSL1 and VSL2, the comparators CMP1 and CMP2, and the current circuits CS1 and CS2 are provided corresponding to each pixel 10 of the semiconductor chip CHP1, and may be provided as many as the number of pixels 10 in the semiconductor chip CHP1.

### 17th Embodiment

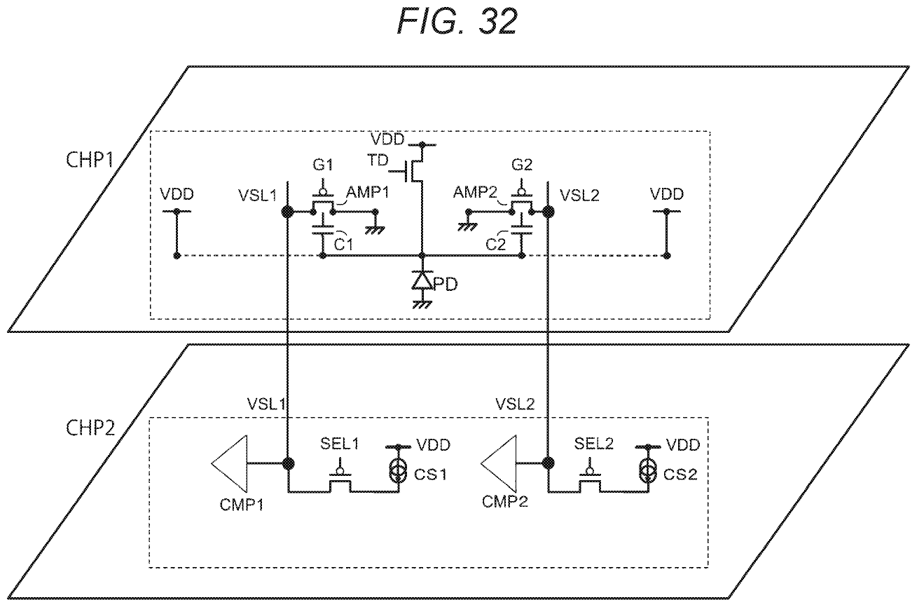

FIG. 32 is a schematic diagram illustrating a chip configuration example of the pixel 10 according to a 17th embodiment. FIG. 32 illustrates the pixel 10 according to the eighth embodiment. However, the selection transistors SEL1 and SEL2 are provided in the semiconductor chip CHP2. That is, the semiconductor chip CHP1 includes the photodiode PD, the amplification transistors AMP1 and AMP2, the capacitor layers C1 and C2, and the charge discharge transistor TD. The semiconductor chip CHP2 includes the comparators CMP1 and CMP2, the selection transistors SEL1 and SEL2, and the current circuits CS1 and CS2.

The semiconductor chip CHP2 includes the selection transistors SEL1 and SEL2 in addition to the comparators CMP1 and CMP2 and the current circuits CS1 and CS2. The selection transistor SEL1 is connected between the comparator CMP1 and the current circuit CS1, and the selection transistor SEL2 is connected between the comparator CMP2 and the current circuit CS2. Thus, the selection transistors SEL1 and SEL2 can selectively connect the current circuits CS1 and CS2 to the vertical signal lines VSL1 and VSL2 and selectively read out signals to the vertical signal lines VSL1 and VSL2. In this embodiment, the number of elements of the semiconductor chip CHP1 can be reduced while securing operation margins of the comparators (source follower circuits) CMP1 and CMP2. By providing the selection transistors SEL1 and SEL2 on the semiconductor chip CHP2, the semiconductor chip CHP1 including the pixel 10 can be miniaturized. Other configurations of the 17th embodiment may be similar to those of the 14th embodiment.

In the 17th embodiment, the vertical signal lines VSL1 and VSL2, the comparators CMP1 and CMP2, the selection transistors SEL1 and SEL2, and the current circuits CS1 and CS2 are provided corresponding to each pixel column, and may be provided as many as the number of pixels 10 in one pixel column. Furthermore, the vertical signal lines VSL1 and VSL2, the comparators CMP1 and CMP2, the selection transistors SEL1 and SEL2, and the current circuits CS1 and CS2 may be provided corresponding to the pixels 10 included in the plurality of pixel rows. Moreover, the vertical signal lines VSL1 and VSL2, the comparators CMP1 and CMP2, the selection transistors SEL1 and SEL2, and the current circuits CS1 and CS2 are provided corresponding to each pixel 10 of the semiconductor chip CHP1, and may be provided as many as the number of pixels 10 in the semiconductor chip CHP1.

### 18th Embodiment

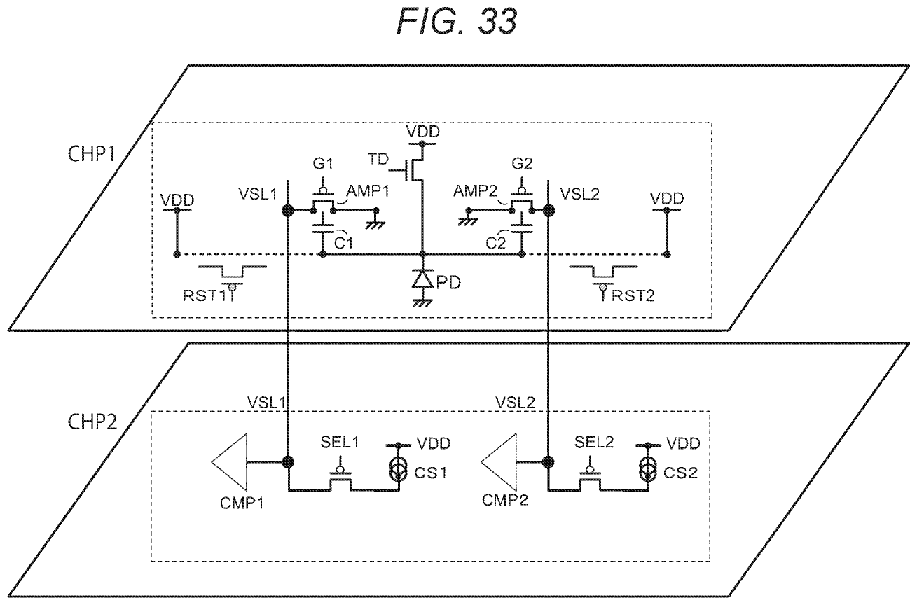

FIG. 33 is a schematic diagram illustrating a chip configuration example of the pixel 10 according to an 18th embodiment. The 18th embodiment is different from the 17th embodiment in that the reset transistors RST1 and RST2 are provided. Other configurations of the 18th embodiment may be similar to the corresponding configurations of the 17th embodiment. The configurations of the reset transistors RST1 and RST2 may be similar to those of the tenth embodiment. Therefore, the 18th embodiment can obtain the effects of the tenth and 17th embodiments (FIG. 23, FIG. 32).

### 19th Embodiment

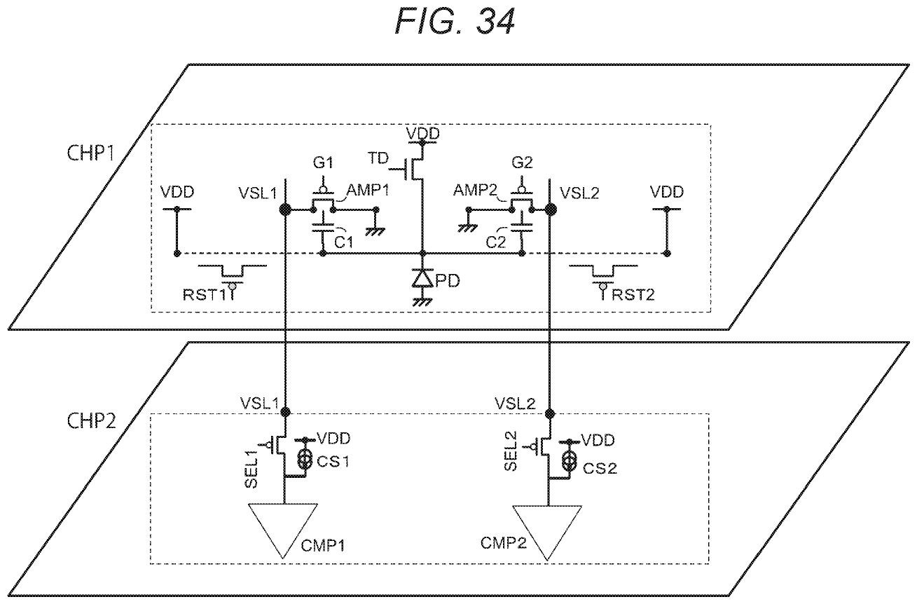

FIG. 34 is a schematic diagram illustrating a chip configuration example of the pixel 10 according to a 19th embodiment. According to the 19th embodiment, the selection transistors SEL1 and SEL2 are provided in the vertical signal lines VSL1 and VSL2, respectively. The selection transistor SEL1 is connected between the vertical signal line VSL1 and the comparator CMP1, and is connected between the vertical signal line VSL1 and the current circuit CS1. The selection transistor SEL1 electrically connects or disconnects the vertical signal line VSL1, the comparator CMP1, and the current circuit CS1. The selection transistor SEL2 is connected between the vertical signal line VSL2 and the comparator CMP2, and is connected between the vertical signal line VSL2 and the current circuit CS2. The selection transistor SEL2 electrically connects or disconnects the vertical signal line VSL2, the comparator CMP2, and the current circuit CS2.

Thus, the selection transistors SEL1 and SEL2 can selectively read signals to any one of the vertical signal lines VSL1 and VSL2. Other configurations of the 19th embodiment may be similar to the corresponding configurations of the 18th embodiment. Therefore, the 19th embodiment can also obtain the effects of the 18th embodiment.

In the 19th embodiment, the vertical signal lines VSL1 and VSL2, the selection transistors SEL1 and SEL2, the comparators CMP1 and CMP2, and the current circuits CS1 and CS2 may be provided as many as the number of pixels 10 in one pixel column corresponding to each pixel column. Furthermore, the vertical signal lines VSL1 and VSL2, the selection transistors LSE1 and SEL2, the comparators CMP1 and CMP2, and the current circuits CS1 and CS2 may be provided corresponding to the pixels 10 included in the plurality of pixel rows. Moreover, the vertical signal lines VSL1 and VSL2, the selection transistors LSE1 and SEL2, the comparators CMP1 and CMP2, and the current circuits CS1 and CS2 may be provided as many as the number of pixels 10 in the semiconductor chip CHP1, corresponding to each pixel 10 of the semiconductor chip CHP1.

### 20th Embodiment

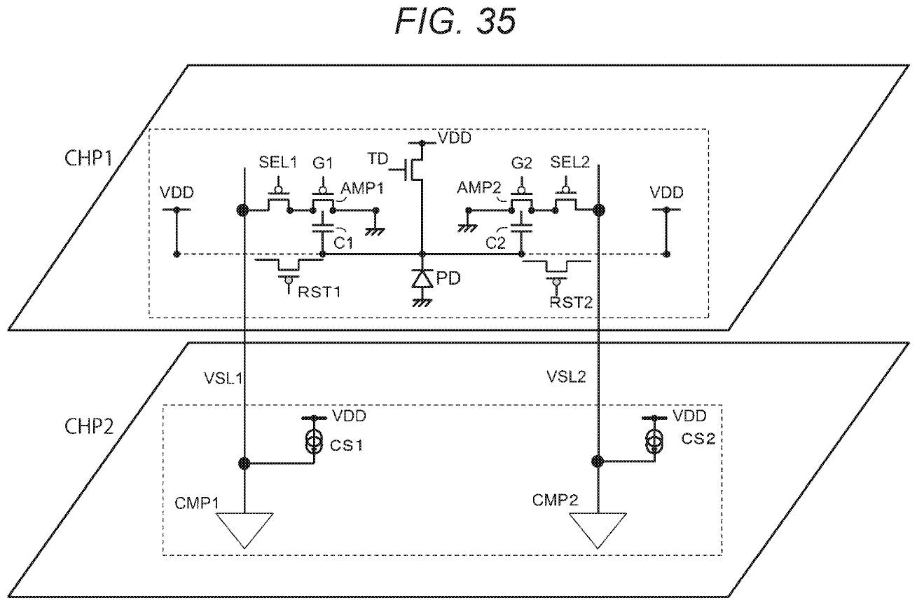

FIG. 35 is a schematic diagram illustrating a chip configuration example of the pixel 10 according to a 20th embodiment. The 20th embodiment is different from the 19th embodiment in that the selection transistors SEL and SEL2 are connected between the amplification transistors AMP1 and AMP2 and the vertical signal lines VSL1 and VSL2, respectively. In this case, the selection transistors SEL1 and SEL2 are provided in the semiconductor chip CHP1. Other configurations of the 20th embodiment may be similar to the corresponding configurations of the 19th embodiment. The 20th embodiment may be referred to as a combination of the 11th and 14th embodiments. Therefore, the 20th embodiment can obtain the effects of the 11th and 14th embodiments (FIG. 26, FIG. 29).

### 21st Embodiment

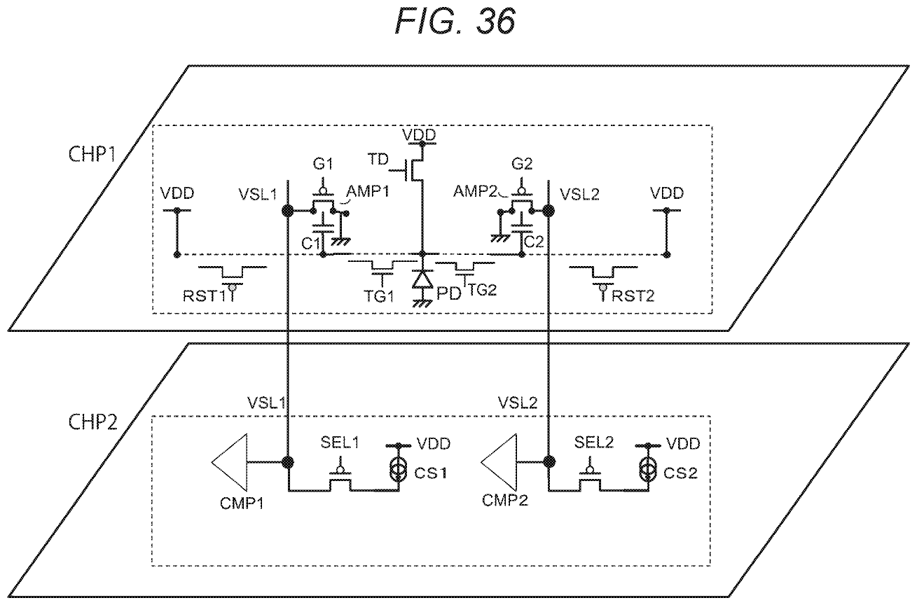

FIG. 36 is a schematic diagram illustrating a chip configuration example of the pixel 10 according to a 21st embodiment. According to the 21st embodiment, the transfer transistors TG1 and TG2 are provided between the photodiode PD and the capacitor layer C1 and between the photodiode PD and the capacitor layer C2, respectively. The selection transistors SEL1 and SEL2 are connected between the comparator CMP1 and the current circuit CS1 and between the comparator CMP2 and the current circuit CS2, respectively. That is, the 21st embodiment may be said to be a combination (FIG. 27, FIG. 33) with the 12th and 18th embodiments. Therefore, the 21st embodiment can obtain the effects of the 12th and 18th embodiments. In addition, by providing the selection transistors SEL1 and SEL2, it is possible to suppress crosstalk between the adjacent vertical signal lines VSL1 and VSL2.

In the 21st embodiment, the vertical signal lines VSL1 and VSL2, the selection transistors SEL1 and SEL2, the comparators CMP1 and CMP2, and the current circuits CS1 and CS2 may be provided as many as the number of pixels 10 in one pixel column corresponding to each pixel column. Furthermore, the vertical signal lines VSL1 and VSL2, the selection transistors SEL1 and SEL2, the comparators CMP1 and CMP2, and the current circuits CS1 and CS2 may be provided corresponding to the pixels 10 included in the plurality of pixel rows. Moreover, the vertical signal lines VSL1 and VSL2, the selection transistors ESL1 and SEL2, the comparators CMP1 and CMP2, and the current circuits CS1 and CS2 may be provided as many as the number of pixels 10 in the semiconductor chip CHP1, corresponding to each pixel 10 of the semiconductor chip CHP1.

### 22nd Embodiment

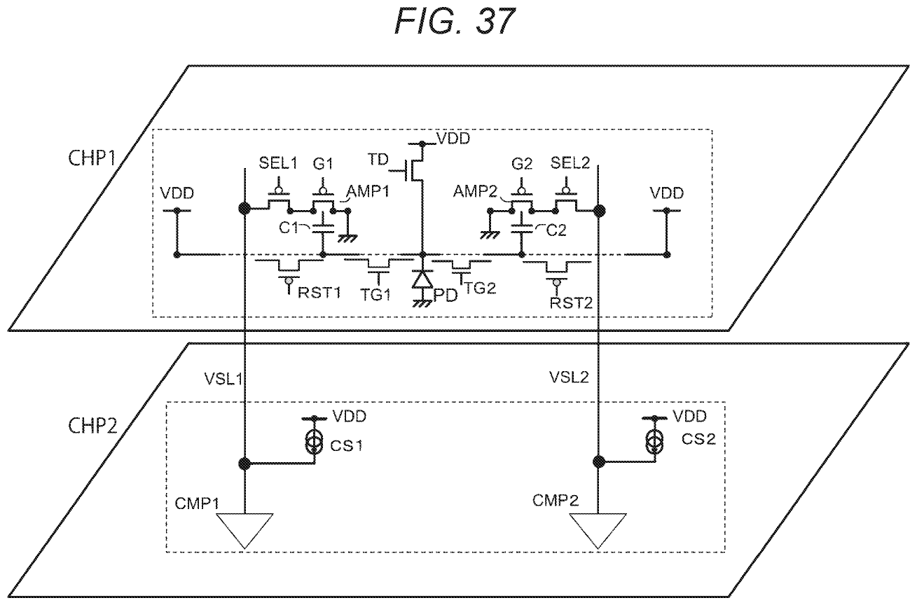

FIG. 37 is a schematic diagram illustrating a chip configuration example of the pixel 10 according to a 22nd embodiment. The 22nd embodiment is different from the 21st embodiment in that the selection transistors SEL1 and SEL2 are connected between the amplification transistors AMP1 and AMP2 and the vertical signal lines VSL1 and VSL2, respectively. In this case, the selection transistors SEL1 and SEL2 are provided in the semiconductor chip CHP1. Other configurations of the 22nd embodiment may be similar to the corresponding configurations of the 21st embodiment. The 22nd embodiment may be referred to as a combination of the 13th and 14th embodiments (FIG. 28, FIG. 29). Therefore, the 22nd embodiment can obtain the effects of the 13th and 14th embodiments.

### 23rd Embodiment

FIG. 38 is a plan view illustrating an example of a pixel array of the pixel region 21 according to a 23rd embodiment. In the pixel region 21, the pixels 10 may be arranged on the entire surface. However, as illustrated in FIG. 38, in the pixel region 21, both the pixel 10 (hereinafter, the distance measuring pixel 10) of the distance measuring device 100 and the pixel 20 (hereinafter, the imaging pixel 20) of the image sensor may be arranged in an X-Y plane. As described above, the distance measuring pixel 10 obtains four pieces of image data I (θ=0 degrees and 180 degrees) and Q (θ=90 degrees and 270 degrees) corresponding to charges obtained when the phases θ of the gate signals S_{TRG1} and S_{TRG2} with respect to the irradiation light are shifted by a predetermined value (for example, 0 degrees, 90 degrees, 180 degrees, and 270 degrees). The image data I (θ=0 degrees and 180 degrees) is two pieces of image data obtained when θ=0 degrees and 180 degrees. The image data Q (θ=90 degrees and 270 degrees) is two pieces of image data obtained when θ=90 degrees and 270 degrees. Note that the image data I (θ=0 degrees and 180 degrees) may be considered to correspond to Q (θ=0 degrees and 180 degrees) in Expression 2. Note that, although not illustrated, pixels that detect RGB of visible light receive light from a subject. However, a plurality of wavelengths of a light source (for example, an LED or the like) for performing distance measurement is prepared as a camera system. What wavelength to use is determined by the configuration of the camera system.

The imaging pixel 20 is a pixel that acquires an image of a target, is configured in, for example, a Bayer array, and detects four pieces of image data of red (R), green (Gr), green (Gb), and blue (B).

The distance measuring pixels 10 of the four pieces of image data I (θ=0 degrees and 180 degrees) and Q (θ=90 degrees and 270 degrees) are set as one distance measurement unit U10, and the imaging pixels 20 of the four pieces of image data R, Gr, Gb, and B are set as one image unit U20. In this case, in the pixel region 21, the distance measurement unit U10 and the image unit U20 are alternately two-dimensionally arranged in the same plane (X-Y plane). That is, the distance measurement unit U10 and the image unit U20 are alternately arranged in the X direction and the Y direction.

Since both the distance measuring pixel 10 and the imaging pixel 20 are included in the pixel region 21, image acquisition and distance measurement processing can be executed simultaneously.

Note that each piece of the image data R, Gr, Gb, and B is visible-light image data having a spectral peak. Although not illustrated, a channel modulation transistor may be used as the imaging pixel 20. The image data I (0=0 degrees and 180 degrees) and the image data Q (0=90 degrees and 270 degrees) may be image data by visible light or image data by infrared light (IR).

The 23rd embodiment may be combined with any of the embodiments described above.

### 24th Embodiment

FIG. 39 is a plan view illustrating an example of a pixel array of the pixel region 21 according to a 24th embodiment. In the 24th embodiment, the distance measurement unit includes a distance measurement unit 10i including distance measuring pixels of four pieces of image data I (θ=0, 180) and a distance measurement unit U10q including distance measuring pixels of four pieces of image data Q (0=90, 270). The distance measurement units U10i and U10q are alternately arranged in a staggered manner in the column direction (Y direction). In the X direction, the distance measurement units U10i and image units U20 are alternately arranged, or distance measurement units U10q and image units U20 are alternately arranged. Other configurations of the 24th embodiment including the arrangement of the image unit U20 may be the same as those of the 23rd embodiment. Therefore, similarly to the 23rd embodiment, the 24th embodiment can simultaneously execute the image acquisition and the distance measurement processing.

As described above, the distance measuring pixels of the image data I (θ=0, 180) and the distance measuring pixels of the image data Q (θ=90, 270) may be arbitrarily arranged as long as they are substantially evenly arranged in the pixel region 21. Furthermore, the distance measurement unit U10 and the image unit U20 may be arbitrarily arranged as long as they are substantially evenly arranged in the pixel region 21.

### 25th Embodiment

FIG. 40 is a plan view illustrating an example of a pixel array of the pixel region 21 according to a 25th embodiment. In the 25th embodiment, the imaging pixel 20 in the image unit U20 includes a pixel IR that detects infrared light. That is, the image unit U20 includes imaging pixels 20 of image data R (red), G (green), and B (blue) and imaging pixels 20 of IR (infrared light). Other configurations of the 25th embodiment may be the same as those of the 23rd embodiment. Therefore, in the 25th embodiment, it is possible to simultaneously execute three processes of visible light image acquisition, gold infrared light image acquisition, and distance measurement processing. The configuration of the distance measurement unit U10 of the 25th embodiment may be the same as that of the 24th embodiment.

### 26th Embodiment

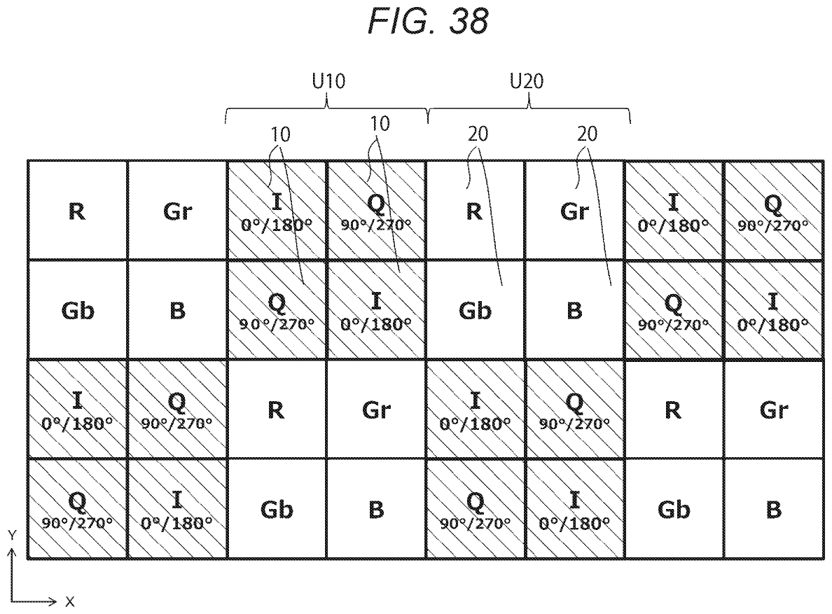

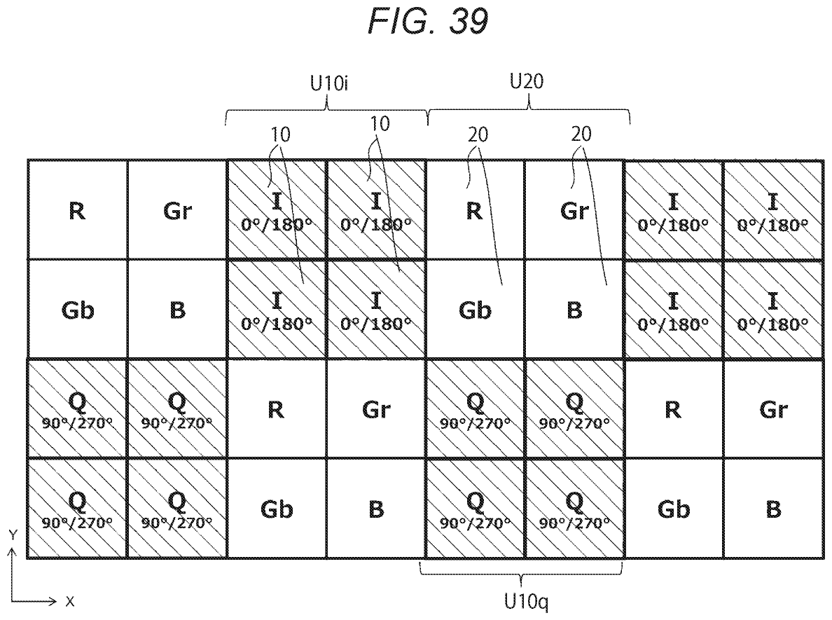

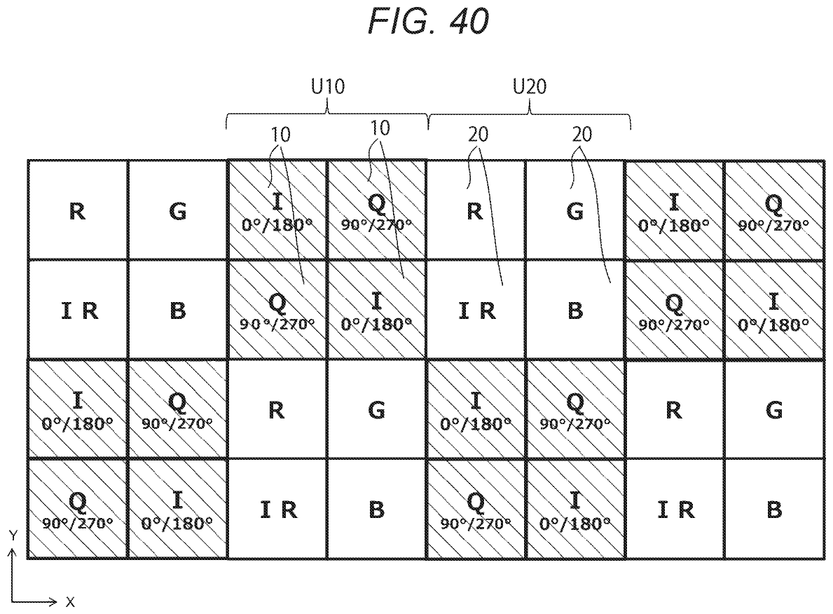

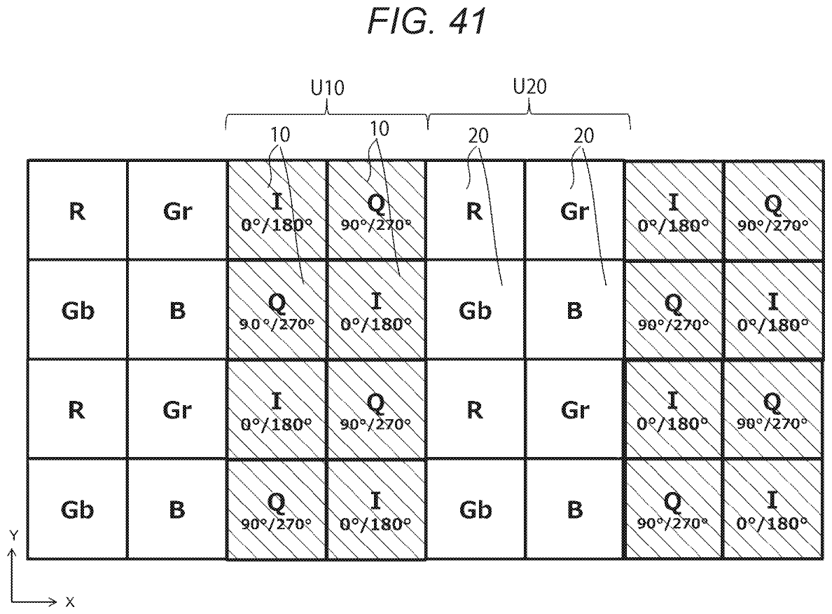

FIG. 41 is a plan view illustrating an example of a pixel array of the pixel region 21 according to a 26th embodiment. In the 26th embodiment, the distance measurement units U10 are arranged in a column in the Y direction, and the image units U20 are arranged in a column in the Y direction. The column of the distance measurement units U10 and the column of the image units U20 are alternately arranged in the X direction. Thus, the layout of the distance measurement unit U10 and the image unit U20 can be easily designed. An internal configuration of each of the distance measurement unit U10 and the image unit U20 may be the same as those of the 23rd embodiment. Other configurations of the 26th embodiment may be the same as corresponding configurations of the 23rd embodiment. Therefore, similarly to the 23rd embodiment, the 26th embodiment can simultaneously execute the image acquisition and the distance measurement processing.

### 27th Embodiment

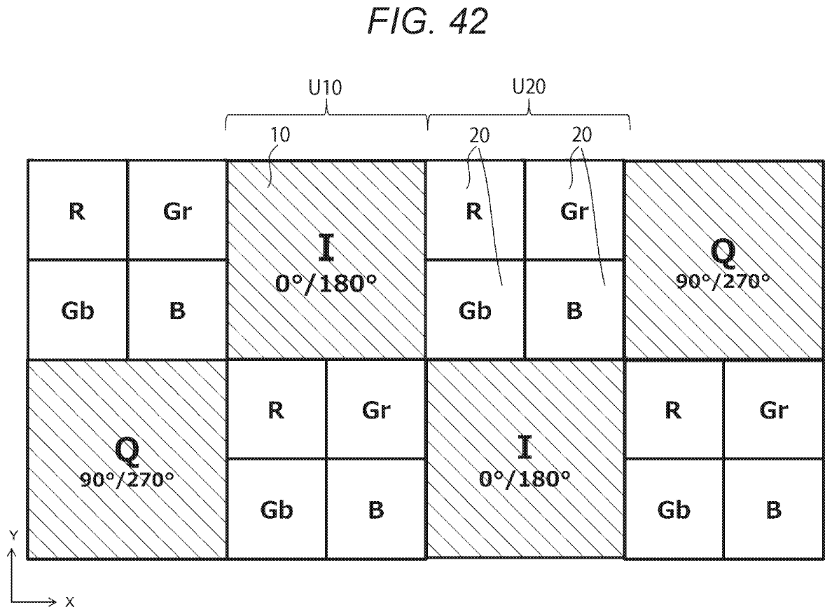

FIG. 42 is a plan view illustrating an example of a pixel array of the pixel region 21 according to a 27th embodiment. In the 27th embodiment, the areas of the distance measuring pixels of the image data I (θ=0, 180) and the distance measuring pixels of the image data Q (θ=90, 270) are larger than the areas of the respective imaging pixels 20 of the image data R (red), G (green), and B (blue). For example, in the present embodiment, the area of the distance measuring pixel 10 is substantially the same as the area of the image unit U20. Thus, the sensitivity of the distance measuring pixel 10 can be improved more than sensitivity of the imaging pixel 20. Other configurations of the 27th embodiment may be the same as the corresponding configurations of the 23rd embodiment. Therefore, similarly to the 23rd embodiment, the 27th embodiment can simultaneously execute the image acquisition and the distance measurement processing.

### 28th Embodiment

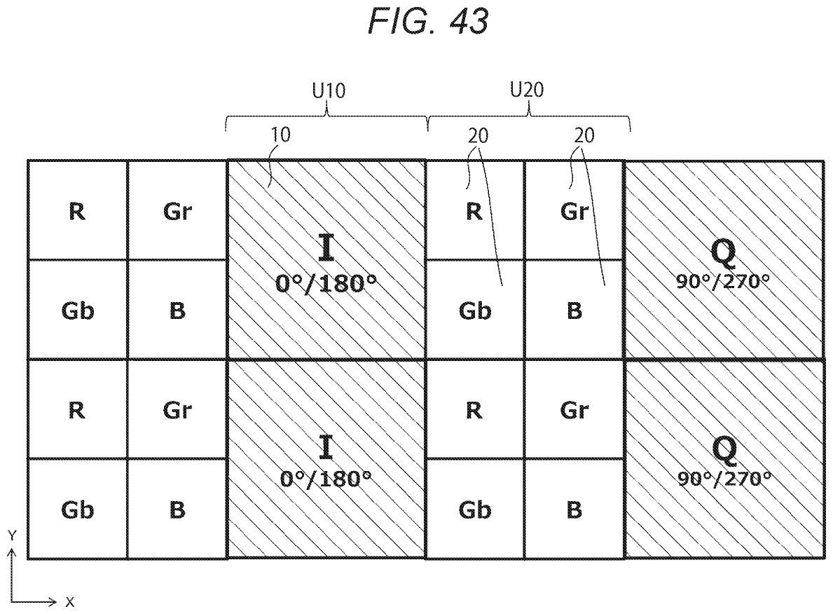

FIG. 43 is a plan view illustrating an example of a pixel array of the pixel region 21 according to a 28th embodiment. The 28th embodiment is a combination of the 26th embodiment and the 27th embodiment. Therefore, in the 28th embodiment, the distance measuring pixels 10 are arranged in a column in the Y direction, and the image units U20 are arranged in a column in the Y direction. Columns of the distance measuring pixels 10 and columns of the image units U20 are alternately arranged in the X direction. In addition, a column of the distance measuring pixels 10 of the image data I (0=0, 180) and a column of the distance measuring pixels 10 of the image data Q (0=90, 270) are arranged to alternately appear in the X direction. Moreover, the area of the distance measuring pixel 10 is larger than the area of each imaging pixel 20, and is, for example, substantially the same as the area of the image unit U20.

Thus, the layout of the distance measurement unit U10 and the image unit U20 can be easily designed, and the sensitivity of the distance measuring pixel 10 can be improved more than the sensitivity of the imaging pixel 20. Other configurations of the 26th embodiment may be the same as the corresponding configurations of the 23rd embodiment. Therefore, similarly to the 23rd embodiment, the 26th embodiment can simultaneously execute the image acquisition and the distance measurement processing.

### 29th Embodiment

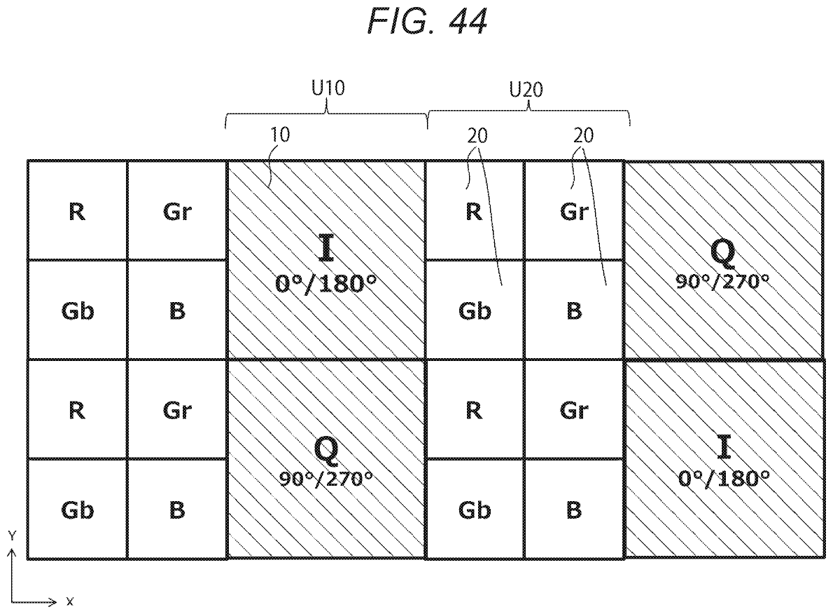

FIG. 44 is a plan view illustrating an example of a pixel array of the pixel region 21 according to a 29th embodiment. In the 29th embodiment, in the column of the distance measuring pixels 10, the distance measuring pixels 10 of the image data I (0=0, 180) and the distance measuring pixels 10 of the image data Q (0=90, 270) are alternately arranged in the Y direction. The distance measuring pixels 10 of the image data I (0=0, 180) and the distance measuring pixels 10 of the image data Q (0=90, 270) are arranged to alternately appear also in the X direction. With such an arrangement, the resolution of the distance measuring device 100 can be improved.

Other configurations of the 29th embodiment may be the same as corresponding configurations of the 28th embodiment. Therefore, similarly to the 28th embodiment, the 29th embodiment can simultaneously execute the image acquisition and the distance measurement processing.

### 30th Embodiment

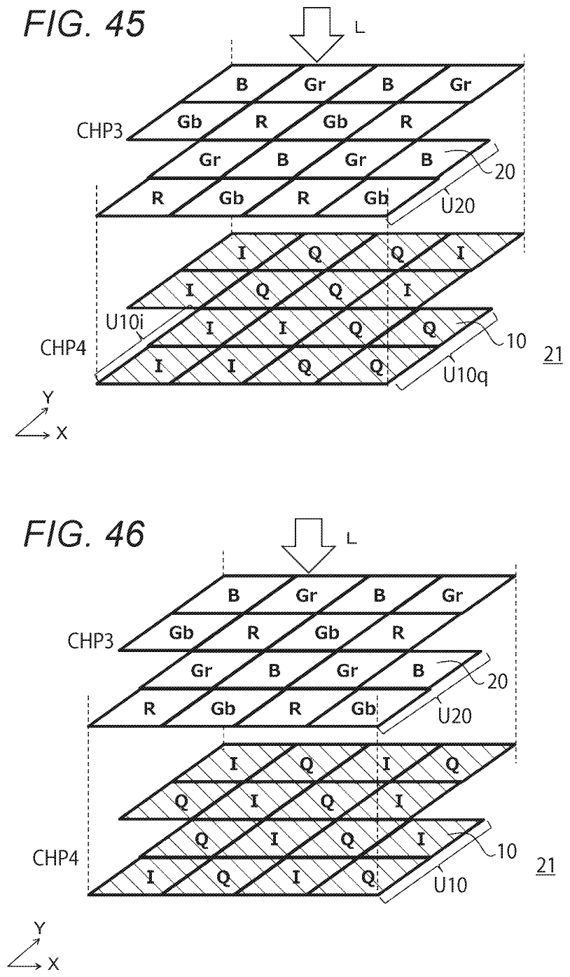

FIG. 45 is a conceptual diagram illustrating a configuration example of the pixel region 21 according to a 30th embodiment. In the 30th embodiment, the distance measuring pixels 10 and the imaging pixels 20 are arranged on semiconductor chips CHP3 and CHP4 different from each other. The imaging pixels 20 are provided on the semiconductor chip CHP3, and the distance measuring pixels 10 are provided on the semiconductor chip CHP4. In the semiconductor chip CHP3, imaging pixels similar to the image unit U20 in FIG. 39 are arranged. In the semiconductor chip CHP4, the distance measurement units U10i and U10q in FIG. 39 are alternately arranged. The semiconductor chips CHP3 and CHP4 are bonded to each other and stacked. The light L is incident from the semiconductor chip CHP3 side. The semiconductor chip CHP3 receives the light L and transmits the light L to the semiconductor chip CHP4. Thus, both the distance measuring pixels 10 and the imaging pixels 20 can detect the light L. In addition, since the semiconductor chip CHP3 receives the light L first, the imaging pixels 20 can detect visible light with low attenuation and high intensity. Thus, a spectral sensitivity characteristic of the imaging pixel 20 is improved.

In the present embodiment, the four imaging pixels 20 of the image unit U20 are stacked at substantially the same position with respect to the four distance measuring pixels 10 of the distance measurement unit U10. Therefore, the distance measuring device 100 can obtain the image data and the distance measurement data with high resolution.

Note that the light L may enter from the semiconductor chip CHP4 side. In this case, the semiconductor chip CHP4 receives the light L and transmits the light L to the semiconductor chip CHP3. Usually, an R (red) imaging pixel has a spectral sensitivity of about 650 nm, Gr and Gb (green) imaging pixels have a spectral sensitivity of about 550 nm, and a B (blue) imaging pixel has a spectral sensitivity of about 450 nm. The distance measuring pixel 10 normally detects light in an infrared region of 840 nm to 1550 nm. Therefore, by causing the light L to enter from the semiconductor chip CHP4 side of the stacked structure as in the present embodiment, the light in the infrared region is first detected in the distance measuring pixels 10, and thereafter, the visible light of the imaging pixels 20 is detected. In this case, it is possible to suppress the influence (color mixing) of the infrared light on the imaging pixel 20.

### 31st Embodiment

FIG. 46 is a conceptual diagram illustrating a configuration example of the pixel region 21 according to a 31st embodiment. In the 31st embodiment, the distance measurement units U10 in FIG. 38 are arranged in the semiconductor chip CHP4. Other configurations of the 31st embodiment including the configuration of the semiconductor chip CHP3 may be similar to the corresponding configuration of the 30th embodiment.

### 32nd Embodiment

FIG. 47 is a conceptual diagram illustrating a configuration example of the pixel region 21 according to a 32nd embodiment. In the 32nd embodiment, in the semiconductor chip CHP4, the distance measurement unit U10 in FIG. 38 and the IR (infrared light) imaging pixel 20i are alternately two-dimensionally arranged on the same plane. The IR imaging pixel 20i has substantially the same area as the distance measurement unit U10. The area of the IR imaging pixel 20i is substantially equal to the area of the distance measurement unit U10 and is larger than the area of the distance measuring pixel 10. Therefore, the distance measuring device 100 according to the present embodiment can detect near-infrared light with high sensitivity. Other configurations of the 32nd embodiment may be similar to the corresponding configurations of the 30th embodiment. According to the 32nd embodiment, it is possible to simultaneously execute three processes of the visible light image acquisition, the gold infrared light image acquisition, and the distance measurement processing.

### 33rd Embodiment

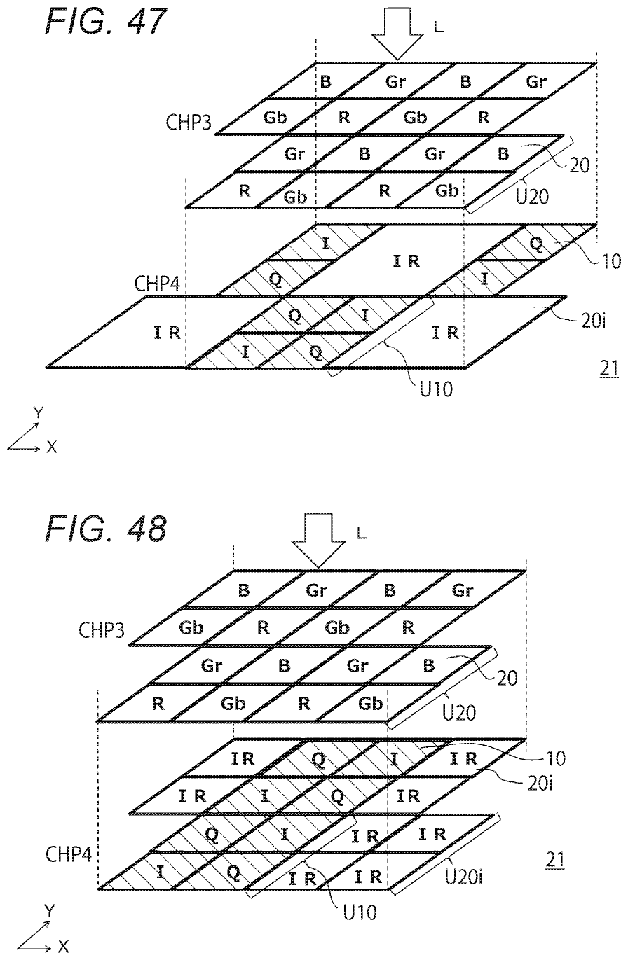

FIG. 48 is a conceptual diagram illustrating a configuration example of the pixel region 21 according to a 33rd embodiment. In the 33rd embodiment, in the semiconductor chip CHP4, the distance measurement units U10 in FIG. 38 are arranged in a column in the Y direction, and the image units U201 of infrared light (IR) are also arranged in the Y direction. The columns of the distance measurement units U10 and the columns of the IR image units U20i are alternately arranged in the X direction. By arranging in this manner, the layout of the distance measurement unit U10 and the imaging pixel 20i can be easily designed.

Other configurations of the 33rd embodiment may be similar to the corresponding configurations of the 32nd embodiment. The 33rd embodiment can obtain effects similar to those of the 32nd embodiment.

### 34th Embodiment

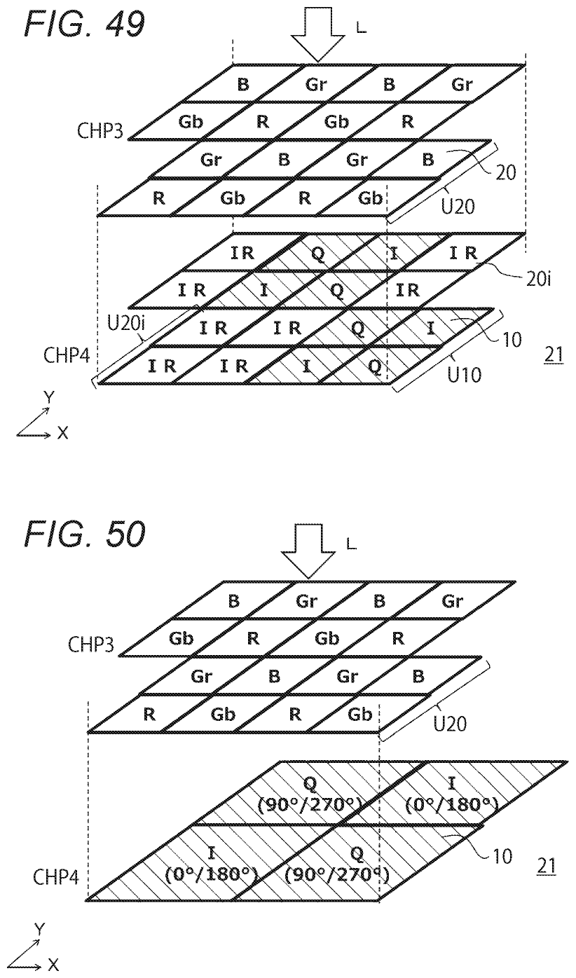

FIG. 49 is a conceptual diagram illustrating a configuration example of the pixel region 21 according to a 34th embodiment. In the 34th embodiment, in the semiconductor chip CHP4, the distance measurement unit U10 and the image units U20i of the four imaging pixels 201 are alternately arranged in the X direction and the Y direction. Since the distance measurement unit U10 and the image unit U20i are alternately arranged in the X-Y plane, the spatial resolution of the image unit U20i is improved. Other configurations of the 34th embodiment may be similar to the corresponding configurations of the 33rd embodiment. The 34th embodiment can obtain effects similar to those of the 33rd embodiment.

### 35th Embodiment

FIG. 50 is a conceptual diagram illustrating a configuration example of the pixel region 21 according to a 35th embodiment. In the 35th embodiment, in the semiconductor chip CHP4, the areas of the distance measuring pixels 10 of the image data I and the distance measuring pixels 10 of the image data Q are larger than the areas of the respective imaging pixels 20 of the image data R (red), Gr (green), and B (blue). In the present embodiment, the area of the distance measuring pixel 10 is substantially the same as the area of the image unit U20. Thus, the sensitivity of the distance measuring pixel 10 can be improved more than the sensitivity of the imaging pixel 20. Since the near-infrared light is easily attenuated, by increasing the sensitivity of the distance measuring pixel 10, the distance measuring pixel 10 can detect the near-infrared light with high sensitivity. Other configurations of the 35th embodiment may be the same as corresponding configurations of the 30th embodiment. Therefore, similarly to the 30th embodiment, the 35th embodiment can simultaneously execute the image acquisition and the distance measurement processing.

### 36th Embodiment

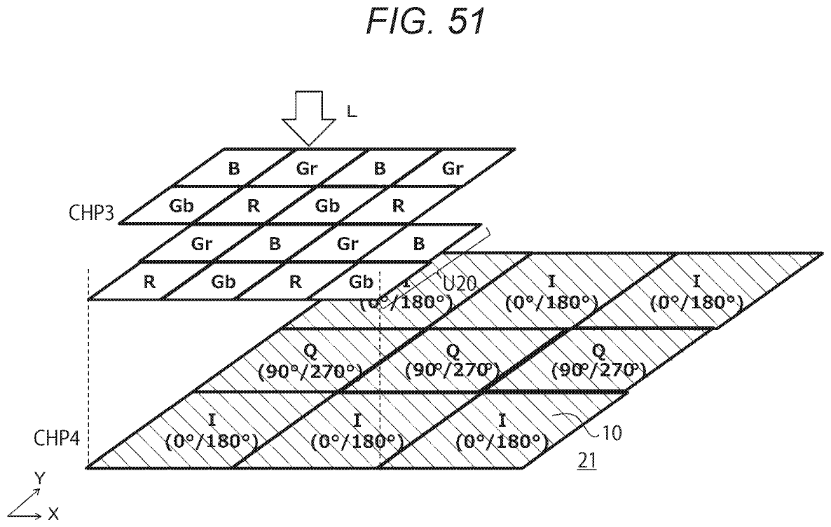

FIG. 51 is a conceptual diagram illustrating a configuration example of the pixel region 21 according to a 36th embodiment. In the 36th embodiment, in the semiconductor chip CHP4, the distance measuring pixels 10 of the image data I are arranged in the X direction, and the distance measuring pixels 10 of the image data Q are arranged in the X direction. A column of the distance measuring pixels 10 of the image data I and a column of the distance measuring pixels 10 of the image data Q appear alternately in the Y direction. Thus, the layout of the semiconductor chip CHP4 can be efficiently designed. Other configurations of the 36th embodiment may be the same as corresponding configurations of the 35th embodiment. Therefore, similarly to the 35th embodiment, the 36th embodiment can simultaneously execute the image acquisition and the distance measurement processing.

### 37th Embodiment

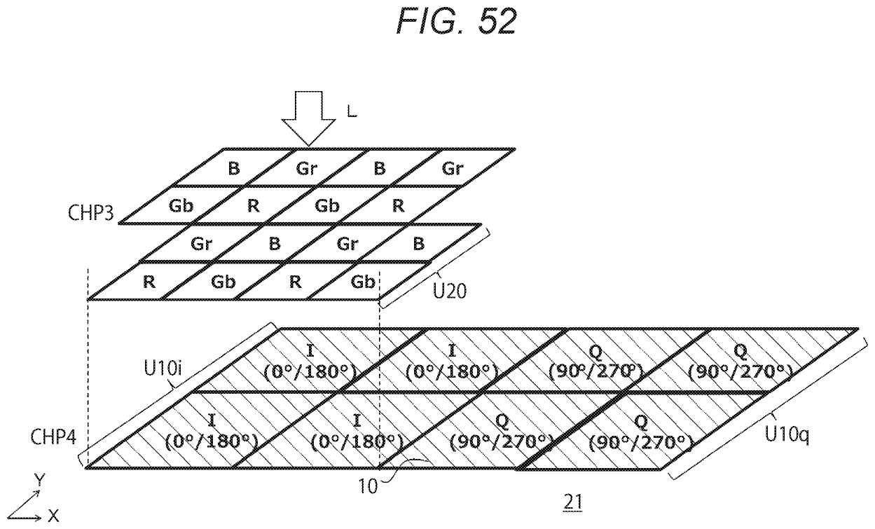

FIG. 52 is a conceptual diagram illustrating a configuration example of the pixel region 21 according to a 37th embodiment. In the 37th embodiment, in the semiconductor chip CHP4, the distance measuring pixels 10 of the image data I include 4 pixels of 2×2 to form one distance measurement unit U10i. The distance measuring pixels 10 of the image data Q include 4 pixels of 2×2 to form one distance measurement unit U10q. Although not illustrated, the distance measurement units U10I and U10q are alternately arranged in the X direction and/or the Y direction. Thus, in the semiconductor chip CHP4, the distance measurement units U10I and U10q are arranged substantially uniformly. Since the distance measurement units U10i and U10q are alternately arranged in the X-Y plane, the spatial resolution of the distance measurement units U10i and U10q is improved. Other configurations of the 37th embodiment may be the same as corresponding configurations of the 35th embodiment. Therefore, similarly to the 35th embodiment, the 37th embodiment can simultaneously execute the image acquisition and the distance measurement processing.

### 38th Embodiment

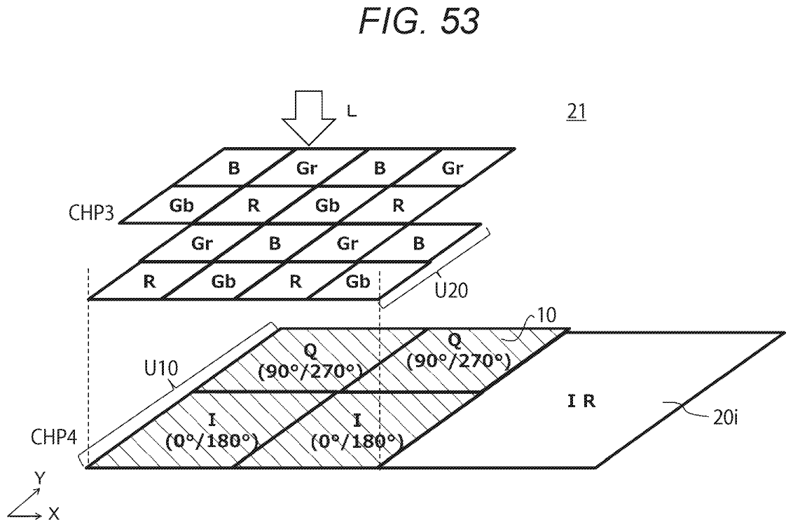

FIG. 53 is a conceptual diagram illustrating a configuration example of the pixel region 21 according to a 38th embodiment. In the 38th embodiment, in the semiconductor chip CHP4, the distance measuring pixels 10 of the two pieces of image data I and the distance measuring pixels 10 of the two pieces of image data Q form one distance measurement unit U10 including 4 pixels of 2×2. Furthermore, an IR (infrared light) imaging pixel 20i is provided in the semiconductor chip CHP4. The area of the imaging pixel 20i is larger than that of the distance measuring pixel 10 and is substantially equal to the area of the distance measurement unit U10. Thus, the distance measuring device 100 can detect near-infrared light with high sensitivity. Furthermore, the distance measuring device 100 can simultaneously execute three processes of the visible light image acquisition, the near-infrared light image acquisition, and the distance measurement processing. Other configurations of the 38th embodiment may be similar to the corresponding configurations of the 35th embodiment.

### 39th Embodiment

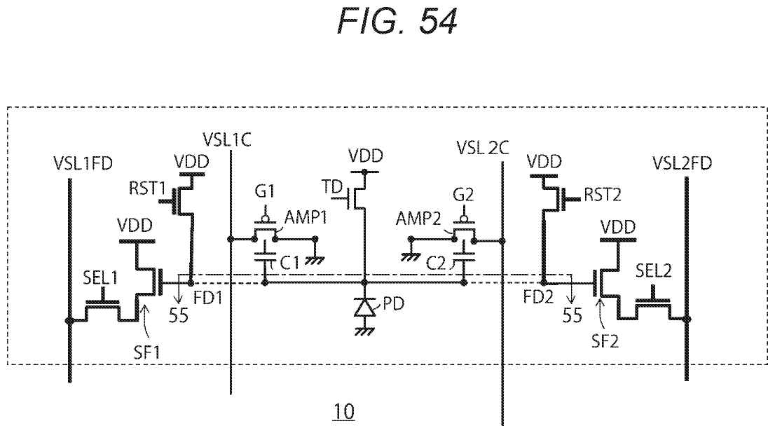

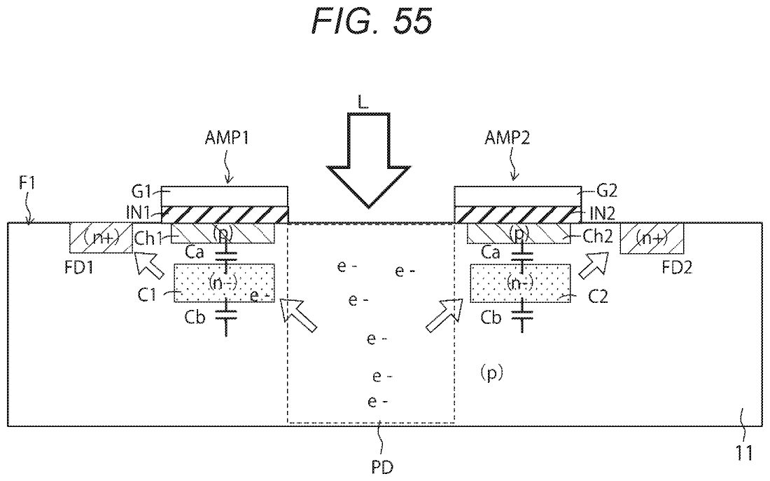

FIG. 54 is an equivalent circuit diagram illustrating a configuration example of the pixel 10 according to a 39th embodiment. FIG. 55 is a conceptual diagram illustrating an operation in a cross section taken along line 55-55 of FIG. 54. In the 39th embodiment, floating diffusion regions FD1 and FD2 are further provided, and charges from the capacitor layers C1 and C2 can be accumulated.

The reset transistors RST1 and RST2 are connected between the floating diffusion regions FD1 and FD2 and the power supply VDD, respectively. The reset transistor RST1 can perform a reset operation by discharging the charge of the floating diffusion region FD1. The reset transistor RST2 can perform a reset operation by discharging the charge of the floating diffusion region FD2.

The source follower circuits SF1 and SF2 may have the same configuration as those of the fifth embodiment. The source follower circuit SF1 is connected between the floating diffusion region FD1 and a vertical signal line VSLIFD, and can transmit a voltage corresponding to the amount of charges accumulated in the floating diffusion region FD1 to the vertical signal line VSL1FD. The source follower circuit SF2 is connected between the floating diffusion region FD2 and a vertical signal line VSL2FD, and can transmit a voltage corresponding to the amount of charges accumulated in the floating diffusion region FD2 to the vertical signal line VSL2FD.

Moreover, the amplification transistor AMP1 is connected between the ground and a vertical signal line VSLIC, and can transmit a voltage corresponding to the amount of charges accumulated in the capacitor layer C1. The amplification transistor AMP2 is connected between the ground and a vertical signal line VSL2C, and can transmit a voltage corresponding to the amount of charges accumulated in the capacitor layer C2.

As described above, the present embodiment includes the floating diffusion regions FD1 and FD2 in addition to the capacitor layers C1 and C2. The floating diffusion regions FD1 and FD2 may accumulate charges overflowing from the capacitor layers C1 and C2, respectively, in a case where the capacitor layers C1 and C2 are filled with charges. Alternatively, the floating diffusion regions FD1 and FD2 may accumulate the charges transferred from the capacitor layers C1 and C2, respectively.

In a case where the capacitor layers C1 and C2 accumulate the charges overflowing from the capacitor layers C1 and C2, respectively, it can be considered that the capacitances of the floating diffusion regions FD1 and FD2 are added to the capacitances of the capacitor layers C1 and C2, respectively. Therefore, the pixel 10 can generate a signal corresponding to a large amount of light, and can substantially expand the dynamic range. In this case, the column processing section 23 is only required to execute signal processing using signals from the vertical signal lines VSL1FD and VSL2FD.

Furthermore, in a case where the floating diffusion regions FD1 and FD2 accumulate the charges transferred from the capacitor layers C1 and C2, after the charges are transferred to the floating diffusion regions FD1 and FD2, the capacitor layers C1 and C2 can newly accumulate the charges. Therefore, the floating diffusion regions FD1 and FD2 and the capacitor layers C1 and C2 can output individual signals from the vertical signal lines VSL1FD and VSL2FD and the vertical signal lines VSLIC and VSL2C. In this case, four types of signals are detected at a time. By changing frequencies in the first accumulation operation and the next accumulation operation in the capacitor layers C1 and C2, the distance measurement range can be expanded.

Also in the present embodiment, since the capacitor layers C1 and C2 are used, effects similar to those of the first embodiment can be obtained.

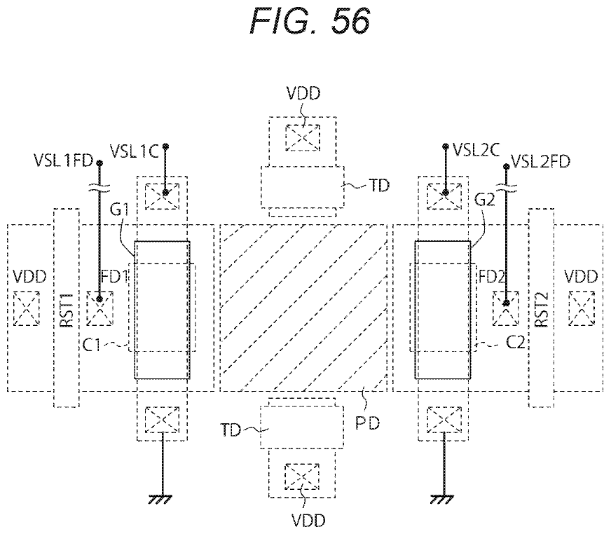

FIG. 56 is a plan view illustrating an example of a layout of the pixel 10 according to the 39th embodiment. In the 39th embodiment, the floating diffusion regions FD1 and FD2 are provided on the surface of the semiconductor substrate 11 between the capacitor layers C1 and C2 and the reset transistors RST1 and RST2. Other layouts of the pixel 10 of the 39th embodiment may be the same as the layout (FIG. 24) of the tenth embodiment.

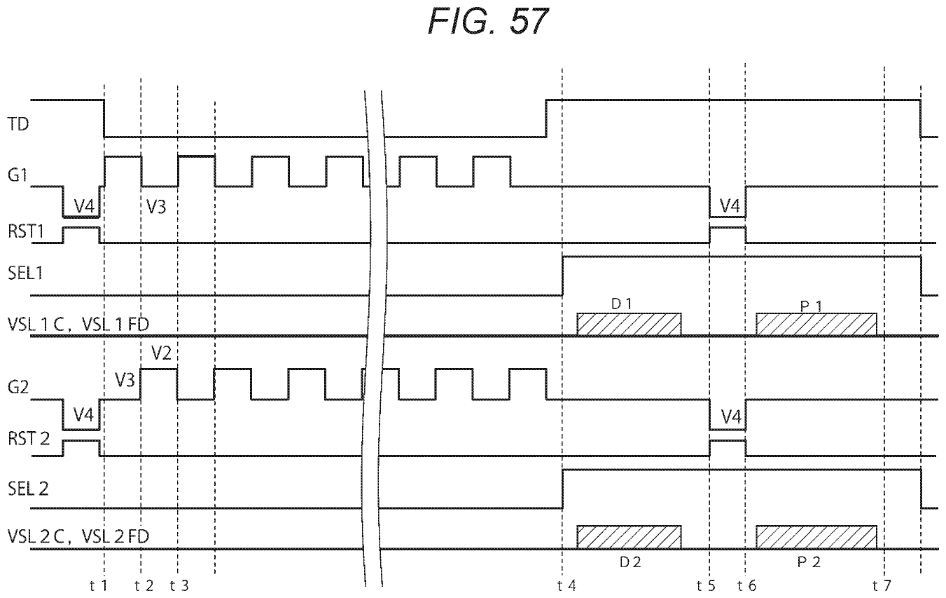

FIG. 57 is a timing chart illustrating an example of an operation of the pixel 10 according to the 39th embodiment. FIG. 57 illustrates an operation example in a case where the capacitor layers C1 and C2 accumulate charges overflowing from the capacitor layers C1 and C2, respectively.

Before t1, by turning on the reset transistors RST1 and RST2, the charges of the floating diffusion regions FD1 and FD2 are removed, and the floating diffusion regions FD1 and FD2 are reset. In addition, a large negative reset voltage V4 is applied to the gate electrodes G1 and G2 to reset the capacitor layers C1 and C2.

Thereafter, operations of t1 to t7 may be basically the same as corresponding operations of the tenth embodiment (FIG. 25). However, in the present embodiment, charges are first distributed and accumulated in the capacitor layers C1 and C2 from t1 to t4. When the capacitor layers C1 and C2 are filled with charges, the signal charge having overflowed the capacitor layer C1 is accumulated in the floating diffusion region FD1, and the signal charge having overflowed the capacitor layer C2 is accumulated in the floating diffusion region FD2. As described above, since the floating diffusion regions FD1 and FD2 are added to the capacitor layers C1 and C2, respectively, the capacitor layers C1 and C2 and the floating diffusion regions FD1 and FD2 can accumulate large signal charges as compared with the embodiment described above.

For example, it is assumed that the capacitor layers C1 and C2 accumulate signal charges Qla and Q2a, respectively, and the floating diffusion regions FD1 and FD2 accumulate signal charges Q1b and Q2b, respectively. In this case, the pixel 10 can output the signal voltage D1 corresponding to the signal charge Qla+Q1b and the signal voltage D2 corresponding to the signal charge Q2a+Q2b.

In a case where the signal charges are relatively small, the capacitor layers C1 and C2 do not overflow, and the signal charges Q1b and Q2b of the floating diffusion regions FD1 and FD2 become zero. In this case, the signals are detected only by the signal charges Qla and Q2a. Therefore, even if the signal state is detected before the reset state, the CDS processing can be performed as in the embodiment described above, and an accurate signal component with less kTC noise can be generated. On the other hand, in a case where the signal charges are large, the capacitor layers C1 and C2 overflow, and the signal charges Q1b and Q2b are accumulated in the floating diffusion regions FD1 and FD2. In this case, the signal charges Qla+Q1b and Q2a+Q2b become large, and thus the influence of kTC noise is small. Therefore, even if the signal state is detected before the reset state, a signal component having a small influence of kTC noise can be generated by the CDS processing.

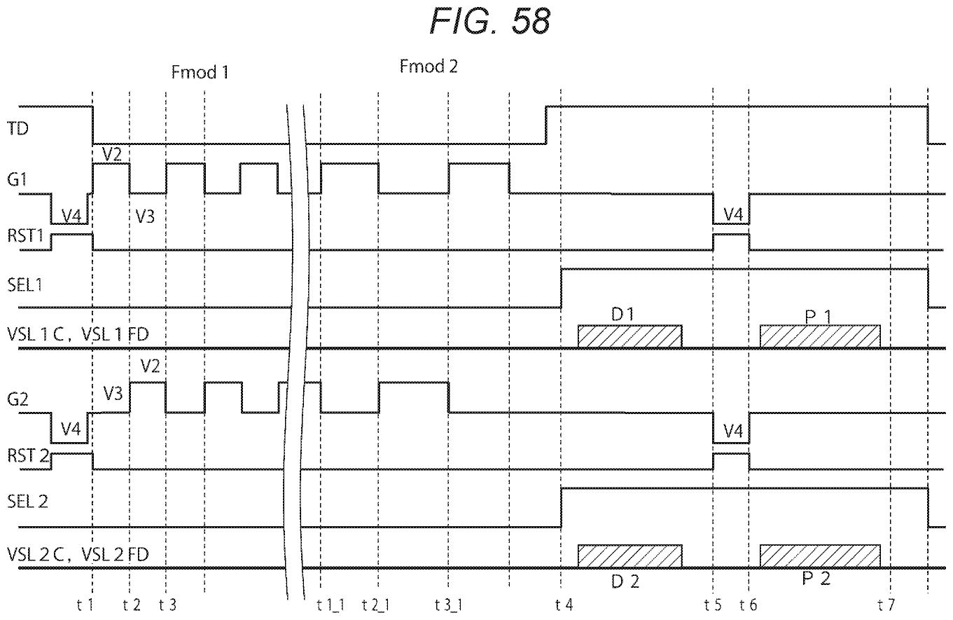

FIG. 58 is a timing chart illustrating another example of the operation of the pixel 10 according to the 39th embodiment. FIG. 58 illustrates an operation example in a case where the floating diffusion regions FD1 and FD2 accumulate the charges transferred from the capacitor layers C1 and C2.

As described with reference to FIG. 57, before t1, the floating diffusion regions FD1 and FD2 and the capacitor layers C1 and C2 are reset. Thereafter, the operations of t1 to t3 and t4 to t7 may be basically the same as the operation of FIG. 57. However, in FIG. 58, the signal charges of the capacitor layers C1 and C2 accumulated in t1 to t3 are transferred to the floating diffusion regions FD1 and FD2. Thereafter, in t1_1 to t3_1, signal charges are accumulated in the capacitor layers C1 and C2 at frequencies different from t1 to t3.

For example, in t1 to t3, charges are distributed to the capacitor layers C1 and C2 at a frequency Fmod1=100 MHZ. After accumulation at the frequency Fmod1, the signal charges of the capacitor layers C1 and C2 are transferred to the floating diffusion regions FD1 and FD2.

Next, in t1_1 to t3_1, charges are distributed to the capacitor layers C1 and C2 at a frequency Fmod2=20 MHz. After accumulation at the frequency Fmod1, the capacitor layers C1 and C2 accumulate the signal charges.

From t4 to t7, the vertical signal lines VSLIC and VSL2C and the vertical signal lines VSL1FD and VSL2FD may sequentially or simultaneously read the signal charges of the capacitor layers C1 and C2 and the floating diffusion regions FD1 and FD2. In this case, the read time is shortened.

Alternatively, the vertical signal lines VSL1FD and VSL2FD read the first signal charges of the floating diffusion regions FD1 and FD2, and then transfer the signal charges of the capacitor layers C1 and C2 to the floating diffusion regions FD1 and FD2. Moreover, the vertical signal lines VSL1FD and VSL2FD may read signal charges subsequent to the floating diffusion regions FD1 and FD2. In this case, since the read paths of the signals are the same, a variation between the first signal and the next signal is reduced.

In this manner, signals of a plurality of frequencies are obtained in one read operation. Therefore, the distance measurement range in iToF can be expanded. For example, when the frequency Fmod1=100 MHZ, the distance measurement range of the distance measuring device 100 is about 1.5 m. When the frequency Fmod2=20 MHz, the distance measurement range of the distance measuring device 100 is about 7.5 m.

### 40th Embodiment

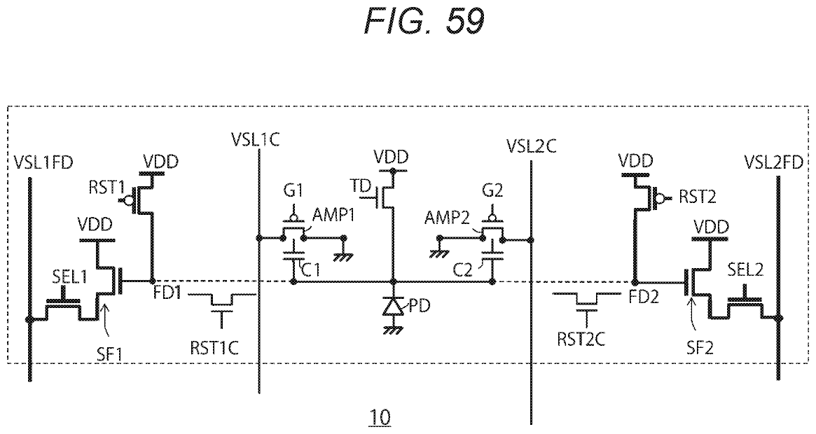

FIG. 59 is an equivalent circuit diagram illustrating a configuration example of the pixel 10 according to a 40th embodiment. In the 40th embodiment, the pixel 10 further includes reset transistors RST1C and RST2C. In the equivalent circuit, the reset transistor RST1C is provided between the capacitor layer C1 and the floating diffusion region FD1. The reset transistor RST1C connects the capacitor layer C1 and the power supply VDD via the floating diffusion region FD1 and the reset transistor RST1 when the capacitor layer C1 is reset. Thus, the reset transistor RST1C discharges the charge from the capacitor layer C1 and resets the capacitor layer C1. The reset transistor RST2C is provided between the capacitor layer C2 and the floating diffusion region FD2, and connects the capacitor layer C2 and the power supply VDD via the floating diffusion region FD2 and the reset transistor RST2 when the capacitor layer C2 is reset. Thus, the reset transistor RST2C discharges the charge from the capacitor layer C2 and resets the capacitor layer C2. Other configurations of the present embodiment may be similar to corresponding configurations of the 39th embodiment.

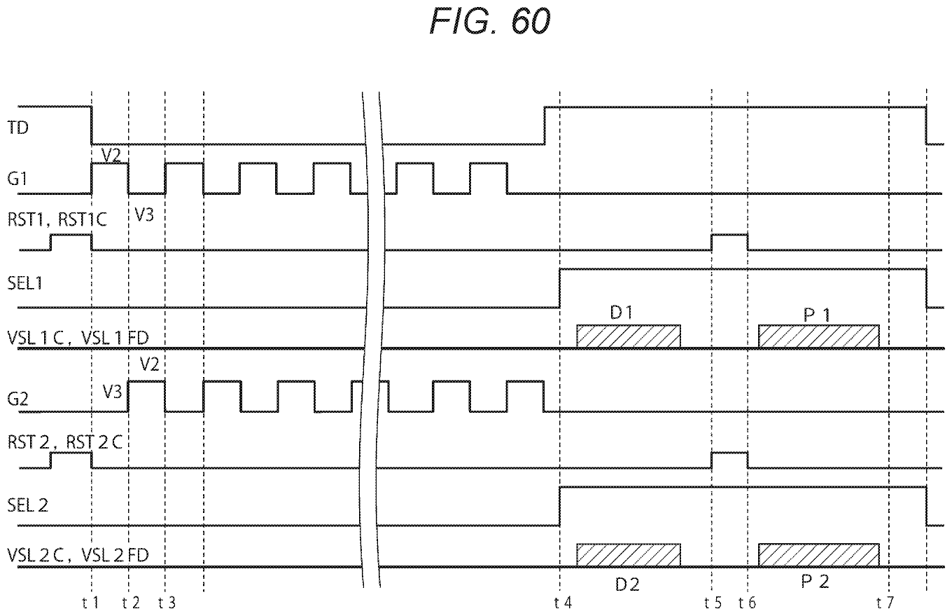

FIG. 60 is a timing chart illustrating an example of an operation of the pixel 10 according to the 40th embodiment. FIG. 60 illustrates an operation example in a case where the capacitor layers C1 and C2 accumulate charges overflowing from the capacitor layers C1 and C2, respectively. FIG. 61 is a timing chart illustrating another example of the operation of the pixel 10 according to the 40th embodiment. FIG. 61 illustrates an operation example in a case where the floating diffusion regions FD1 and FD2 accumulate the charges transferred from the capacitor layers C1 and C2. That is, FIG. 60 illustrates an example in which the embodiment of FIG. 57 of the 39th embodiment is applied to the 40th embodiment, and FIG. 61 illustrates an example in which the embodiment of FIG. 58 of the 40th embodiment is applied to the 40th embodiment.

The reset transistors RST1, RST2, RST1C, and RST2C remove the charges of the capacitor layers C1 and C2 and the floating diffusion regions FD1 and FD2 and reset the capacitor layers C1 and C2 and the floating diffusion regions FD1 and FD2 in advance before t1. Thereafter, the collection operation, the accumulation operation, and the read operation from t1 to t5 are similar to those illustrated in FIG. 57 or 58 of the 39th embodiment.

Next, in the reset period t5 to t6, the reset transistors RST1, RST2, RST1C, and RST2C execute the reset operation. The reset transistors RST1 and RST2 discharge the charges of the floating diffusion regions FD1 and FD2 to the power supply VDD. The reset transistors RST1C and RST2C discharge the charges of the capacitor layers C1 and C2 to the power supply VDD via the floating diffusion regions FD1 and FD2.

The next read operation from t6 to t7 may be similar to the operation illustrated in FIG. 57 or 58 of the 39th embodiment. Therefore, the 40th embodiment can obtain effects similar to those of the 39th embodiment.

Furthermore, in the 40th embodiment, by causing the reset transistors RST1 and RST2 to execute the reset function, the voltages of the gate electrodes G1 and G2 of the amplification transistors AMP1 and AMP2 do not need to be set to the reset voltage V4. Therefore, the operation margins of the amplification transistors AMP1 and AMP2 can be expanded, and the dynamic ranges of the signal voltages of the vertical signal lines VSL1 and VSL2 can be expanded. Furthermore, the operation margins of the reset transistors RST1 and RST2 can be expanded.

The 39th embodiment may be combined with other embodiments. For example, the pixel 10 of the 39th embodiment may further include the transfer transistors TF1 and TG2 of FIG. 15. The pixel 10 of the 39th embodiment may further include the selection transistors SEL1 and SEL2 of FIG. 18. Moreover, the pixel 10 according to the 39th embodiment may include two or more transistors of the reset transistors RST1C and RST2C, the transfer transistors TF1 and TG2, and the selection transistors SEL1 and SEL2. Thus, the distance measuring device 100 of the 39th embodiment can also obtain each effect.

In the above embodiment, channel modulation transistors by the capacitor layers C1 and C2 are used as the amplification transistors AMP1 and AMP2. On the other hand, in the following embodiment, a CCD element is used for accumulating signal charges.

### 41st Embodiment

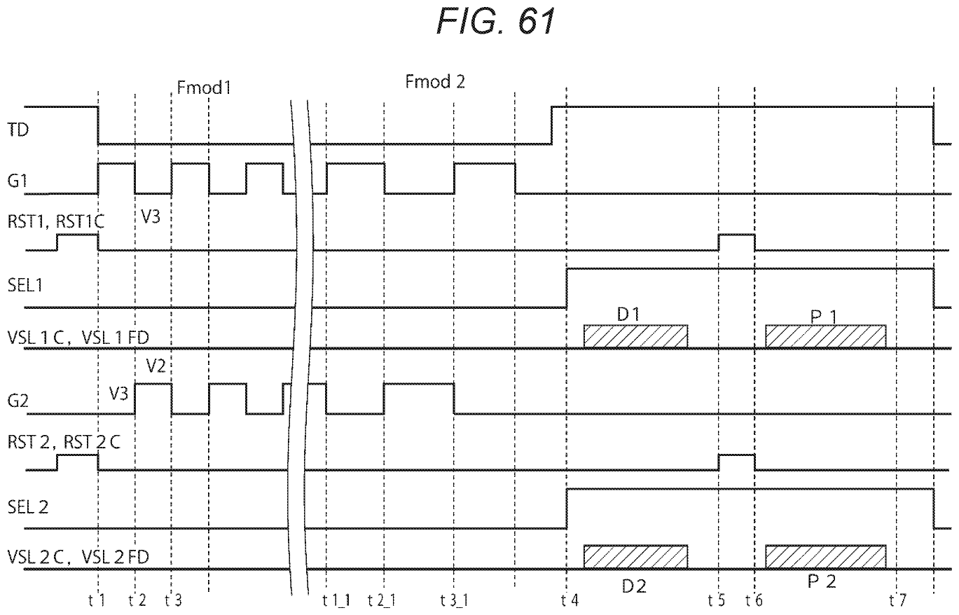

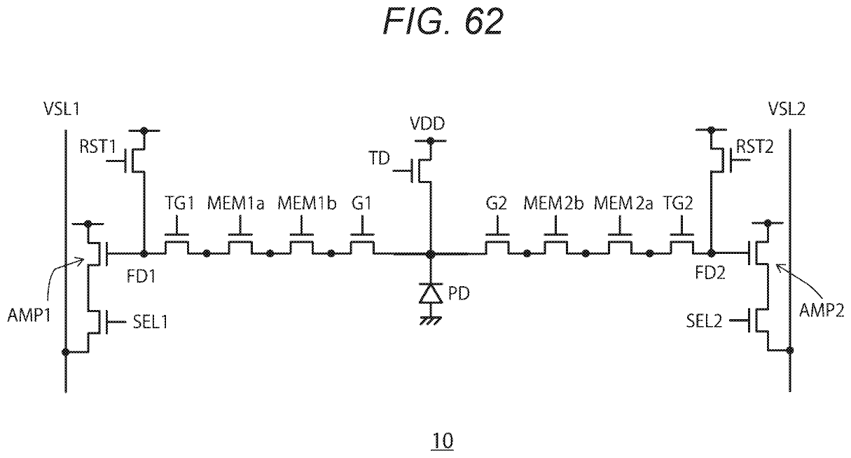

FIG. 62 is a circuit diagram illustrating an example of a configuration of the pixel 10 according to a 41st embodiment. The pixel 10 according to the 41st embodiment does not include the capacitor layers C1 and C2, and distributes signal charges of the photodiode PD to memory sections MEM1a, MEM1b, MEM2a, and MEM2b via normal metal oxide semiconductor field effect transistors (MOSFET) (G1 and G2), and thereafter transfers the signal charges by CCD. Note that G1 and G2 may indicate respective transistors having the gate electrodes G1 and G2 or gate voltages applied to the respective transistors.

The gate of the amplification transistor AMP1 is connected to the floating diffusion region FD1. The transfer transistor TG1, the memory sections MEM1a and MEMlb, and a distribution transistor G1 are connected in series between the floating diffusion region FD1 and the photodiode PD. The memory sections MEM1a and MEMlb are connected in series between the transfer transistor TG1 and the distribution transistor G1. The transfer transistor TG2, the memory sections MEM2a and MEM2b, and a distribution transistor G2 are connected in series between the floating diffusion region FD2 and the photodiode PD. The memory sections MEM2a and MEM2b are connected in series between the transfer transistor TG2 and the distribution transistor G2. The reset transistors RST1 and RST2 and the selection transistors SEL1 and SEL2 may be the same as those in FIG. 59. The amplification transistors AMP1 and AMP2 constitute a source follower circuit.

The distribution transistors G1 and G2 alternately distribute signal charges (for example, electrons) photoelectrically converted by the photodiode PD at a predetermined frequency Fmod1 (for example, about 100 MHZ). This signal charge is accumulated in the memory sections MEM1b and MEM2b. Moreover, the memory sections MEM1b and MEM2b transfer the signal charges to the memory sections MEM1a and MEM2a by CCD, respectively.

Thereafter, the distribution transistors G1 and G2 alternately distribute the signal charges of the photodiode PD at a predetermined frequency Fmod2 (for example, about 20 MHZ). This signal charge is accumulated in the memory sections MEM1b and MEM2b after the first signal charge is transferred. Thus, the signal charges distributed at the first frequency Fmod1 are accumulated in the memory sections MEM1a and MEM2a, and the signal charges distributed at the second frequency Fmod2 are accumulated in the memory sections MEM1b and MEM2b.

In the read operation, the transfer transistors TG1 and TG2 transfer the signal charges accumulated in the memory sections MEM1a and MEM2a to the floating diffusion regions FD1 and FD2. Thus, the amplification transistors AMP1 and AMP2 can simultaneously output the signal voltages corresponding to the signal charges corresponding to the frequency Fmod1 to the vertical signal lines VSL1 and VSL2, respectively.

Thereafter, the floating diffusion regions FD1 and FD2 are reset, and the transfer transistors TG1 and TG2 transfer the signal charges accumulated in the memory sections MEM1b and MEM2b to the floating diffusion regions FD1 and FD2 via the memory sections MEM1a and MEM2a. Thus, the amplification transistors AMP1 and AMP2 can simultaneously output the signal voltages corresponding to the signal charges corresponding to the frequency Fmod2 to the vertical signal lines VSL1 and VSL2, respectively.

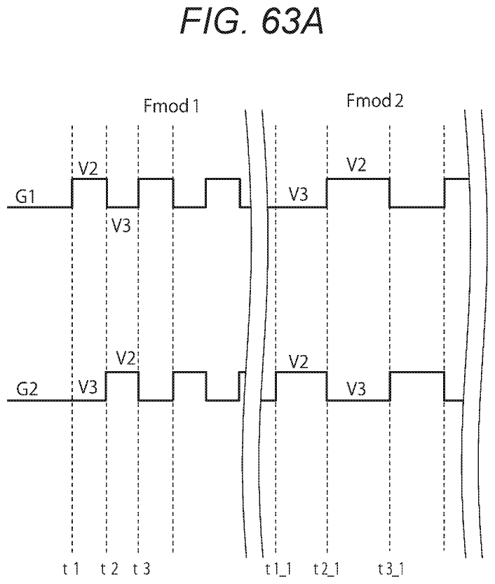

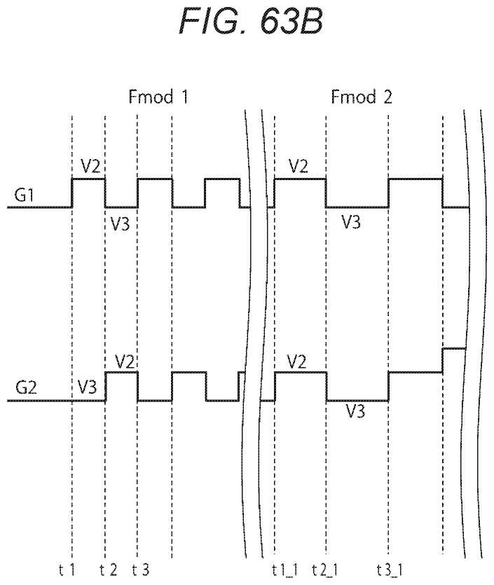

As described above, the floating diffusion region FD1 can accumulate the charges of the memory sections MEM1a and MEM1b individually at different timings, and the floating diffusion region FD2 can accumulate the charges of the memory sections MEM2a and MEM2b individually at different timings. Thus, the amplification transistors AMP1 and AMP2 can output signal voltages corresponding to the respective charges of the memory sections MEM1a and MEM1b and the memory sections MEM2a and MEM2b (see FIG. 63A). In addition, the floating diffusion region FD1 may collectively accumulate the charges of the memory sections MEM1a and MEM1b at the same time, and the floating diffusion region FD2 may collectively accumulate the charges of the memory sections MEM2a and MEM2b at the same time. Thus, the amplification transistors AMP1 and AMP2 can output the signal voltage corresponding to the total charge of the memory sections MEM1a and MEM1b and the signal voltage corresponding to the total charge of the memory sections MEM2a and MEM2a (see FIG. 63B).

According to the 41st embodiment, it is possible to widen the distance measurement range in iToF in which signals of a plurality of frequencies are obtained in one read operation.

Moreover, in the present embodiment, the distribution order of the charges may be reversed (reversed phase) between the first distribution operation at the frequency Fmod1 and the second distribution operation at the frequency Fmod2. That is, the phases of the gate voltages of the distribution transistors G1 and G2 may be shifted by 180 degrees between the first distribution operation at the frequency Fmod1 and the second distribution operation at the frequency Fmod2. For example, FIG. 63A is a timing chart illustrating an operation example of the pixel 10 according to the 41st embodiment. In FIG. 63A, only the operations of the gate voltages of the distribution transistors G1 and G2 are illustrated, and the operations of the gate voltages of the other memory sections MEM1a, MEM2a, MEM1b, and MEM2b are omitted.

In the distribution operation at the frequency Fmod1 of t1 to t3, the charges of the first t1 to t2 are distributed to the distribution transistor G1 side, and the charges of the next t2 to t3 are distributed to the distribution transistor G2 side. This distribution processing is repeatedly executed. The charges distributed by the distribution operation at the frequency Fmod1 are accumulated in the memory sections MEM1b and MEM2b. The charges accumulated in the memory sections MEM1b and MEM2b are transferred to the memory sections MEM1a and MEM2a.

Thereafter, in the distribution operation at the frequency Fmod2 of t1_1 to t3_1, the charges of the first t1_1 to t2_1 are distributed to the distribution transistor G2 side, and the charges of the next t2_1 to t3_1 are distributed to the distribution transistor G1 side. This distribution processing is repeatedly executed. The charges distributed by the distribution operation at the frequency Fmod2 are accumulated in the memory sections MEM1b and MEM2b.

The switching of the distribution order can be executed by reversing the on/off operation order of the distribution transistors G1 and G2 between the first distribution operation and the second distribution operation.

Since light obliquely enters the end portion of the pixel region 21, noise due to the parasitic light sensitivity (PLS) may be mixed into the memory sections MEM1a, MEM2a, MEM1b, and MEM2b.

In the present embodiment, in the first distribution operation and the second distribution operation, the distribution order of the charges is reversed (reversed phase), and the phases of the gate voltages of the distribution transistors G1 and G2 are shifted by 180 degrees. By reversing the order of charge distribution in this manner, it is possible to make noise components of the PLS substantially the same amount on the left and right. For example, it is assumed that the memory sections MEM1a and MEM2b store charges of the image data Q (θ=0 degrees), and the memory sections MEM2a and MEM1b store charges of the image data Q (θ=180 degrees). In this case, the image data Q (θ=0 degrees) and the image data Q (θ=180 degrees) include substantially the same PLS component. In the distance measurement calculation, since the difference signal between the image data Q (θ=0 degrees) and the image data Q (θ=180 degrees) is used as in Expression 2, the PLS component can be canceled. In addition, signal components due to characteristic variations of the distribution transistors G1 and G2 can also be canceled.

On the other hand, FIG. 63B is a timing chart illustrating another example of an operation of the pixel 10 according to the 41st embodiment. As illustrated in FIG. 63B, it is also conceivable to make the distribution order of the charges the same in the first distribution operation and the second distribution operation. That is, the distribution order of the charges is the same (in-phase) in the first distribution operation at the frequency Fmod1 and the second distribution operation at the frequency Fmod2. In this case, it is not necessary to shift the phases of the gate voltages of the distribution transistors G1 and G2 between the first distribution operation with the frequency Fmod1 and the second distribution operation with the frequency Fmod2.

In the distribution operation at the frequency Fmod1 of t1 to t3, the charges of the first t1 to t2 are distributed to the distribution transistor G1 side, and the charges of the next t2 to t3 are distributed to the distribution transistor G2 side. This distribution processing is repeatedly executed. The charges distributed by the distribution operation at the frequency Fmod1 are accumulated in the memory sections MEM1b and MEM2b. The charges accumulated in the memory sections MEM1b and MEM2b are transferred to the memory sections MEM1a and MEM2a.

Thereafter, in the distribution operation at the frequency Fmod2 of t1_1 to t3_1, the charges of the first t1_1 to t2_1 are distributed to the distribution transistor G1 side, and the charges of the next t2_1 to t3_1 are distributed to the distribution transistor G2 side. This distribution processing is repeatedly executed. The charges distributed by the distribution operation at the frequency Fmod2 are accumulated in the memory sections MEM1b and MEM2b.

As described above, in a case where the distribution orders of the charges are the same in the first distribution operation and the second distribution operation, the phases of the gate voltages of the distribution transistors G1 and G2 are the same in the first distribution operation and the second distribution operation. Thus, in the pixel 10, signal charges of the same phase (same 0) are accumulated in the memory sections MEM1a and MEM2a and the memory sections MEM1b and MEM2b. Therefore, signal charges corresponding to a large amount of light can be accumulated in the memory sections MEM1a and MEM2a and the memory sections MEM1b and MEM2b, and the dynamic range can be substantially expanded. For example, it is assumed that the memory sections MEM1a and MEM2a store charges of the image data Q (θ=0 degrees), and the memory sections MEM1b and MEM2b store charges of the image data Q (θ=180 degrees). In this case, the image data Q (θ=0 degrees) has the dynamic range corresponding to the capacitances of the memory sections MEM1a and MEM2a. The image data Q (θ=180 degrees) has the dynamic range corresponding to the capacitances of the memory sections MEM1b and MEM2b.

### 42nd Embodiment

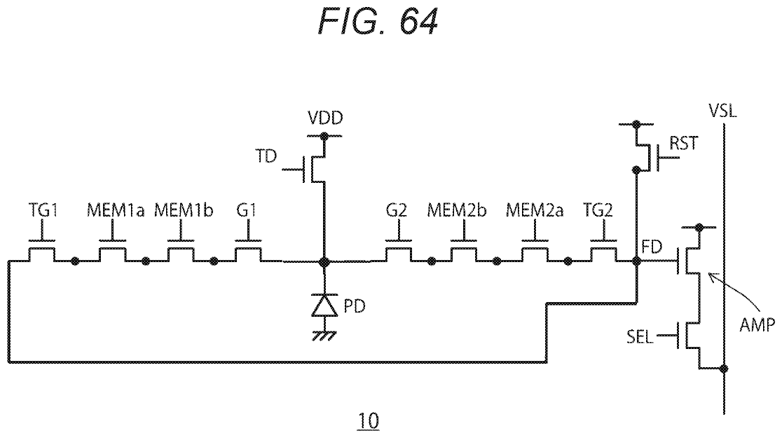

FIG. 64 is a circuit diagram illustrating an example of a configuration of the pixel 10 according to a 42nd embodiment. In the 42nd embodiment, the floating diffusion region FD, the amplification transistor AMP, the reset transistor RST, and the selection transistor SEL are shared by the memory sections MEM1a and MEM1b and the memory sections MEM2a and MEM2b. Accordingly, one vertical signal line VSL is also provided for each pixel 10.

Since the floating diffusion region FD is shared as one by each pixel 10, the transfer transistors TG1 and TG2 alternately transfer the charges of the memory sections MEM1a and MEM1b and the charges of the memory sections MEM2a and MEM2b to the floating diffusion FD. Then, the selection transistor SEL transmits signals corresponding to the charges of the memory sections MEM1a and MEM1b and signals corresponding to the charges of the memory sections MEM2a and MEM2b to the vertical signal line VSL at different timings. A reset operation is required between the output of the signals corresponding to the charges of the memory sections MEM1a and MEM1b and the output of the signals corresponding to the charges of the memory sections MEM2a and MEM2b.

Other configurations and operations of the 42nd embodiment are similar to those of the 41st embodiment.

In the 42nd embodiment, since the floating diffusion region FD and the amplification transistor AMP are shared, an offset variation of the floating diffusion region FD and a gain variation of the amplification transistor AMP are suppressed. Furthermore, since the number of elements constituting each pixel 10 is small, this leads to miniaturization of the pixel region 21.

### 43rd Embodiment

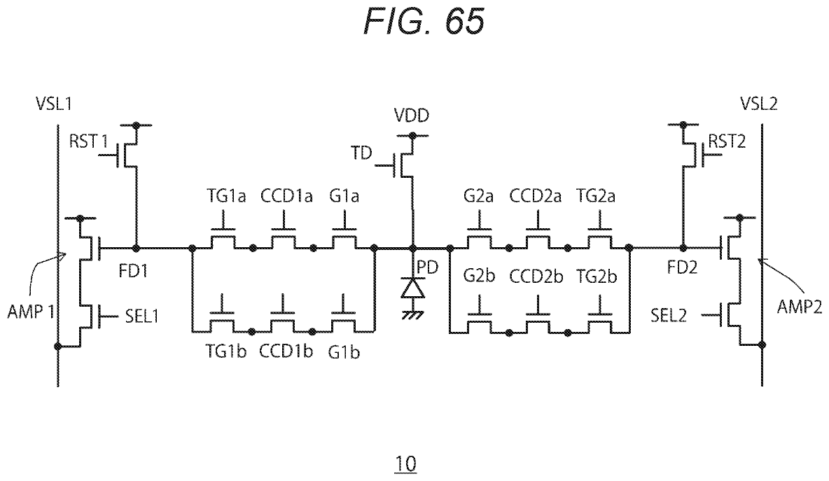

FIG. 65 is a circuit diagram illustrating an example of a configuration of the pixel 10 according to a 43rd embodiment. In the 43rd embodiment, the memory sections CCD1a and CCD1b are connected in parallel via the distribution transistors G1a and G1b and the transfer transistors TG1a and TG1b. The memory sections CCD1a and CCD1b are connected to the photodiode PD via the distribution transistors G1a and G1b, respectively, and individually receive signal charges at different timings. Moreover, the memory sections CCD1a and CCD1b are connected to the floating diffusion region FD1 via the transfer transistors TG1a and TG1b, respectively, and individually transmit signal charges to the floating diffusion region FD1 at different timings from each other.

The memory sections CCD2a and CCD2b are connected to the photodiode PD via the distribution transistors G2a and G2b, respectively, and individually receive signal charges at different timings. Moreover, the memory sections CCD2a and CCD2b are connected to the floating diffusion region FD2 via the transfer transistors TG2a and TG2b, respectively, and individually transmit signal charges to the floating diffusion region FD2 at different timings from each other.

Consequently, the memory sections CCD1a and CCD1b can perform the CCD operation similarly to the memory sections MEM1a and MEM1b in FIG. 62, respectively, and the memory sections CCD2a and CCD2b can perform the CCD operation similarly to the memory sections MEM2a and MEM2b in FIG. 62, respectively. For example, the charges distributed by the distribution operation at the frequency Fmod1 are accumulated in the memory sections CCD1a and CCD2a. The charges distributed by the distribution operation at the frequency Fmod2 are accumulated in the memory sections CCD1b and CCD2b.

In the read operation, the transfer transistors TG1a and TG2a transfer the signal charges accumulated in the memory sections CCD1a and CCD2a to the floating diffusion regions FD1 and FD2. Thus, the amplification transistors AMP1 and AMP2 can simultaneously output the signal voltages corresponding to the signal charges corresponding to the frequency Fmod1 to the vertical signal lines VSL1 and VSL2, respectively.

Thereafter, the floating diffusion regions FD1 and FD2 are reset, and the transfer transistors TG1b and TG2b transfer the signal charges accumulated in the memory sections CCD1b and CCD2b to the floating diffusion regions FD1 and FD2. Thus, the amplification transistors AMP1 and AMP2 can simultaneously output the signal voltages corresponding to the signal charges corresponding to the frequency Fmod2 to the vertical signal lines VSL1 and VSL2, respectively.

As in the 41st embodiment, by reversing the distribution order of the charges in the first distribution operation and the second distribution operation, it is possible to make the noise components of the PLS substantially the same amount on the left and right. For example, the memory sections CCD1a and CCD2b store charges of the image data Q (θ=0 degrees), and the memory sections CCD2a and CCD1b store charges of the image data Q (θ=180 degrees). The image data Q (θ=0 degrees, 180 degrees) is output via the vertical signal lines VSL1 and VSL2, respectively. In this case, similarly to the 41st embodiment, the PLS component can be canceled in the distance measurement calculation. Furthermore, characteristic variations of the distribution transistors G1a and G2a and characteristic variations of the distribution transistors G1b and G2b can also be canceled.

### 44th Embodiment

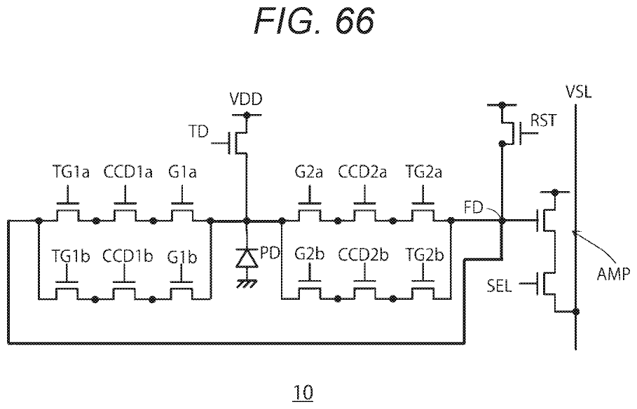

FIG. 66 is a circuit diagram illustrating an example of a configuration of the pixel 10 according to a 44th embodiment. The 44th embodiment is an embodiment in which the 42nd embodiment is applied to the 43rd embodiment. In the 44th embodiment, similarly to the 42nd embodiment, the floating diffusion region FD, the amplification transistor AMP, the reset transistor RST, and the selection transistor SEL are shared by the memory sections CCD1a and CCD1b and the memory sections CCD2a and CCD2b. Accordingly, the floating diffusion region FD, the amplification transistor AMP, the reset transistor RST, and the selection transistor SEL are also shared by the distribution transistors G1a, G1b, G2a, and G2b and the transfer transistors TG1a, TG1b, TG2a, and TG2b.

In the 44th embodiment, similarly to the 42nd embodiment, since the floating diffusion region FD and the amplification transistor AMP are shared, the offset variation of the floating diffusion region FD and the gain variation of the amplification transistor AMP are suppressed. Furthermore, since the number of elements constituting each pixel 10 is smaller than that in the 43rd embodiment, this leads to miniaturization of the pixel region 21.

### 45th Embodiment

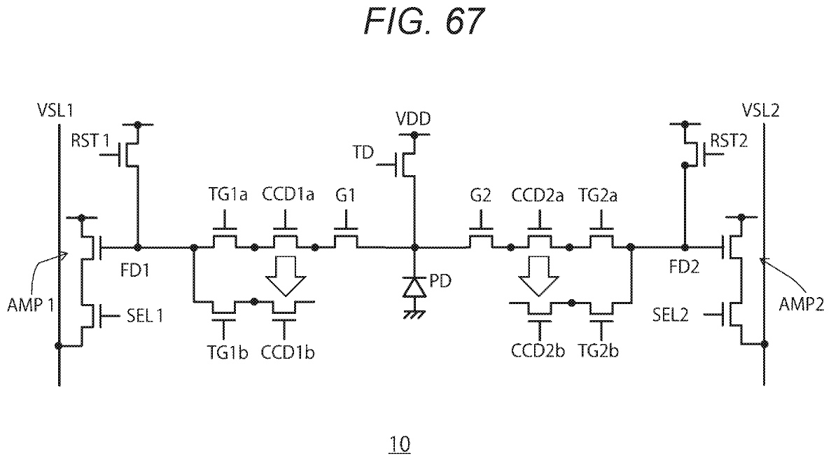

FIG. 67 is a circuit diagram illustrating an example of a configuration of the pixel 10 according to a 45th embodiment. In the 45th embodiment, the distribution transistors G1b and G2b are not provided. The memory section CCD1b is connected to the floating diffusion region FD1 via the transfer transistor TG1b. The memory section CCD2b is connected to the floating diffusion region FD2 via the transfer transistor TG2b. The memory sections CCD1a and CCD2a are connected to the photodiode PD via the distribution transistors G1 and G2, respectively. Other configurations of the 45th embodiment may be similar to the corresponding configurations of the 43rd embodiment.

In the 45th embodiment, after charges are accumulated in the memory sections CCD1a and CCD2a, the charges are transferred to the memory sections CCD1b and CCD2b by CCD. Then, after the charge transfer, the charge is accumulated again in the memory sections CCD1a and CCD2a.

For example, the distribution transistors G1 and G2 alternately distribute signal charges photoelectrically converted by the photodiode PD) at a predetermined frequency Fmod1. The signal charges are accumulated in the memory sections CCD1a and CCD2a. Moreover, the memory sections CCD1a and CCD2a transfer the signal charges to the memory sections CCD1b and CCD2b by CCD, respectively.

Thereafter, the distribution transistors G1 and G2 alternately distribute the signal charges of the photodiode PD at a predetermined frequency Fmod2. This signal charge is accumulated in the memory sections CCD1a and CCD2a after the first signal charge is transferred. Thus, the signal charges distributed at the first frequency Fmod1 are accumulated in the memory sections MEM1b and MEM2b, and the signal charges distributed at the second frequency Fmod2 are accumulated in the memory sections MEM1a and MEM2a.

According to the 45th embodiment, the charges accumulated in the memory sections CCD1a and CCD1b are distributed via the single distribution transistor G1. The charges stored in the memory sections CCD2a and CCD2b are distributed via the single distribution transistor G2. Thus, in the 45th embodiment, variations in the distribution transistor G1 and variations in the distribution transistor G2 are eliminated as compared with the 43rd embodiment. Furthermore, in the 45th embodiment, since the number of elements constituting each pixel 10 is smaller than that in the 43rd embodiment, this leads to miniaturization of the pixel region 21.

Other operations of the 45th embodiment may be similar to those of the 43rd embodiment. Therefore, the 45th embodiment can further obtain effects similar to those of the 43rd embodiment.

### 46th Embodiment

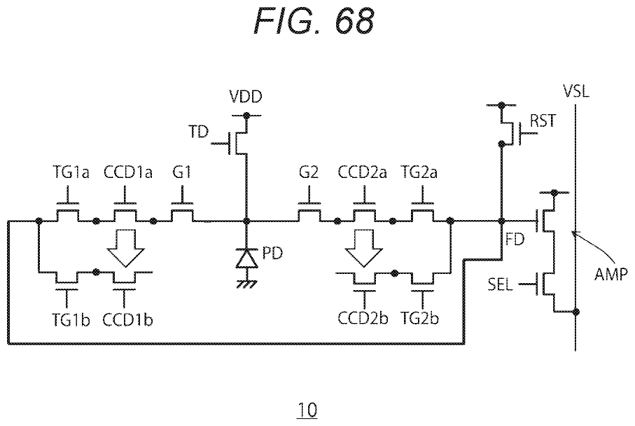

FIG. 68 is a circuit diagram illustrating an example of a configuration of the pixel 10 according to a 46th embodiment. The 46th embodiment is an embodiment in which the 42nd embodiment is applied to the 45th embodiment. In the 46th embodiment, similarly to the 42nd embodiment, the floating diffusion region FD, the amplification transistor AMP, the reset transistor RST, and the selection transistor SEL are shared by the memory sections CCD1a and CCD1b and the memory sections CCD2a and CCD2b. Accordingly, the floating diffusion region FD, the amplification transistor AMP, the reset transistor RST, and the selection transistor SEL are also shared by the distribution transistors G1 and G2 and the transfer transistors TG1a, TG1b, TG2a, and TG2b.

In the 46th embodiment, similarly to the 42nd embodiment, since the floating diffusion region FD and the amplification transistor AMP are shared, the offset variation of the floating diffusion region FD and the gain variation of the amplification transistor AMP are suppressed. Furthermore, since the number of elements constituting each pixel 10 is smaller than that in the 45th embodiment, this leads to miniaturization of the pixel region 21.

### 47th Embodiment

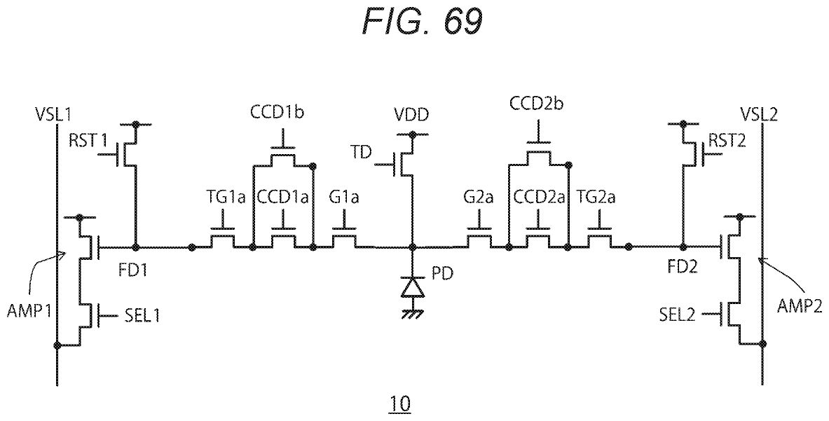

FIG. 69 is a circuit diagram illustrating an example of a configuration of the pixel 10 according to a 47th embodiment. In the 47th embodiment, the memory sections CCD1a and CCD1b are connected in parallel, and the memory sections CCD2a and CCD2b are connected in parallel. The memory sections CCD1a and CCD1b are connected to the photodiode PD via the distribution transistor G1a, and are connected to the floating diffusion region FD1 via the transfer transistor TG1a. The memory sections CCD2a and CCD2b are connected to the photodiode PD via the distribution transistor G2a, and are connected to the floating diffusion region FD2 via the transfer transistor TG2a. That is, in the 47th embodiment, the distribution transistor G1a and the transfer transistor TG1a are shared by the memory sections CCD1a and CCD1b, and the distribution transistor G2a and the transfer transistor TG2a are shared by the memory sections CCD2a and CCD2b.

Thus, it is possible to remove a variation component of the distribution transistor (G1a, G1b in FIG. 66) and a variation component of the transfer transistor (TG1a and TG1b in FIG. 66) from the signal charges accumulated in the memory sections CCD1a and CCD1b. Further, it is possible to remove a variation component of the distribution transistor (G2a, G2b) and a variation component of the transfer transistor (TG2a, TG2b) from the signal charges accumulated in the memory sections CCD2a and CCD2b. Furthermore, since the number of elements constituting each pixel 10 is smaller than that in the 43rd embodiment, this leads to miniaturization of the pixel region 21.

Other configurations of the 47th embodiment may be similar to the corresponding configurations of the 43rd embodiment. Therefore, the 47th embodiment can further obtain effects similar to those of the 43rd embodiment.

The charge distribution operation may be the same as the operation described with reference to FIG. 63A or FIG. 63B. The PLS component can be canceled by an operation similar to that in FIG. 63A. In addition, signal components due to characteristic variations of the distribution transistors G1a and G2a can also be canceled. The dynamic range can be expanded by an operation similar to that in FIG. 63B.

Note that, in the 47th embodiment, since the distribution transistor G1a and the transfer transistor TG1a are shared by the memory sections CCD1a and CCD1b, the charge distribution operation and the charge transfer operation are executed at different timings for the memory sections CCD1a and CCD1b, respectively. Since the distribution transistor G2a and the transfer transistor TG2a are also shared by the memory sections CCD2a and CCD2b, the charge distribution operation and the charge transfer operation are executed at different timings for the memory sections CCD2a and CCD2b, respectively.

### 48th Embodiment

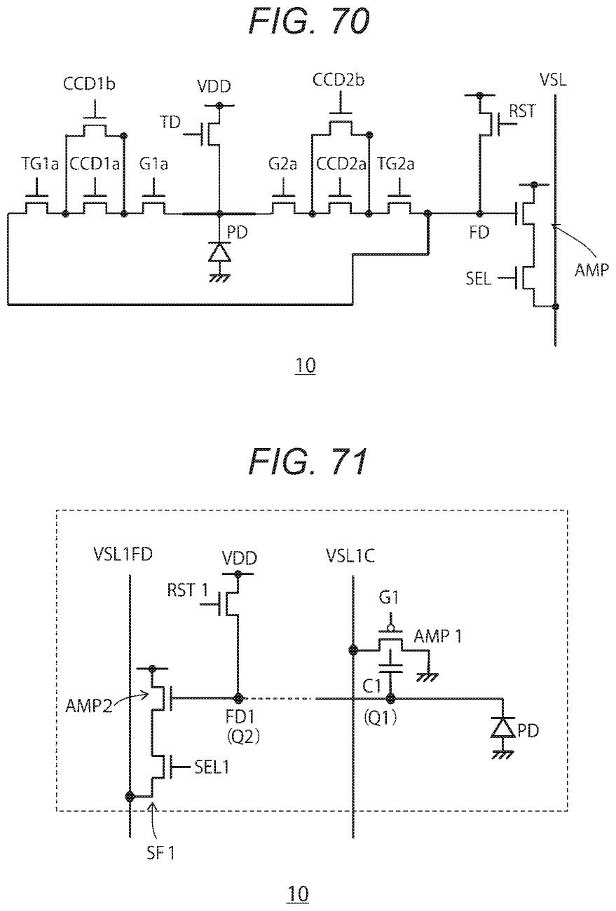

FIG. 70 is a circuit diagram illustrating an example of a configuration of the pixel 10 according to a 48th embodiment. The 48th embodiment is an embodiment in which the 42nd embodiment is applied to the 47th embodiment. In the 48th embodiment, similarly to the 42nd embodiment, the floating diffusion region FD, the amplification transistor AMP, the reset transistor RST, and the selection transistor SEL are shared by the memory sections CCD1a and CCD1b and the memory sections CCD2a and CCD2b. Accordingly, the floating diffusion region FD, the amplification transistor AMP, the reset transistor RST, and the selection transistor SEL are also shared by the distribution transistors G1 and G2 and the transfer transistors TG1a, TG1b, TG2a, and TG2b.

In the 48th embodiment, similarly to the 42nd embodiment, since the floating diffusion region FD and the amplification transistor AMP are shared, the offset variation of the floating diffusion region FD and the gain variation of the amplification transistor AMP are suppressed. Furthermore, since the number of elements constituting each pixel 10 is smaller than that in the 47th embodiment, this leads to miniaturization of the pixel region 21.

Other configurations and operations of the 48th embodiment may be similar to those of the 47th embodiment. Therefore, the 48th embodiment can further obtain effects similar to those of the 47th embodiment.

### 49th Embodiment: Image Sensor

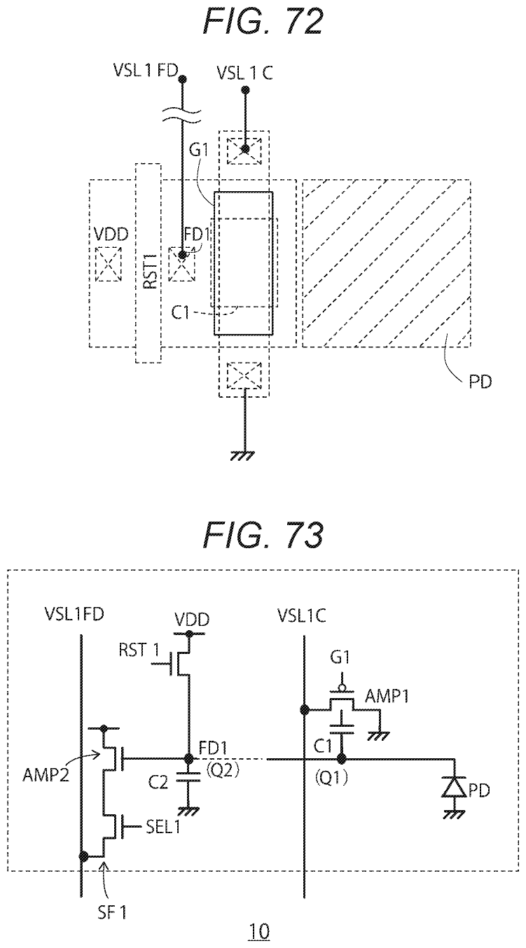

FIG. 71 is an equivalent circuit diagram illustrating an example of a configuration of the pixel 10 according to a 49th embodiment. FIG. 72 is a plan view illustrating an example of a layout of the pixel 10 according to the 49th embodiment. The following embodiment is a mode in which the present technology is applied to a CMOS (Complementary Metal Oxide Semiconductor) Image Sensor (CIS). In the CIS, unlike the iToF sensor, it is not necessary to perform a distribution operation of distributing the charge of the photodiode PD to the left and right. Therefore, the embodiment of the CIS is basically only required to have a configuration on either one side of the circuit configurations on both sides of the photodiode PD of the iToF sensor described above. The cross section of the present embodiment has a configuration on one side of FIG. 5. Furthermore, the embodiment of the iToF sensor described above is basically applicable to the following CIS. A basic block diagram of the following embodiment may be the same as that illustrated in FIG. 2.

The pixel 10 includes the photodiode PD, the capacitor layer C1, the amplification transistors AMP1 and AMP2, the vertical signal lines VSLIC and VSL1FD, the floating diffusion region FD1, the reset transistor RST1, and the selection transistor SEL1.

The configurations of the photodiode PD and the amplification transistor AMP1 may be similar to those of the first embodiment. A source electrode of the amplification transistor AMP1 is connected to the vertical signal line VSLIC, and a drain electrode thereof is grounded. Similarly to that of the first embodiment, the amplification transistor AMP1 is a channel modulation transistor whose threshold voltage is modulated by the charge accumulated in the capacitor layer C1. The amplification transistor AMP1 is constituted by a p-type MOSFET, for example. In this case, the amplification transistor AMP1 constitutes a source follower circuit, and the threshold voltage of the channel layer changes due to the back bias effect caused by the charge amount Q1 of the capacitor layer C1. A fluctuation of the threshold voltage of the amplification transistor AMP1 is output to the vertical signal line VSLIC as an output signal.

The capacitance of the capacitor layer C1 can be set by changing the layout area of the capacitor layer C1 illustrated in FIG. 72. For example, when the layout area of the capacitor layer C1 is reduced, the capacitance of the capacitor layer C1 is reduced, and a fluctuation of the signal voltage output to the vertical signal line VSLIC per charge is increased. This leads to an increase in photoelectric conversion efficiency of the pixel 10. In the present embodiment, since the degree of freedom of the layout area of the capacitor layer C1 is high, the degree of freedom of setting the photoelectric conversion efficiency is also high.

Note that, in a case where the amplification transistor AMP1 is a p-type MOSFET, the charges accumulated in the capacitor layer C1 are electrons. On the other hand, the amplification transistor AMP1 may by constituted by an n-type MOSFET. In this case, the charges accumulated in the capacitor layer C1 are hole charges.

The capacitor layer C1 may have the same configuration as that of the first embodiment. It is an n-type impurity diffusion layer provided in the semiconductor layer below the channel layer of the amplification transistor AMP1. The capacitor layer C1 can accumulate charges photoelectrically converted by the photodiode PD.

Depending on the amount of the charge Q1 (for example, electron e) accumulated in the capacitor layer C1, the conductive state of the amplification transistor AMP1 changes, and the current or the voltage of the vertical signal line VSL1 changes. Therefore, the vertical signal line VSLIC can transmit a voltage corresponding to the amount of charge accumulated in the capacitor layer C1. In the present description, the charges Q1 and Q2 may indicate charge amounts.

As described above, the photodiode PD, the amplification transistor AMP1, and the capacitor layer C1 may be basically the same as those in the first embodiment.

The floating diffusion region FD1 is provided apart from the amplification transistor AMP1, and can accumulate charges from the capacitor layer C1. The configuration of the floating diffusion region FD1 may be similar to that in FIGS. 54 and 55.

The reset transistor RST1 is connected between the floating diffusion region FD1 and the power supply VDD. The reset transistor RST1 can perform a reset operation by discharging the charge of the floating diffusion region FD1.

The amplification transistor AMP1 is connected between the power supply VDD and the selection transistor SEL1, and has a gate connected to the floating diffusion region FD1. The amplification transistor AMP1 is connected to the vertical signal line VSL1FD via the selection transistor SEL1. The amplification transistor AMP1 and the selection transistor SEL1 constitute the source follower circuit SF1. Note that, in FIG. 72, illustration of the source follower circuit SF1 is omitted.

The source follower circuit SF1 is connected between the floating diffusion region FD1 and the vertical signal line VSL1FD, and can transmit a voltage corresponding to the amount of charge accumulated in the floating diffusion region FD1 to the vertical signal line VSL1FD.

In such a configuration, the amplification transistor AMP1 can output a signal voltage corresponding to the charge Q1 accumulated in the capacitor layer C1 to the vertical signal line VSLIC. The vertical signal line VSLIC transmits a signal corresponding to the accumulated charges in the capacitor layer C1. The amplification transistor AMP2 can output a signal voltage corresponding to the charge Q2 accumulated in the floating diffusion region FD1 to the vertical signal line VSL1FD. The vertical signal line VSL1FD transmits a signal corresponding to the accumulated charges in the floating diffusion region FD1. For example, in a case where a light amount of an optical signal is small and a signal charge amount is smaller than the capacitance of the capacitor layer C1, it is sufficient if only the output signal of the capacitor layer C1 output from the vertical signal line VSLIC is used. On the other hand, in a case where the light amount of the optical signal is large and the signal charge amount is larger than the capacitance of the capacitor layer C1, it is only required to use the output signals of both the capacitor layer C1 and the floating diffusion region FD1 output from the vertical signal lines VSLIC and VSL1FD. Thus, the floating diffusion region FD1 can accumulate saturated charges overflowing from the capacitor layer C1. Consequently, the dynamic range of the pixel 10 can be expanded.

For example, the photoelectric conversion efficiency of the capacitor layer C1 and the floating diffusion region FD1 is set to uci and urDi, respectively, and the signal charge amounts in the capacitor layer C1 and the floating diffusion region FD1 are set to Q1 and Q2, respectively. In this case, a combined output signal Vout of the vertical signal lines VSLIC and VSL1FD can be obtained by Expression 1.

$$Vout = {μ}_{C 1} \times Q 1 + {μ}_{FD 1} \times Q 2 = {μ}_{C 1} ( Q 1 + ( {μ}_{FD 1} / {μ}_{C 1} ) \times Q 2 ) \qquad ( Expression 1 )$$

Here, in a case where μ_{FD1}/μ_{C1}=1/100, the capacitance of the floating diffusion region FD1 is 100 times that of the capacitor layer C1. Therefore, as compared with the case of only the capacitor layer C1, the pixel 10 of the present embodiment can detect signal charges of approximately 100 times. That is, the saturation charge amount of the pixel 10 is almost 100 times.

In addition, normally, in order to detect signal charges by a plurality of detecting sections (floating diffusion region or capacitor), each pixel requires five or more transistors. The pixel 10 according to the present embodiment includes four transistors and one photodiode PD. Therefore, the present embodiment leads to miniaturization of the pixel region 21.

Furthermore, in the present embodiment, the signal voltage corresponding to the charge Q1 of the capacitor layer C1 and the signal voltage corresponding to the charge Q2 of the floating diffusion region FD1 are detected by the different vertical signal lines VSLIC and VSL1FD, respectively. Therefore, for example, even if a large dark current component is mixed in the floating diffusion region FD1 as noise, the dark current component affects only the signal of the charge Q2 and does not affect the signal of the charge Q1.

In a case where not only the charge Q2 but also the signal corresponding to the charge Q1 of the capacitor layer C1 is detected via the floating diffusion region FD1, the output signals of both the charges Q1 and Q2 are affected by the dark current component.

On the other hand, according to the present embodiment, the output signals of the charges Q1 and Q2 are transmitted to the different vertical signal lines VSLIC and VSL1FD, respectively. Therefore, the dark current component of the floating diffusion region FD1 affects only the signal of the charge Q2, and does not affect the signal of the charge Q1. Consequently, the influence of the dark current component on the output signal can be alleviated.

In addition, the charge Q2 originally includes photon shot noise larger than a dark current component. Therefore, by making the charge Q2 sufficiently larger than the charge Q1, even if the charge Q2 of the floating diffusion region FD1 includes a dark current component, the influence of the dark current component on the charge Q2 can be reduced.

In addition, in a case where the amplification transistor AMP1 is a p-type MOSFET, resetting the capacitor layer C1 removes electrons to the floating diffusion region FD1 by setting the gate voltage of the amplification transistor AMP1 to a negative voltage. As described above, the charge of the capacitor layer C1 of the channel modulation transistor can be almost completely removed. Therefore, since the reproducibility of the reset state is favorable, the signal processing section 26 of FIG. 2 can extract an accurate signal component with less kTC noise even if the reset state detected after the signal state is excluded from the signal state in the CDS processing.

### 50th Embodiment

FIG. 73 is an equivalent circuit diagram illustrating an example of a configuration of the pixel 10 according to a 50th embodiment. The pixel 10 according to the present embodiment further includes a capacitor layer C2 connected between the floating diffusion region FD1 and the ground. Other configurations of the present embodiment may be similar to corresponding configurations of the 49th embodiment.

According to the present embodiment, the capacitance of the floating diffusion region FD1 increases by the amount of the capacitor layer C2. Thus, the dynamic range of the pixel 10 can be further expanded. In addition, by substantially increasing the capacitance of the floating diffusion region FD1, the influence of the kTC noise components can be reduced.

### 51st Embodiment

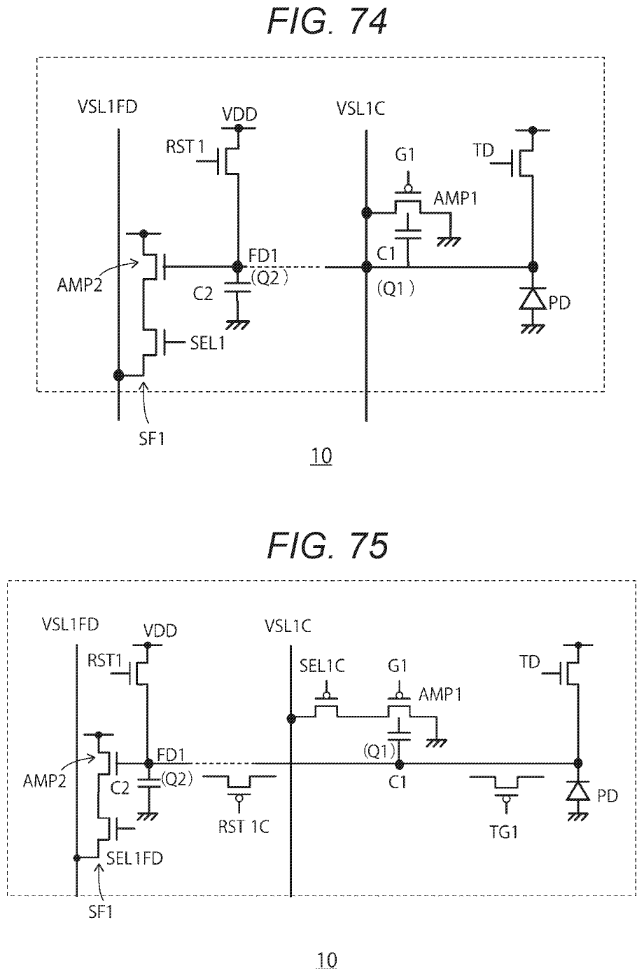

FIG. 74 is an equivalent circuit diagram illustrating an example of a configuration of the pixel 10 according to a 51st embodiment. The pixel 10 according to the present embodiment further includes a charge discharge transistor TD that discharges the charge of the photodiode PD. The charge discharge transistor TD is connected between the power supply VDD and the cathode of the photodiode PD, and can discharge the charge accumulated in the photodiode PD to the power supply VDD. The planar layout, operation, and the like of the charge discharge transistor TD are as described in the third embodiment.

According to the present embodiment, unnecessary signal charges generated in the photodiode PD can be removed. Therefore, it is possible to prevent such unnecessary signal charges from affecting the charges Q1 and Q2 of the capacitor layer C1 and the floating diffusion region FD1.

### 52nd Embodiment

FIG. 75 is an equivalent circuit diagram illustrating an example of a configuration of the pixel 10 according to a 52nd embodiment. The pixel 10 according to the present embodiment further includes a selection transistor SELIC, the reset transistor RST1C, and the transfer transistor TG1. Note that, for convenience, the selection transistor of the source follower circuit SF1 is SELIFD.

The selection transistor SELIC is provided between the amplification transistor AMP1 and the vertical signal line VSLIC, and connects between the amplification transistor AMP1 and the vertical signal line VSLIC when the pixel 10 is selected. Thus, the selection transistor SELIC can transmit a voltage corresponding to the conductive state of the amplification transistor AMP1 to the vertical signal line VSLIC. Other configurations, operations, and the like of the selection transistor SELIC may be similar to those of the selection transistor SEL1 of the seventh embodiment.

The reset transistor RST1C is provided between the capacitor layer C1 and the floating diffusion region FD1, and connects the capacitor layer C1 and the power supply VDD via the floating diffusion region FD1 when resetting the capacitor layer C1. Thus, the reset transistor RST1C discharges the charge from the capacitor layer C1 and resets the capacitor layer C1. Other configurations, operations, and the like of the reset transistor RST1C may be similar to those of the reset transistor RST1 of the tenth embodiment.

The transfer transistor TG1 is provided between the photodiode PD and the capacitor layer C1, and transfers the charge from the photodiode PD to the capacitor layer C1 or the floating diffusion region FD1. Since there is no interface between the semiconductor layer and the silicon oxide film in the path of the signal charge, charges are not trapped or de-trapped in the middle of the path. Therefore, the transfer transistor TG1 can smoothly transfer the signal charge to the capacitor layer C1 or the floating diffusion region FD1. The transfer transistor TG1 has a charge collection function among functions of the amplification transistor AMP1. Other configurations, operations, and the like of the transfer transistor TG1 may be similar to those of the transfer transistor TG1 of the sixth embodiment.

As described above, since the pixel 10 further includes the selection transistor SELIC, the reset transistor RST1C, and the transfer transistor TG1, the amplification transistor AMP1 as the channel modulation transistor has only a function of accumulating charges in the capacitor layer C1 and a function of generating a signal corresponding to the charge amount. The transfer transistor TG1, the selection transistor SELIC, and the reset transistor RST1C execute a charge transfer function from the photodiode PD to the capacitor layer C1 and the floating diffusion region FD1, a selection function of transmitting a signal voltage from the amplification transistor AMP1 to the vertical signal line VSLIC, and a reset function of resetting the capacitor layer C1, respectively. Thus, the operation margin of the amplification transistor AMP1 can be expanded, and the dynamic ranges of the signal voltages of the vertical signal lines VSL1 and VSL2 can be expanded.

Note that the pixel 10 according to the present embodiment may include any one or two of the selection transistor SELIC, the reset transistor RST1C, and the transfer transistor TG1.

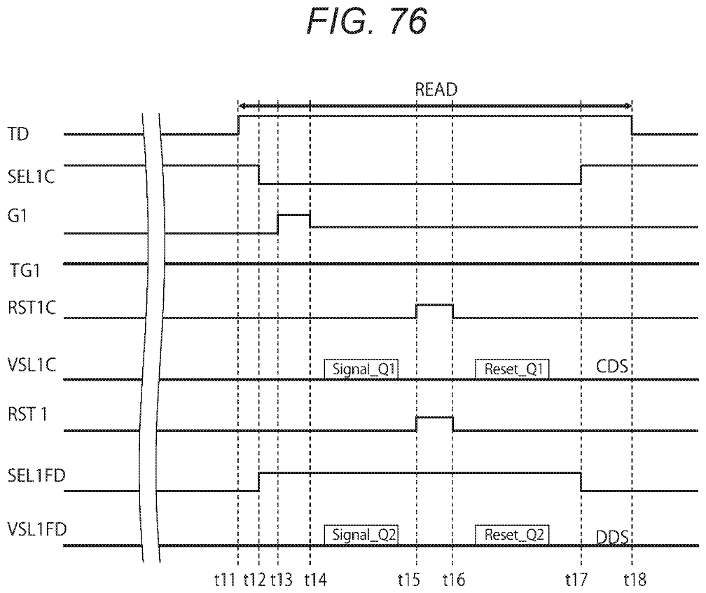

FIG. 76 is a timing chart illustrating an example of a read operation of the pixel 10 according to the 52nd embodiment. First, it is assumed that the pixel 10 is in a reset state in which the floating diffusion region FD1 and the capacitor layer C1 do not accumulate charges.

In an accumulation operation of the signal charge until t11, the charge discharge transistor TD, the selection transistors SELIC and SELIFD, and the reset transistors RST1C and RST1 are turned off. On the other hand, since the gate voltage G1 is at a low level, the amplification transistor AMP1 accumulates the signal charge from the photodiode PD in the capacitor layer C1. Note that the transfer transistor TG1 maintains the ON state in this read operation.

Next, at t11, the charge discharge transistor TD is turned on, the charge of the photodiode PD is discharged, and the accumulation period ends. The period from t11 to t17 is a read period.

Next, at t12, the selection transistors SELIC and SEL1FD are turned on. Thus, a signal voltage based on the charge amount Q2 accumulated in the floating diffusion region FD1 is transmitted to the vertical signal line VSL1FD via the selection transistor SELIFD. Furthermore, at t13, the gate electrode G1 of the amplification transistor AMP1 rises to a high level and is turned off. At t14, the gate electrode G1 becomes an intermediate level higher than the low level and lower than the high level, and the amplification transistor AMP1 causes a current corresponding to the charge amount Q1 of the capacitor layer C1 to flow. Thus, a signal voltage corresponding to the charge amount Q1 of the capacitor layer C1 is transmitted to the vertical signal line VSLIC.

Next, at t15, the reset transistors RST1C and RST1 are turned on, and the charges of the floating diffusion region FD1 and the capacitor layer C1 are removed. Thus, the floating diffusion region FD1 and the capacitor layer C1 are brought into a reset state.

Next, at t16, the reset transistors RST1C and RST1 are turned off, and the reset operation is completed.

From t16 to t17, signals of the reset state of the floating diffusion region FD1 and the capacitor layer C1 are read out. Thus, signals of both the signal state and the reset state corresponding to the signal charge are obtained.

Next, at t17, the selection transistors SELIC and SEL1FD are turned off. Thus, the pixel 10 is electrically disconnected from the vertical signal lines VSLIC and VSL1FD.

Signals of the signal state and the reset state are AD-converted. From t17 to t18, the signal from the vertical signal line VSLIC is subjected to the CDS processing. Furthermore, the signal from the vertical signal line VSL1FD is subjected to double data sampling (DDS) processing. Note that, in the reset operation from t15 to t16, the charge of the capacitor layer C1 can be completely removed. Therefore, the signal processing section 26 can perform the CDS processing with the signal from the vertical signal line VSLIC. Thus, kTC noise can be suppressed for the signal charge Q1 of the capacitor layer C1. On the other hand, the charge of the floating diffusion region FD1 cannot be completely removed. Therefore, the signal processing section 26 cannot perform the CDS processing on the signal from the vertical signal line VSL1FD.

After t18, the accumulation operation starts, and the operations from t11 to t18 are repeated.

According to the present embodiment, the kTC noise cannot be suppressed for the charge Q2 of the floating diffusion region FD1, but the kTC noise can be suppressed for the charge Q1 of the capacitor layer C1. In addition, according to the present embodiment, signals can be simultaneously output from both the capacitor layer C1 and the floating diffusion region FD1 to the vertical signal lines VSLIC and VSL1FD. Therefore, the frame rate can be increased.

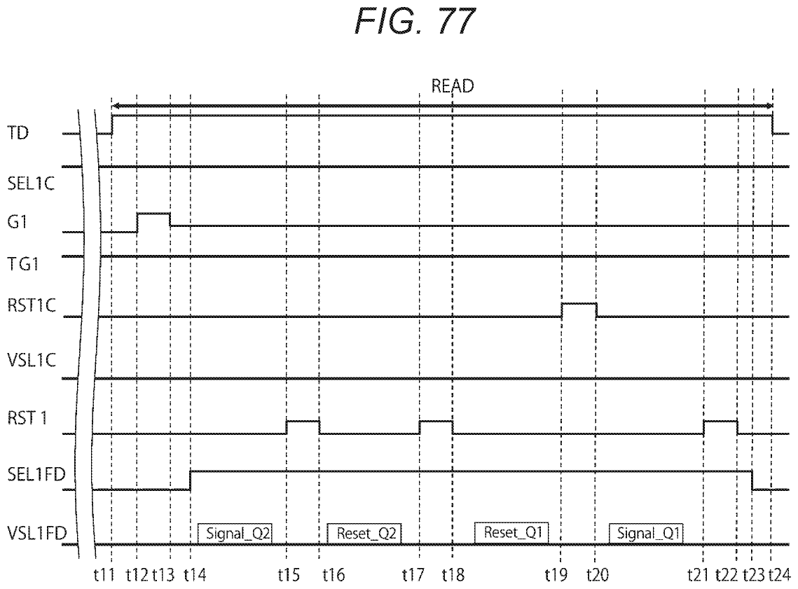

FIG. 77 is a timing chart illustrating another example of the read operation of the pixel 10 according to the 52nd embodiment. In this example, the selection transistor SELIC maintains OFF, and both the signal charges Q1 and Q2 are output to the vertical signal line VSL1FD via the selection transistor SEL1FD.

The accumulation operation until t11 may be the same as the operation described with reference to FIG. 76. Thus, the signal charge from the photodiode PD is accumulated in the capacitor layer C1 and the floating diffusion region FD1.

Next, at t11, the charge discharge transistor TD is turned on, the charge of the photodiode PD is discharged, and the accumulation period ends. The period from t11 to t24 is a read period. At t12, the gate electrode G1 of the amplification transistor AMP1 rises to the high level and is turned off. At t13, the gate electrode G1 becomes an intermediate level higher than the low level and lower than the high level, and the amplification transistor AMP1 causes a current corresponding to the charge amount Q1 of the capacitor layer C1 to flow. Thus, the signal voltage corresponding to the charge amount Q1 of the capacitor layer C1 is transmitted to the vertical signal line VSL1C.

Next, at t14, the selection transistor SELIFD is turned on. Thus, the signal voltage based on the charge amount Q2 accumulated in the floating diffusion region FD1 is transmitted to the vertical signal line VSL1FD via the selection transistor SEL1FD.

Next, at t15, the reset transistor RST1 is turned on to remove the signal charge Q2 of the floating diffusion region FD1. Thus, the floating diffusion region FD1 is brought into a reset state.

Next, at t16, the reset transistor RST1 is turned off, and the signal voltage based on the reset state of the floating diffusion region FD1 is transmitted to the vertical signal line VSL1FD via the selection transistor SELIFD. In this case, reading of the signal charge Q2 of the floating diffusion region FD1 is the DDS processing as described above.

Next, at t17, the reset transistor RST1 is turned on to bring the floating diffusion region FD1 into a reset state again.

Next, at t18, the reset transistor RST1 is turned off, and the signal voltage based on the reset state of the floating diffusion region FD1 is transmitted to the vertical signal line VSL1FD via the selection transistor SELIFD. The reset state read at this time may be considered to be the same as the reset state of the capacitor layer C1.

Next, at t19, the reset transistor RST1C is turned on, and the signal charge Q1 of the capacitor layer C1 is transferred to the floating diffusion region FD1.

Next, at t20, the reset transistor RST1C is turned off, and the signal voltage based on the signal charge Q1 of the floating diffusion region FD1 is transmitted to the vertical signal line VSL1FD via the selection transistor SEL1FD.

Next, at t21, the reset transistor RST1 is turned on to remove the signal charge Q1 of the floating diffusion region FD1. Thus, the floating diffusion region FD1 is brought into a reset state again.

Next, at t22, the reset transistor RST1 is turned off, and at t23, the selection transistor SELIFD is turned off. Moreover, at t24, by turning off the charge discharge transistor TD, the pixel 10 can perform a charge accumulation operation.

In this example, the pixel 10 outputs the signal state of the signal charge Q1 after outputting the reset state of the capacitor layer C1. Therefore, the signal processing section 26 can perform the CDS processing on the signal charge Q1 of the capacitor layer C1.

In the example of FIG. 77, both the signal charges Q1 and Q2 are detected in the same floating diffusion region FD1 and output to the vertical signal line VSL1FD. Therefore, since the photoelectric conversion efficiency does not differ, it is not necessary to consider the difference in photoelectric conversion efficiency between the capacitor layer C1 and the floating diffusion region FD1 when calculating the combined signal of the signal charges Q1 and Q2.

### 53rd Embodiment

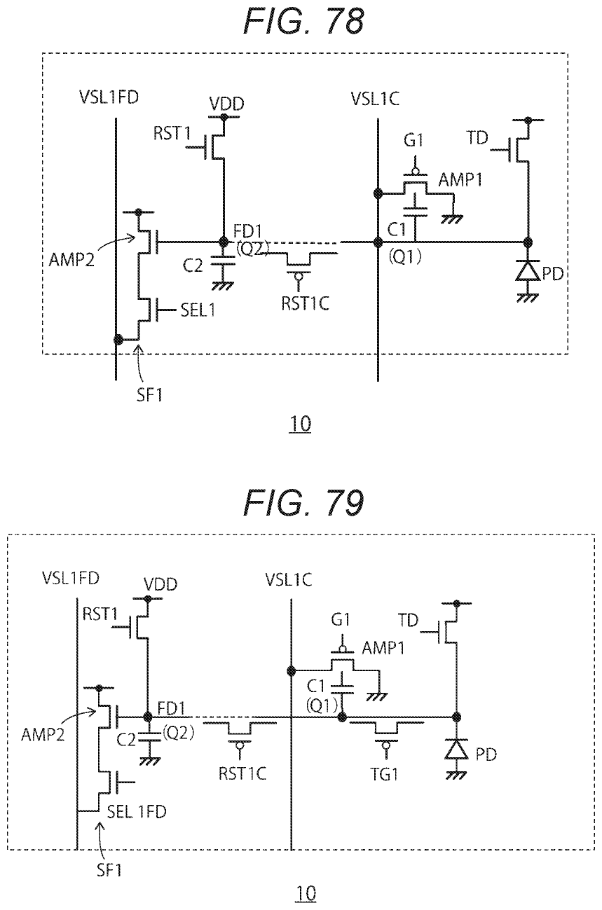

FIG. 78 is an equivalent circuit diagram illustrating an example of a configuration of the pixel 10 according to a 53rd embodiment. The pixel 10 according to the present embodiment includes the reset transistor RST1C, but the selection transistor SELIC and the transfer transistor TG1 are omitted. Other configurations of the present embodiment may be similar to those of the 52nd embodiment. In the present embodiment, the dynamic range can be expanded similarly to the 52nd embodiment while the pixel region 21 is made smaller than that in the 52nd embodiment.

The operation of the present embodiment may be basically the same as that of the 52nd embodiment except that the selection transistor SELIC and the transfer transistor TG1 are omitted. Therefore, the present embodiment can obtain the effect of the 52nd embodiment.

### 54th Embodiment

FIG. 79 is an equivalent circuit diagram illustrating an example of a configuration of the pixel 10 according to a 54th embodiment. The pixel 10 according to the present embodiment includes the reset transistor RST1C and the transfer transistor TG1, but the selection transistor SELIC is omitted. Other configurations of the present embodiment may be similar to those of the 52nd embodiment. In the present embodiment, the dynamic range can be expanded similarly to the 52nd embodiment while the pixel region 21 is made smaller than that in the 52nd embodiment.

The operation of the present embodiment may be basically the same as that of the 52nd embodiment except that the selection transistor SELIC is omitted. Therefore, the present embodiment can obtain the effect of the 52nd embodiment.

### 55th Embodiment

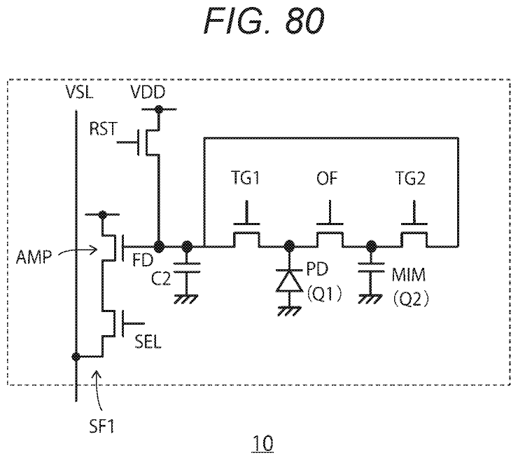

FIG. 80 is an equivalent circuit diagram illustrating an example of a configuration of the pixel 10 according to a 55th embodiment. The pixel 10 according to the present embodiment does not include a channel modulation transistor, and signal charges accumulated in the photodiode PD are Q1, and signal charges accumulated in a capacitor element MIM (Metal Insulator Metal) are Q2. The capacitor element MIM is a capacitor element in which a metal layer, an insulating layer, and a metal layer are stacked.

In the present embodiment, the signal charges Q1 and Q2 are detected using the same floating diffusion region FD and the same source follower circuit SF1. Therefore, the signal charges Q1 and Q2 are detected without being affected by variations in characteristics of the floating diffusion region and the source follower circuit. Furthermore, the dynamic range can be increased by using the signal charges Q1 and Q2.

The pixel 10 includes the transfer transistors TG1 and TG2, an overflow transistor OF, and the capacitor element MIM. The transfer transistor TG1 is connected between the photodiode PD and the floating diffusion region FD. The overflow transistor OF is connected between the photodiode PD and the capacitor element MIM. The transfer transistor TG2 is connected between the capacitor element MIM and the floating diffusion region FD. That is, the overflow transistor OF and the transfer transistor TG2 are connected in series between the photodiode PD and the floating diffusion region FD. The capacitor element MIM as the third capacitive element is connected between a node between the overflow transistor OF and the transfer transistor TG2 and the ground (reference power supply).

The capacitance of the capacitor element MIM is larger than the capacitance of the photodiode PD. Furthermore, the capacitance of the capacitor element MIM is larger than the capacitance of the capacitor layer C2. The configurations of the reset transistor RST and the source follower circuit SF1 may be similar to those of the 54th embodiment.

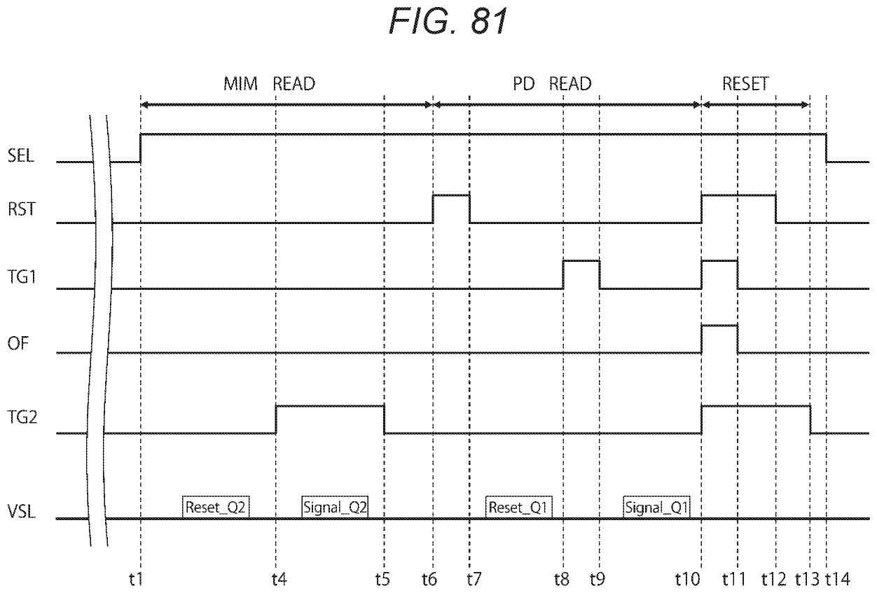

FIG. 81 is a timing chart illustrating an example of a read operation of the pixel 10 according to the 55th embodiment. First, as an initial state, the photodiode PD, the capacitor element MIM, and the floating diffusion region FD do not accumulate charges.

Next, before t1, the photodiode PD receives light and accumulates signal charges. In a case where the amount of light is small, the photodiode PD accumulates the signal charge Q1. In a case where the amount of light is large, the charges having overflowed the photodiode PD are accumulated in the capacitor element MIM. The signal charge accumulated in the capacitor element MIM becomes Q2.

After the charge accumulation is ended, the read operation of the capacitor element MIM is started. At t1, the selection transistor SEL is turned on, and the reset state of the floating diffusion region FD is detected.

Next, at t4 to t5, the transfer transistor TG2 is turned on, and the signal charge of the capacitor element MIM is transferred to the floating diffusion region FD and the capacitor layer C2. Thus, a signal voltage based on the signal charge Q2 of the capacitor element MIM is transmitted to the vertical signal line VSL via the selection transistor SEL. The signal charge Q2 is detected while the transfer transistor TG2 is turned on. Therefore, the signal charge Q2 is detected with conversion efficiency corresponding to the combined capacitance of the floating diffusion region FD, the capacitor layer C2, and the capacitor element MIM.

Next, the read operation of the photodiode PD is started. From t6 to t7, the reset transistor RST is turned on, the charges of the floating diffusion region FD and the capacitor layer C2 are removed, and the floating diffusion region FD and the capacitor layer C2 are brought into reset states. Next, in t7 to t8, the reset state of the floating diffusion region FD is detected.

Next, at t8 to t9, the transfer transistor TG1 is turned on, and the signal charge Q1 of the photodiode PD is transferred to the floating diffusion region FD and the capacitor layer C2. From t9 to t10, a signal voltage based on the signal charge Q1 of the photodiode PD is transmitted to the vertical signal line VSL via the selection transistor SEL. The signal charge Q1 is detected after the transfer transistor TG1 is turned off. Therefore, the signal charge Q1 is detected with conversion efficiency corresponding to the capacitance of the floating diffusion region FD and the capacitor layer C2.

Next, from t10 to t11, the reset transistor RST, the transfer transistors TG1 and TG2, and the overflow transistor OF are turned on. Thus, charges are removed from the floating diffusion region FD, the capacitor layer C2, the capacitor element MIM, and the photodiode PD, and the floating diffusion region FD, the capacitor layer C2, the capacitor element MIM, and the photodiode PD are brought into reset states.

Next, at t11, the transfer transistor TG1 and the overflow transistor OF are turned off, and the photodiode PD is electrically separated from the capacitor element MIM and the floating diffusion region FD. Moreover, at t12, the reset transistor RST is turned off, and the floating diffusion region FD and the capacitor layer C2 are disconnected from the power supply VDD. At t13, the transfer transistor TG2 is turned off, and the capacitor element MIM is disconnected from the floating diffusion region FD and the capacitor layer C2. At t14, the selection transistor SEL becomes an OFF state, and the pixel 10 enters the accumulation operation again.

As described above, according to the present embodiment, in a case where the amount of light is small, only the photodiode PD accumulates the signal charge Q1. In this case, the signal charge Q1 is detected with a relatively small capacitance of the floating diffusion region FD and the capacitor layer C2. Thus, the pixel 10 can convert fine light with high conversion efficiency.

On the other hand, in a case where the amount of light is large, the signal charge Q2 accumulated in the capacitor element MIM is detected by relatively large capacitances of the floating diffusion region FD, the capacitor layer C2, and the capacitor element MIM. Thus, the pixel 10 can convert light with a large light amount.

Furthermore, in the present embodiment, the pixel 10 detects the signal charges Q1 and Q2 after detecting the reset state. Therefore, the signal processing section 26 can perform the CDS processing on a signal corresponding to any of the signal charges Q1 and Q2. Therefore, a signal can be obtained when the signal-to-noise ratio (S/N ratio) is favorable.

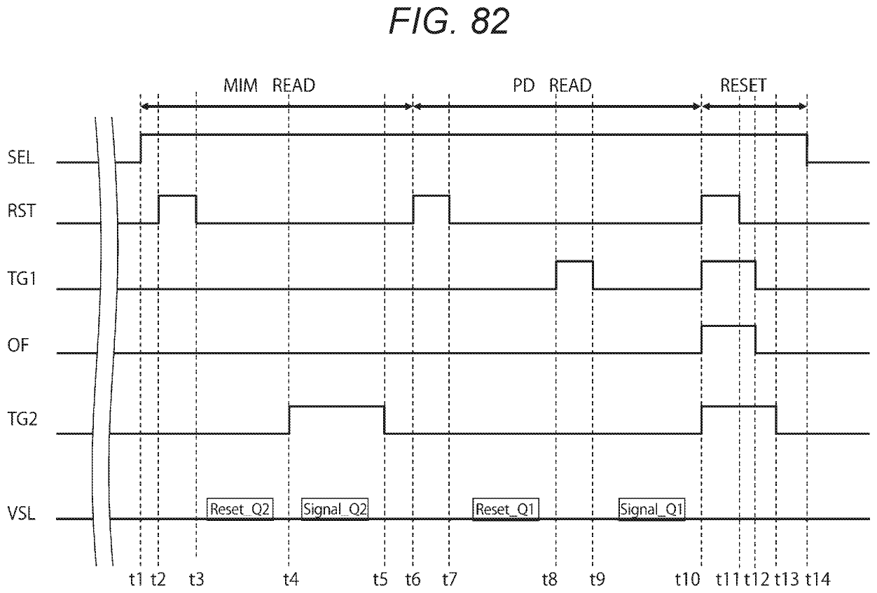

FIG. 82 is a timing chart illustrating another example of the read operation of the pixel 10 according to the 55th embodiment. First, as an initial state, the photodiode PD, the capacitor element MIM, and the floating diffusion region FD do not accumulate charges.

Next, before t1, the photodiode PD receives light and accumulates signal charges. This charge accumulation operation is as described with reference to FIG. 81.

After the charge accumulation is ended, the read operation of the capacitor element MIM is started. At t1, the selection transistor SEL is turned on, and at t2, the reset transistor RST is turned on. Thus, the charges of the floating diffusion region FD and the capacitor layer C2 are removed, and the floating diffusion region FD and the capacitor layer C2 are brought into reset states.

At t3, the reset transistor RST is turned off, and the reset state of the floating diffusion region FD is detected.

Next, the read operation of the signal charge Q2 at t4 to t5 may be the same as the read operation at t4 to t5 in FIG. 81.

Next, the read operation of the photodiode PD is started. From t6 to t7, the reset transistor RST is turned on, and the floating diffusion region FD and the capacitor layer C2 are brought into reset states.

The read operation in the reset state and the read operation of the signal charge Q1 in t7 to t10 may be the same as the read operation in t7 to t10 in FIG. 81.

Next, from t10 to t11, the reset transistor RST, the transfer transistors TG1 and TG2, and the overflow transistor OF are turned on. Thus, charges are removed from the floating diffusion region FD, the capacitor layer C2, the capacitor element MIM, and the photodiode PD, and the floating diffusion region FD, the capacitor layer C2, the capacitor element MIM, and the photodiode PD are brought into reset states.

Next, at t11, the reset transistor RST is turned off, at t12, the transfer transistor TG1 and the overflow transistor OF are turned off, and at t13, the transfer transistor TG2 is turned off. At t14, the selection transistor SEL becomes an OFF state, and the pixel 10 enters the accumulation operation again.

In this example, the floating diffusion region FD and the capacitor layer C1 are reset every time the signal charges Q1 and Q2 are detected. Therefore, kTC noise components included in the read signals of the signal charge Q1 and the signal charge Q2 are different from each other. Thus, the read operation of the signal charges Q1 and Q2 becomes a DDS operation. However, the dynamic range of the detectable light amount can be expanded.

### 56th Embodiment

FIG. 83 is an equivalent circuit diagram illustrating an example of a configuration of the pixel 10 according to a 56th embodiment. The pixel 10 according to the present embodiment is different from that of the 55th embodiment in that a CCD element and a capacitor layer Cc are used as capacitor elements instead of the MIM capacitance. The CCD element is provided between the overflow transistor OF and the transfer transistor TG2, and can completely transfer the charge accumulated in the capacitor layer Cc. Therefore, any signal corresponding to the signal charges Q1 and Q2 can be subjected to the CDS processing. Therefore, the CIS according to the present embodiment can obtain a signal with a favorable S/N ratio. Note that the capacitance of the capacitor layer Cc is sufficiently larger than the capacitance of the photodiode PD.

In the present embodiment, the signal charges Q1 and Q2 are detected using the same floating diffusion region FD and the same source follower circuit SF1. Therefore, the signal charges Q1 and Q2 are detected without being affected by variations in characteristics of the floating diffusion region and the source follower circuit. Furthermore, the dynamic range can be increased by using the photodiode PD and the capacitor layer Cc.

Other configurations of the present embodiment may be similar to corresponding configurations of the 55th embodiment. Therefore, the 56th embodiment can also obtain effects similar to those of the 55th embodiment.

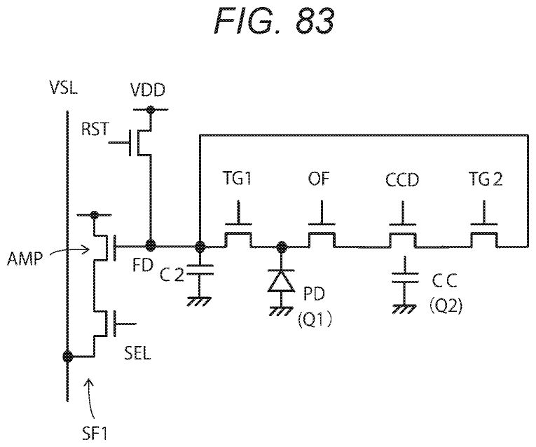

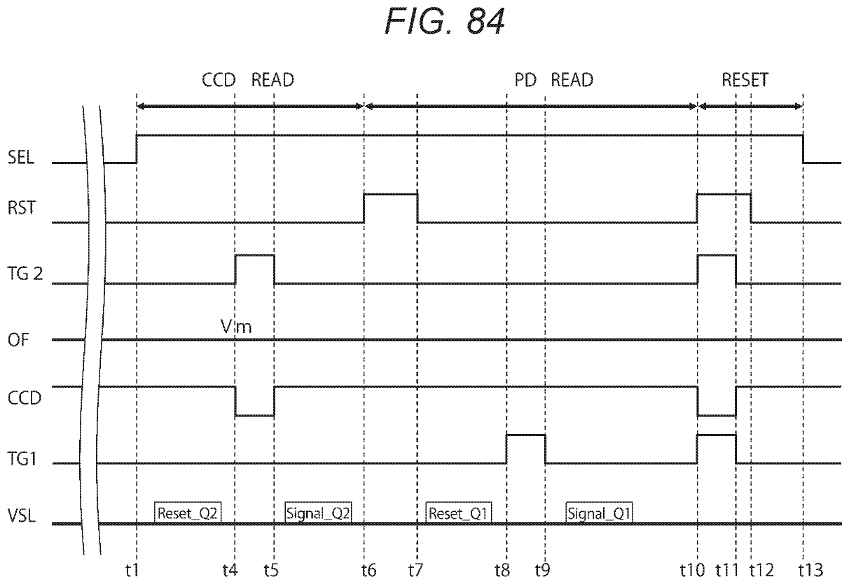

FIG. 84 is a timing chart illustrating an example of a read operation of the pixel 10 according to the 56th embodiment. First, as an initial state, the photodiode PD, the CCD element, and the floating diffusion region FD do not accumulate charges.

Next, before t1, the photodiode PD receives light and accumulates signal charges. The gate voltage of the overflow transistor OF is substantially an intermediate voltage Vm between the high level and the low level, and is in an intermediate conductive state between on and off.

In a case where the amount of light is small, the photodiode PD accumulates the signal charge Q1. In a case where the amount of light is large, the charge having overflowed the photodiode PD is accumulated in the capacitor layer Cc immediately below the CCD element. The signal charge accumulated in the capacitor layer Cc becomes Q2.

After the charge accumulation is ended, the read operation of the signal charge Q2 of the capacitor layer Cc is started. At t1, the selection transistor SEL is turned on, and the reset state of the floating diffusion region FD is detected.

Next, from t4 to t5, the CCD element is turned off, and the transfer transistor TG2 is turned on. Thus, the signal charge Q2 of the capacitor layer Cc is transferred to the floating diffusion region FD and the capacitor layer C2. At t5, the CCD element is turned on, and the transfer transistor TG2 is turned off.

Next, at t5 to t6, a signal voltage based on the signal charge Q2 of the capacitor layer Cc is transmitted to the vertical signal line VSL via the selection transistor SEL.

Next, the read operation of the photodiode PD is started. From t6 to t7, the reset transistor RST is turned on, and the floating diffusion region FD and the capacitor layer C2 are brought into reset states.

The read operation in the reset state and the read operation of the signal charge Q1 in t7 to t10 may be the same as the read operation in t7 to t10 in FIG. 81.

Next, from t10 to tl1, the reset transistor RST and the transfer transistors TG1 and TG2 are turned on. The CCD element may be off. Thus, charges are removed from the floating diffusion region FD, the capacitor layer C2, the capacitor layer Cc, and the photodiode PD, and the floating diffusion region FD, the capacitor layer C2, the capacitor element MIM, and the photodiode PD are brought into reset states.

Next, at t11, the transfer transistors TG1 and TG2 are turned off, and the CCD element is turned on. At t12, the reset transistor RST becomes an OFF state, and at t13, the selection transistor SEL is turned off. Thus, the pixel 10 enters the accumulation operation again.

In the present embodiment, the CCD element and the capacitor layer Cc are used instead of the MIM capacitance, but effects similar to those of the 55th embodiment can be obtained.

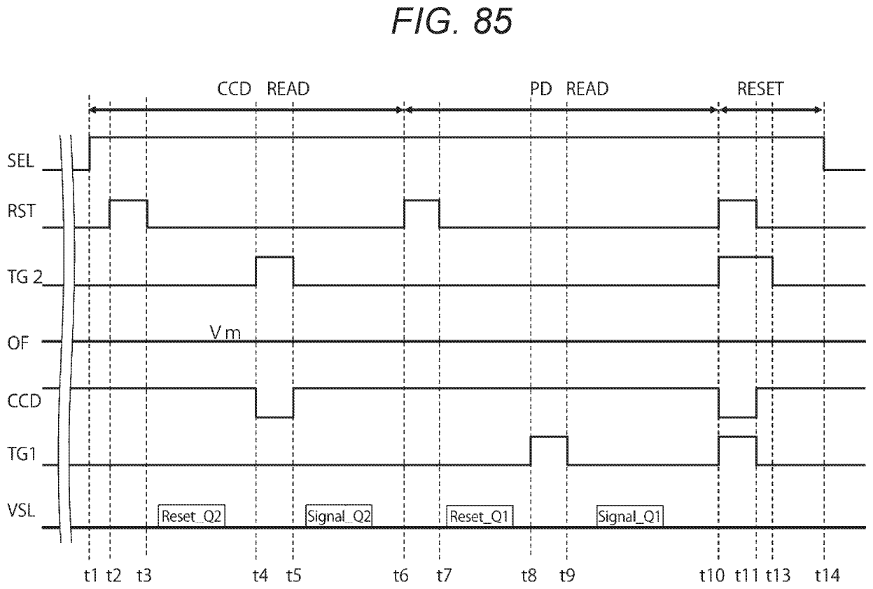

FIG. 85 is a timing chart illustrating an example of a read operation of the pixel 10 according to the 56th embodiment. First, as an initial state, the photodiode PD, the CCD element, and the floating diffusion region FD do not accumulate charges. Next, before t1, the photodiode PD receives light and accumulates signal charges. The charge accumulation operation is as described in FIG. 84.

After the charge accumulation is ended, the read operation of the signal charge Q2 of the capacitor layer Cc is started. At t1, the selection transistor SEL is turned on, and the reset state of the floating diffusion region FD is detected.

Next, at t2 to t3, the reset transistor RST is turned on, and charges are removed from the floating diffusion region FD and the capacitor layer C2 and reset. In a case where the dark current generated in the floating diffusion region FD is large, the reset state of the floating diffusion region FD and the capacitor layer C2 can be accurately detected by removing the charges of the floating diffusion region FD and the capacitor layer C2 immediately before the readout of the reset state.

At t3, after the reset transistor RST is turned off and the reset operation is completed, the read operation of the signal charge Q2 of the capacitor layer Cc and the signal charge Q1 of the photodiode PD at t3 to t10 may be similar to the operation at t3 to t10 of FIG. 84.

The subsequent reset operation from t10 to t14 may be similar to the operation from t10 to t14 in FIG. 84. Note that, in FIG. 85, the reset transistor RST is turned off at t11, and the transfer transistor TG2 is turned off at t13. In this manner, the timings at which the reset transistor RST and the transfer transistor TG2 are turned off may be reversed.

As described above, in the readout of the reset state of the floating diffusion region FD, the charges on the floating diffusion region FD and the capacitor layer C2 may be removed immediately before the readout. Thus, even in a case where the dark current generated in the floating diffusion region FD is large, the reset state of the floating diffusion region FD and the capacitor layer C2 can be accurately detected.

### 57th Embodiment

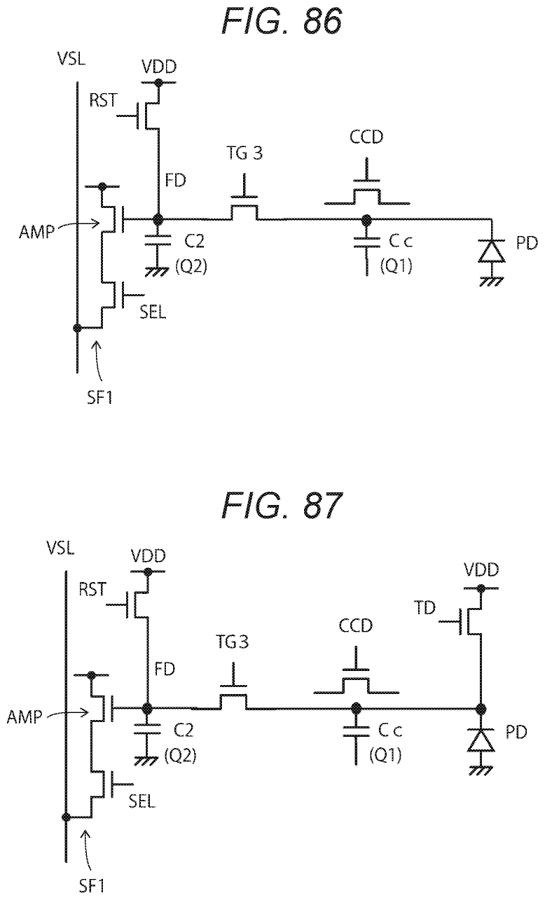

FIG. 86 is an equivalent circuit diagram illustrating an example of a configuration of the pixel 10 according to a 57th embodiment. According to the present embodiment, the CCD element and the transfer transistor TG3 are provided between the photodiode PD and the floating diffusion region FD. The capacitor layer Cc is provided immediately below the CCD element. The capacitor layer Cc can accumulate the charge from the photodiode PD by the operation of the CCD element. For example, when the gate voltage of the CCD element rises to a high level, the capacitor layer Cc accumulates charges (for example, electrons). The CCD element is connected to the floating diffusion region FD via the transfer transistor TG3, but is not directly connected to the floating diffusion region FD.

In the present embodiment, in a case where the amount of light is small, the charge from the photodiode PD is accumulated in the capacitor layer Cc immediately below the CCD element. The signal charge accumulated in the capacitor layer Cc is Q1. In a case where the amount of light is large, the charge having overflowed the capacitor layer Cc is accumulated in the floating diffusion region FD and the capacitor layer C2 via the transfer transistor TG3. The signal charge accumulated in the capacitor layer C2 becomes Q2.

The configurations of the floating diffusion region FD, the capacitor layer C2, the reset transistor RST, and the source follower circuit SF1 may be similar to those of the 56th embodiment.

In the present embodiment, first, a signal voltage corresponding to the signal charge Q2 of the floating diffusion region FD is read out to the vertical signal line VSL. In this case, after the signal charge Q2 of the floating diffusion region FD is detected, the reset state of the floating diffusion region FD is detected. Therefore, reading of the signal charge Q2 is a DDS operation.

Next, the charge Q1 of the capacitor layer Cc is transferred to the floating diffusion region FD by lowering the gate voltage of the CCD element and raising the gate voltage of the transfer transistor TG3. Thus, a signal voltage corresponding to the signal charge Q1 of the floating diffusion region FD is read out to the vertical signal line VSL. At this time, after the reset state of the floating diffusion region FD is detected, the signal charge Q1 of the capacitor layer Cc can be detected. Therefore, for reading of the signal charge Q1, the CDS processing can be performed.

Also in the present embodiment, the signal charges Q1 and Q2 are detected using the same floating diffusion region FD and the same source follower circuit SF1. Therefore, the signal charges Q1 and Q2 are detected without being affected by variations in characteristics of the floating diffusion region and the source follower circuit. Furthermore, the dynamic range can be increased by using the photodiode PD and the capacitor layer Cc.

### 58th Embodiment

FIG. 87 is an equivalent circuit diagram illustrating an example of a configuration of the pixel 10 according to a 58th embodiment. FIG. 88 is a plan view illustrating an example of a layout of the pixel 10 according to the 58th embodiment. According to the present embodiment, the pixel 10 further includes the charge discharge transistor TD that discharges the charge of the photodiode PD. The charge discharge transistor TD is connected between the power supply VDD and the cathode of the photodiode PD, and can discharge the charges (for example, electrons) accumulated in the photodiode PD to the power supply VDD. Therefore, a signal can be obtained when the S/N ratio is favorable.

In the planar layout illustrated in FIG. 88, the CCD element is arranged adjacent to one side of the photodiode PD, and the transfer transistor TG3, the floating diffusion region FD, the reset transistor RST, and the power supply VDD are arranged adjacent to the CCD element in this order. The charge discharge transistor TD is arranged on a side of the photodiode PD opposite to the side on which the CCD element is arranged. The charge discharge transistor TD is, for example, an n-type MOSFET. When the photodiode PD receives the light L, the charge discharge transistor TD is turned off. When the photodiode PD is not receiving the light L, the charge discharge transistor TD is turned on.

Other configurations of the 58th embodiment may be similar to the corresponding configurations of the 57th embodiment. Thus, the 58th embodiment can also obtain the effects of the 57th embodiment.

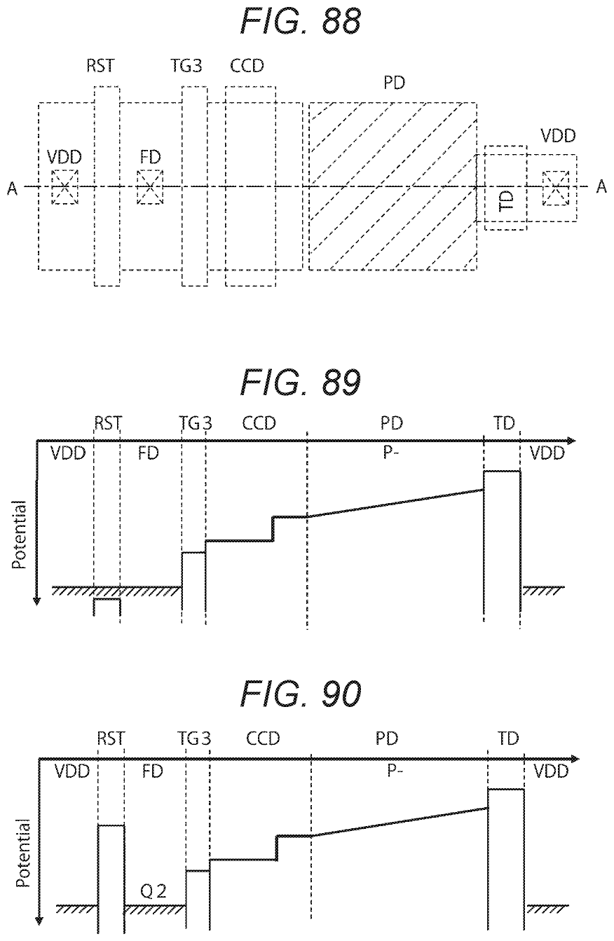

FIGS. 89 to 96 are potential diagrams illustrating an operation of the pixel 10 according to the 58th embodiment. FIGS. 89 to 96 illustrate potentials in a cross section taken along line A-A in FIG. 88. The horizontal axis indicates the position, and the vertical axis indicates the potential. Note that a lower side of the potential is the positive electrode direction.

FIGS. 89 to 91 are examples in which the signal charges Q1 and Q2 are separately accumulated.

As illustrated in FIG. 89, first, the gate voltage of the reset transistor RST is set to a high level, and the reset transistor RST is turned on. Thus, the charges (for example, electrons) in the floating diffusion region FD are removed and the floating diffusion region FD is brought into a reset state.

Next, as illustrated in FIG. 90, after the reset transistor RST is turned off, a signal voltage corresponding to the reset state of the floating diffusion region FD is first output to the vertical signal line VSL via the source follower circuit SF1. In addition, the accumulation operation of signal charges is started. At this time, the potential potential of the CCD element is lower than the potential potential of the transfer transistor TG3. Thus, the signal charge Q2 passes through the CCD element and is accumulated in the floating diffusion region FD. The signal charge Q1 is not yet accumulated in the capacitor layer Cc.

After the signal charge Q2 is accumulated, the signal voltage corresponding to the signal charge Q2 accumulated in the floating diffusion region FD is output to the vertical signal line VSL via the source follower circuit SF1.

Next, as illustrated in FIG. 91, the gate voltage of the transfer transistor TG3 is set to a low level to have a potential lower than the gate voltage of the CCD element. Thus, the signal charge Q1 is accumulated in the capacitor layer Cc immediately below the CCD element.

After the accumulation of the signal charge Q1, as illustrated in FIG. 92, the charge discharge transistor TD is turned on, and the charge of the photodiode PD is removed.

Next, as illustrated in FIG. 93, the reset transistor RST is turned on. Thus, the signal charge Q2 of the floating diffusion region FD is removed and the floating diffusion region FD is brought into a reset state. Next, as illustrated in FIG. 94, after the reset transistor RST is turned off, the signal voltage corresponding to the reset state of the floating diffusion region FD is output to the vertical signal line VSL via the source follower circuit SF1.

Next, as illustrated in FIG. 95, the transfer transistor TG3 is turned on, and the signal charge Q1 is transferred to the floating diffusion region FD. Next, as illustrated in FIG. 96, after the transfer transistor TG3 is turned off, a signal voltage corresponding to the signal charge Q1 transferred to the floating diffusion region FD is output to the vertical signal line VSL via the source follower circuit SF1. Thereafter, the state returns to the reset state in FIG. 89.

According to the present embodiment, both the signal charges Q1 and Q2 are detected after the reset state of the floating diffusion region FD is detected. Therefore, for reading of both the signal charges Q1 and 02, the CDS processing can be performed. Therefore, the S/N ratio is improved.

The signal charges Q1 and 02 may be individually accumulated charges. However, the charge overflowing from the capacitor layer Cc of the CCD element may be accumulated in the floating diffusion region FD as the signal charge Q2. In this case, in a case where the signal charge is smaller than the capacitance of the capacitor layer Cc, since the signal charge does not overflow the capacitor layer Cc, the signal charge Q1 is accumulated only in the capacitor layer Cc, and the signal charge Q2 becomes zero. On the other hand, in a case where the signal charge is larger than the capacitance of the capacitor layer Cc, the signal charge overflows the capacitor layer Cc and is accumulated in the floating diffusion region FD. In this case, the signal charges Q1 and Q2 are accumulated in both the capacitor layer Cc and the floating diffusion region FD.

As described above, the signal charge Q2 may be a signal charge overflowing from the capacitor layer Cc. Consequently, by using the capacitor layer Cc and the floating diffusion region FD, the detectable signal charge amount can be increased, so that the dynamic range of the pixel 10 can be increased.

### 59th Embodiment

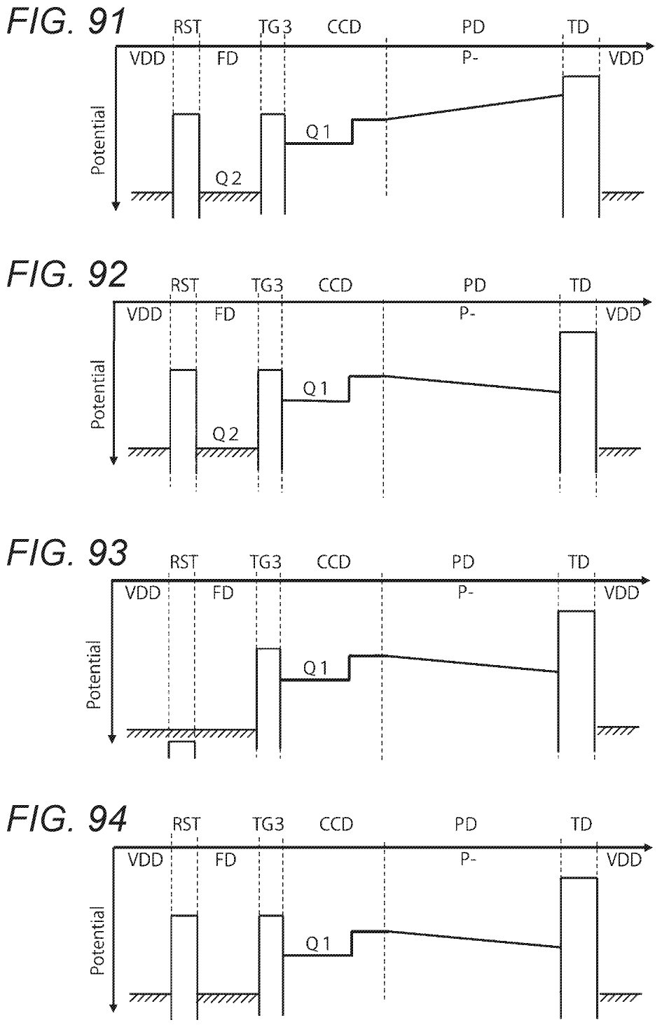

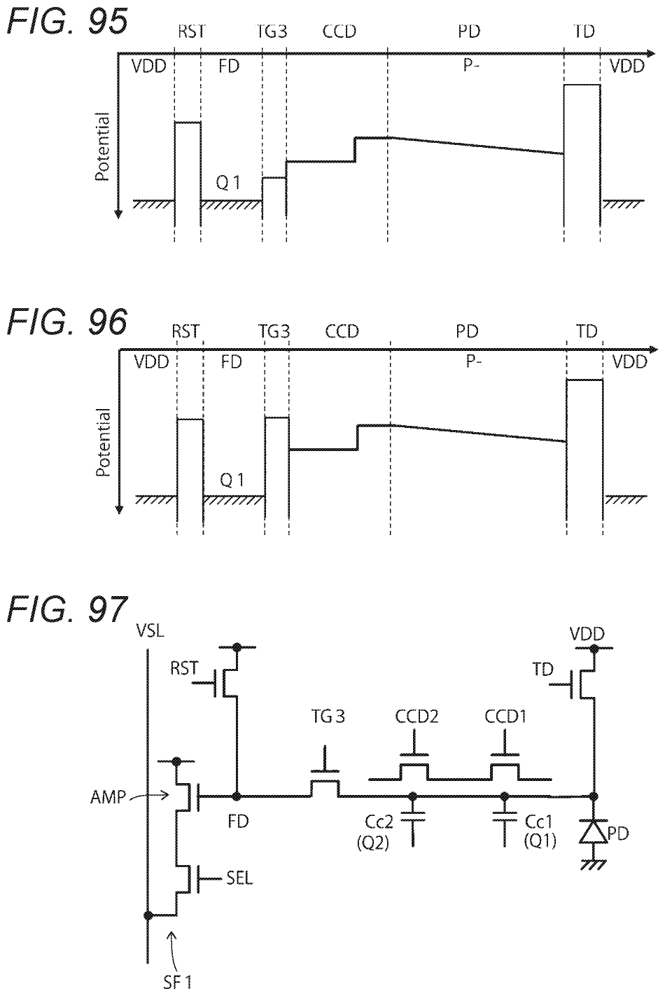

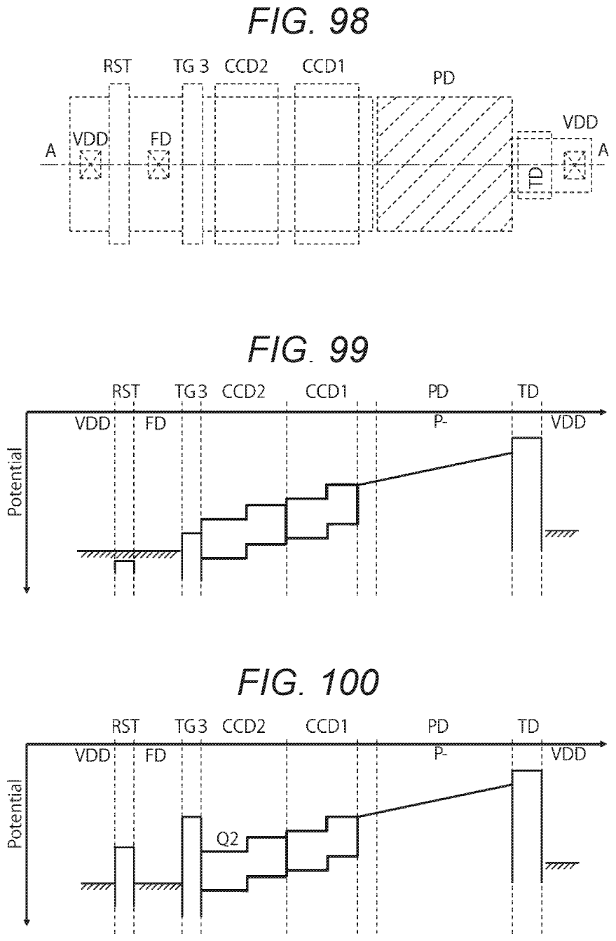

FIG. 97 is an equivalent circuit diagram illustrating an example of a configuration of the pixel 10 according to a 59th embodiment. FIG. 98 is a plan view illustrating an example of a layout of the pixel 10 according to the 59th embodiment. The pixel 10 according to the present embodiment includes a plurality of CCD elements CCD1 and CCD2 (hereinafter simply referred to as CCD1 and CCD2) connected in series between the photodiode PD and the transfer transistor TG3. A capacitor layer Cc1 is provided immediately below the CCD1. A capacitor layer Cc2 is provided immediately below CC2. The capacitor layer C2 is not connected to the floating diffusion region FD.

In the planar layout illustrated in FIG. 98, the CCD1 is arranged adjacent to one side of the photodiode PD, and the CCD2 is arranged adjacent to the CCD1. In addition, the transfer transistor TG3, the floating diffusion region FD, the reset transistor RST, and the power supply VDD are arranged adjacent to the CCD2 in this order. The charge discharge transistor TD is arranged on a side of the photodiode PD opposite to the side on which the CCD element is arranged.

In the present embodiment, the capacitor layer Cc1 immediately below the CCD1 accumulates the signal charge Q1, and the capacitor layer Cc2 immediately below the CCd2 accumulates the signal charge Q2. As in the 58th embodiment, the signal charges Q1 and 02 may be accumulated separately. Alternatively, first, the signal charge Q1 may be accumulated in the capacitor layer Cc1, and the signal charge overflowing from the capacitor layer Cc1 may be accumulated in the capacitor layer Cc2 as the signal charge Q2. Moreover, the signal charges overflowing from the capacitor layers Cc1 and Cc2 may be accumulated in the floating diffusion region FD. Thus, the detectable signal charge amount can be increased, so that the dynamic range of the pixel 10 can be increased.

Furthermore, also in the present embodiment, the signal charges Q1 and Q2 are detected using the same floating diffusion region FD and the same source follower circuit SF1. Therefore, the signal charges Q1 and Q2 are detected without being affected by variations in characteristics of the floating diffusion region and the source follower circuit.

Other configurations of the 59th embodiment may be similar to the corresponding configurations of the 58th embodiment. Thus, the 59th embodiment can also obtain the effects of the 58th embodiment.

FIGS. 99 to 108 are potential diagrams illustrating an operation of the pixel 10 according to the 59th embodiment. FIGS. 99 to 108 illustrate potentials in a cross section taken along line A-A in FIG. 98. The horizontal axis indicates the position, and the vertical axis indicates the potential. Note that the lower side of the potential is the positive electrode direction.

FIGS. 99 to 108 are examples in which the signal charges Q1 and Q2 are separately accumulated.

As illustrated in FIG. 99, first, the gate voltages of the reset transistor RST and the transfer transistor TG3 are set to high levels, and the reset transistor RST and the transfer transistor TG3 are turned on. Thus, the charges (for example, electrons) in the floating diffusion region FD, the CCD1, and the CCD2 are removed, and the floating diffusion region FD, the CCD1, and the CCD2 are brought into a reset state.

Next, as illustrated in FIG. 100, the reset transistor RST and the transfer transistor TG3 are turned off, and the accumulation operation of the signal charge is started. At this time, the gate voltage of the CCD2 is set to a higher level than the gate voltage of the transfer transistor TG3. Thus, the signal charge Q2 is accumulated in the capacitor layer Cc2 of the CCD2. In addition, at this time, the potential of the gate voltage of the CCD2 is lower than the potential of the gate voltage of the CCD1, and thus the signal charge Q1 is not accumulated in the capacitor layer Cc1.

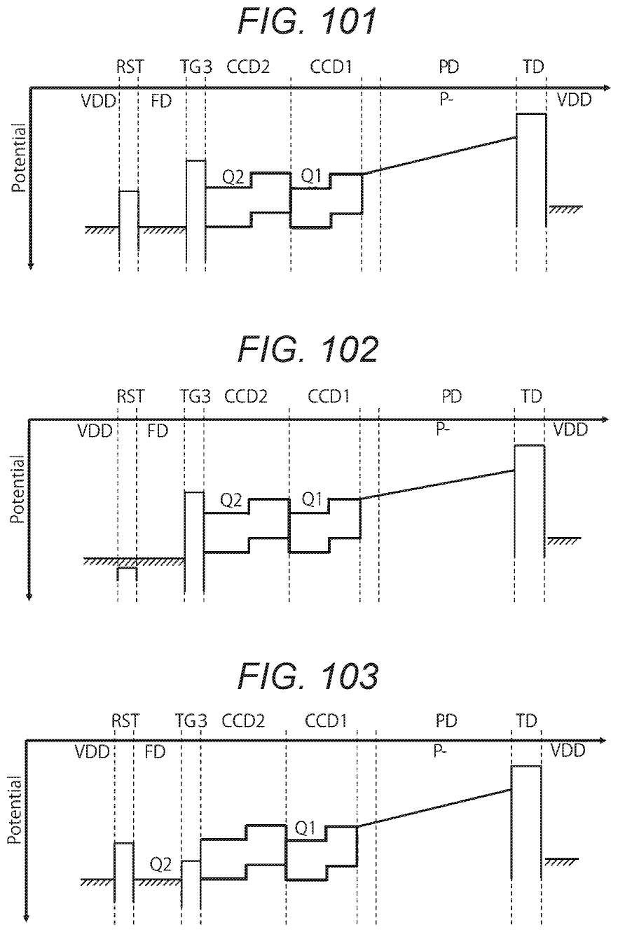

Next, as illustrated in FIG. 101, the gate voltage of the CCD1 is set to a high level, and the signal charge Q1 is accumulated in the capacitor layer Cc2 of the CCD1.

After the accumulation operation of the signal charges Q1 and Q2, as illustrated in FIG. 102, the gate voltage of the reset transistor RST is set to a high level, and the floating diffusion region FD is brought into a reset state again. Thus, the noise components of the PLS in the floating diffusion region FD can be removed. After the reset transistor RST is turned off, a signal voltage corresponding to the reset state of the floating diffusion region FD is first output to the vertical signal line VSL via the source follower circuit SF1.

Next, as illustrated in FIG. 103, the gate voltage of the transfer transistor TG3 is set to a high level. Thus, the transfer transistor TG3 is turned on, and the signal charge Q2 of the CCD1 is transferred to the floating diffusion region FD.

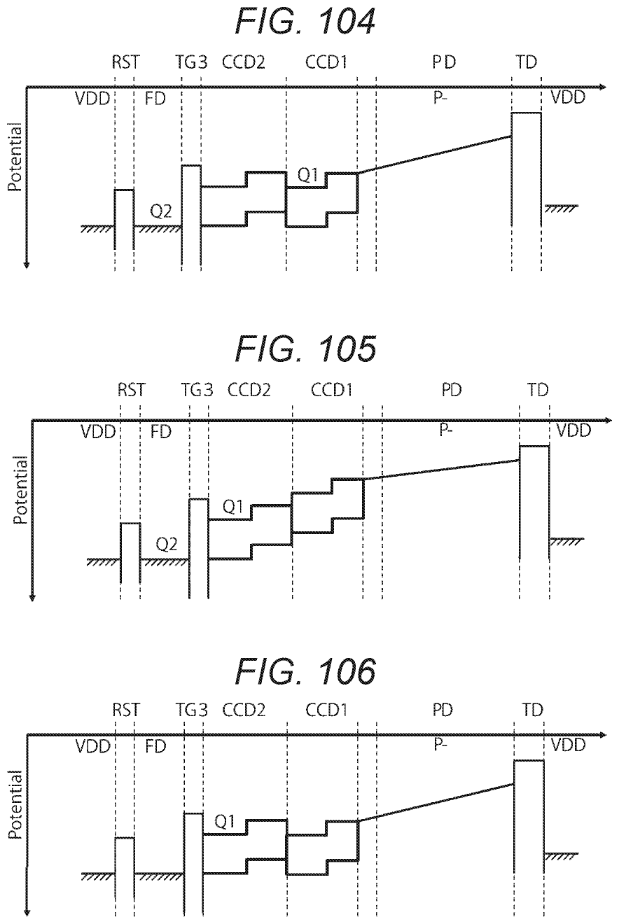

Next, as illustrated in FIG. 104, the gate voltage of the transfer transistor TG3 becomes a low level, and the transfer transistor TG3 is turned off. Next, a signal voltage corresponding to the signal charge Q2 accumulated in the floating diffusion region FD is output to the vertical signal line VSL via the source follower circuit SF1.

Next, as illustrated in FIG. 105, the gate voltage of the CCD1 becomes a low level compared to the gate voltage of the CCD2, and the signal charge Q1 of the capacitor layer Cc1 is transferred to the CCD2.

After the signal voltage corresponding to the signal charge Q2 is read out, the reset transistor RST is turned on again, and as illustrated in FIG. 106, the signal charge Q2 of the floating diffusion region FD is removed and the floating diffusion region FD is brought into a reset state. After the reset transistor RST is turned off, the signal voltage corresponding to the reset state of the floating diffusion region FD is first output to the vertical signal line VSL via the source follower circuit SF1.

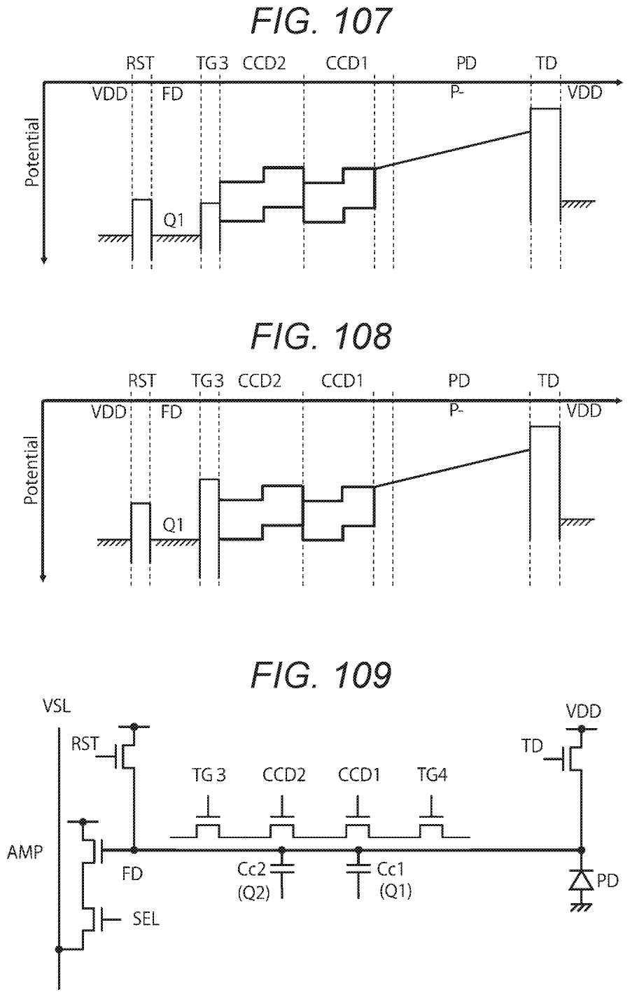

Next, as illustrated in FIG. 107, the gate voltage of the transfer transistor TG3 is set to a high level. Thus, the transfer transistor TG3 is turned on, and the signal charge Q1 transferred to the CCD1 is further transferred to the floating diffusion region FD.

Next, as illustrated in FIG. 108, a signal voltage corresponding to the signal charge Q1 accumulated in the floating diffusion region FD is output to the vertical signal line VSL via the source follower circuit SF1.

Thereafter, as described with reference to FIG. 99, the gate voltage of the reset transistor RST becomes a high level, and the reset transistor RST is turned on. Thus, the signal charge Q1 of the floating diffusion region FD is removed and reset.

In the present embodiment, after the reset state of the floating diffusion region FD is detected, the signal charges Q1 and Q2 of the capacitor layers Cc1 and Cc2 can be detected. Therefore, for reading of the signal charges Q1 and Q2, the CDS processing can be performed. Consequently, the S/N ratio is improved.

As described above, the signal charges Q1 and 02 may be charges accumulated separately in the CCD1 and the CCD2, respectively. However, the charge overflowing from the capacitor layer Cc1 of the CCD1 may be accumulated in the CCD2 as the signal charge Q2. In this case, in a case where the signal charge is smaller than the capacitance of the capacitor layer Cc1, since the signal charge does not overflow the capacitor layer Cc1, the signal charge Q1 is accumulated only in the capacitor layer Cc1, and the signal charge Q2 becomes zero. On the other hand, in a case where the signal charge is larger than the capacitance of the capacitor layer Cc1, the signal charge overflows the capacitor layer Cc1 and is accumulated in the capacitor layer Cc2. In this case, the signal charges Q1 and Q2 are accumulated in both the capacitor layers Cc1 and Cc2. By using the capacitor layers Cc1 and Cc2 in this manner, the detectable signal charge amount can be increased, so that the dynamic range of the pixel 10 can be increased.

### 60th Embodiment

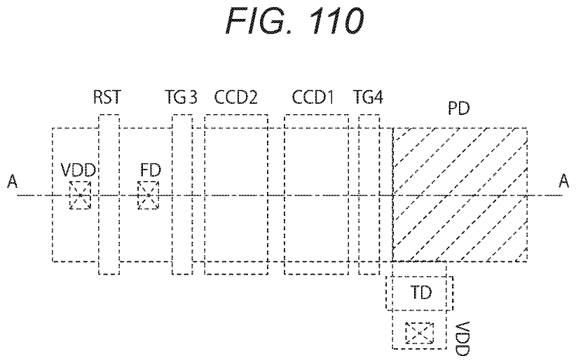

FIG. 109 is an equivalent circuit diagram illustrating an example of a configuration of the pixel 10 according to a 60th embodiment. FIG. 110 is a plan view illustrating an example of a layout of the pixel 10 according to the 60th embodiment. The pixel 10 according to the present embodiment further includes a transfer transistor TG4 between the CCD1 and the photodiode PD. The transfer transistor TG4 can transfer the signal charge of the photodiode PD to the capacitor layer Cc1 of the CCD1. By providing the transfer transistor TG4, the range of the signal charge amount transferred from the photodiode PD to the CCD1 can be increased.

Other configurations of the 60th embodiment may be similar to the corresponding configurations of the 59th embodiment. Thus, the 60th embodiment can also obtain the effects of the 59th embodiment.

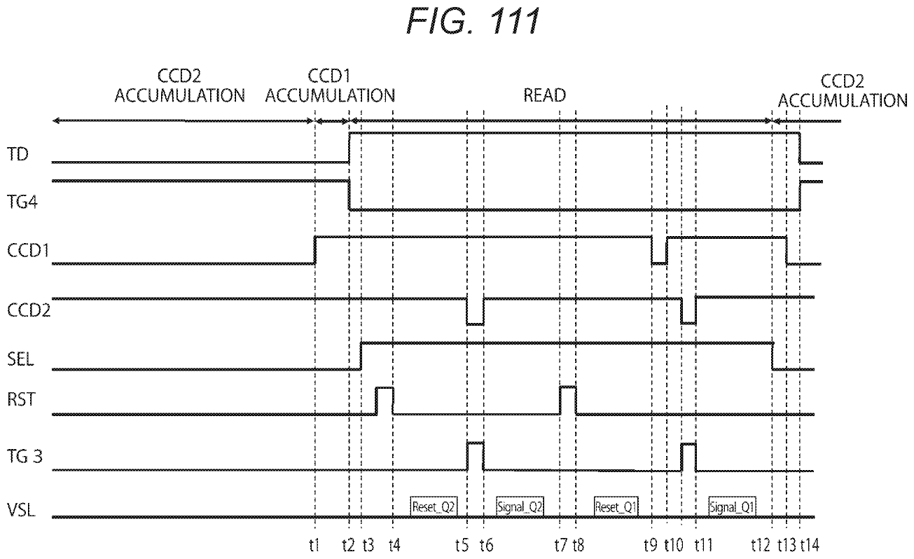

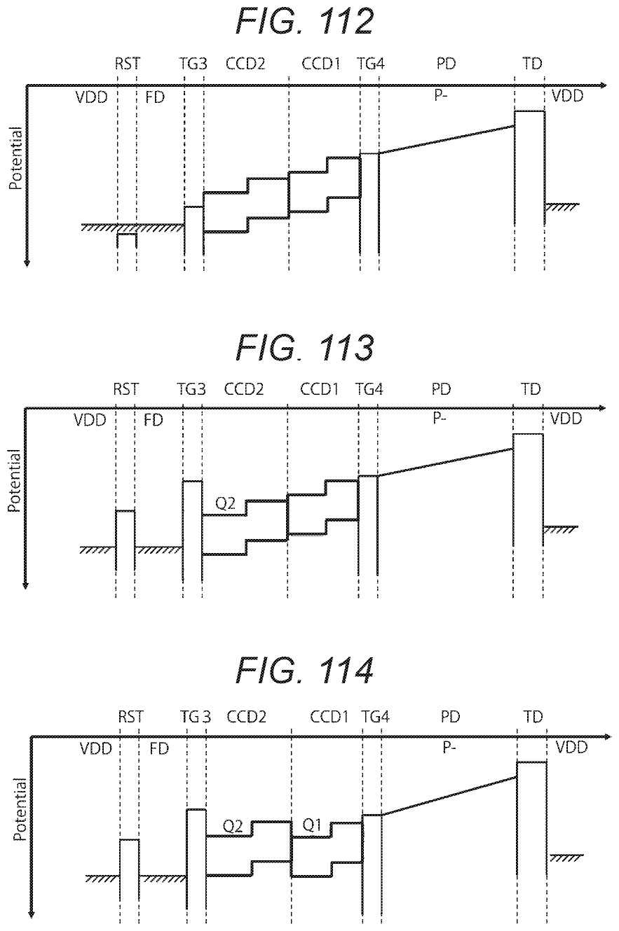

FIG. 111 is a timing chart illustrating an operation of the pixel 10 according to the 60th embodiment. FIGS. 112 to 121 are potential diagrams illustrating an operation of the pixel 10 according to the 60th embodiment. FIGS. 112 to 121 illustrate potentials in a cross section taken along line A-A in FIG. 110. The horizontal axis indicates the position, and the vertical axis indicates the potential. Note that the lower side of the potential is the positive electrode direction. The operation of the pixel 10 according to the present embodiment will be described with reference to FIGS. 111 to 121.

FIGS. 111 to 121 are examples in which the signal charges Q1 and Q2 are separately accumulated.

As illustrated in FIG. 112, first, the gate voltages of the reset transistor RST and the transfer transistor TG3 are set to high levels, and the reset transistor RST and the transfer transistor TG3 are turned on. Thus, the charges (for example, electrons) in the floating diffusion region FD, the CCD1, and the CCD2 are removed, and the floating diffusion region FD, the CCD1, and the CCD2 are brought into a reset state.

Next, as illustrated in FIG. 113, the reset transistor RST and the transfer transistor TG3 are turned off to start accumulation of signal charges. At this time, the gate voltages of the CCD2 and the transfer transistor TG4 are set to high levels, and the CCD2 and the transfer transistor TG4 are turned on. Thus, the signal charge from the photodiode PD is accumulated in the capacitor layer Cc2 of the CCD2 as the signal charge Q2 (before t1 in FIG. 111). At this time, the gate voltage of the CCD1 is lower than the gate voltage of the CCD2, and thus the signal charge Q1 is not accumulated in the capacitor layer Cc1. Note that, before t1 in FIG. 111, the charge discharge transistor TD, the selection transistor SEL, the reset transistor RST, and the CCD1 are turned off.

Next, as illustrated in FIG. 114, the gate voltage of the CCD1 is set to a high level, and the signal charge Q1 is accumulated in the capacitor layer Cc1 of the CCD1 (t1 to t2). After the accumulation operation of the signal charge Q1, the gate voltage of the transfer transistor TG4 is returned to a low level, and the transfer transistor TG4 is turned off (t2). Furthermore, at this time, the charge discharge transistor TD is turned on to discharge the charge of the photodiode PD. Next, the selection transistor SEL is turned on (t3).

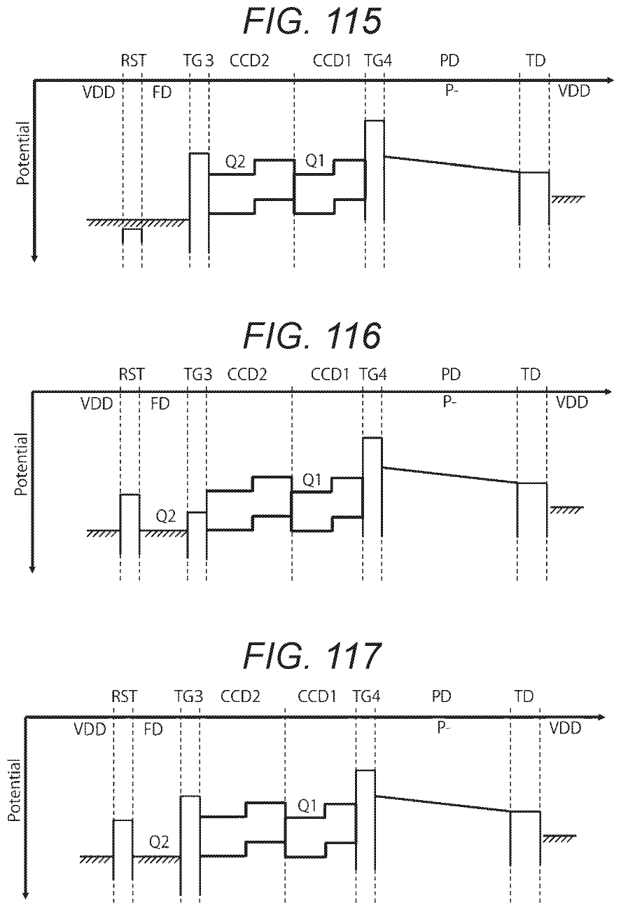

As illustrated in FIG. 115, the gate voltage of the reset transistor RST is set to a high level, and the floating diffusion region FD is brought into a reset state. Thus, the noise components of the PLS in the floating diffusion region FD can be removed. After the reset transistor RST is turned off, a signal voltage corresponding to the reset state of the floating diffusion region FD is output to the vertical signal line VSL via the source follower circuit SF1 (t4 to t5).

Next, as illustrated in FIG. 116, the gate voltage of the transfer transistor TG3 is set to a high level. Thus, the transfer transistor TG3 is turned on, and the signal charge Q2 of the CCD1 is transferred to the floating diffusion region FD (t5 to t6).

Next, as illustrated in FIG. 117, the gate voltage of the transfer transistor TG3 becomes a low level, and the transfer transistor TG3 is turned off. Next, a signal voltage corresponding to the signal charge Q2 accumulated in the floating diffusion region FD is output to the vertical signal line VSL via the source follower circuit SF1 (t6 to t7).

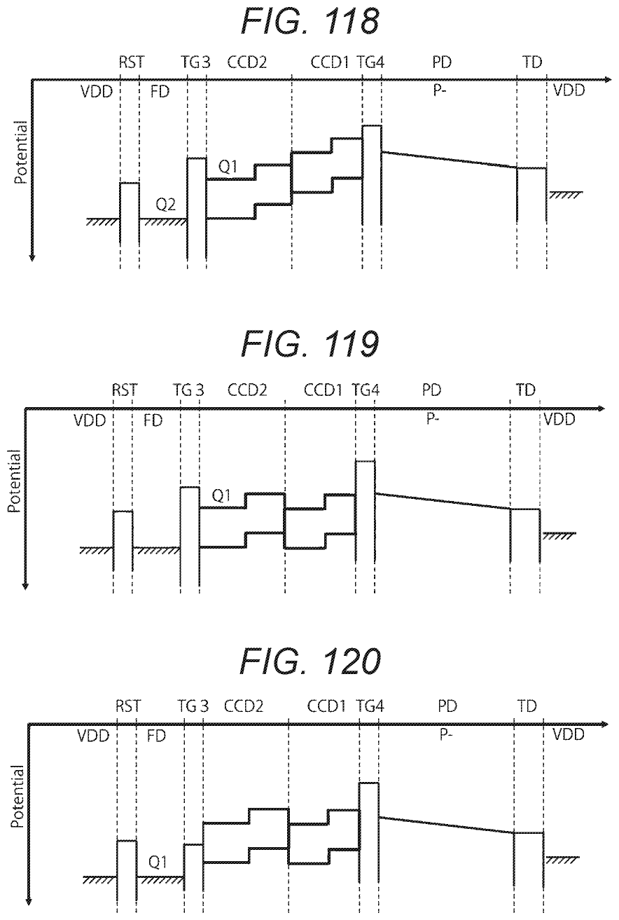

Next, as illustrated in FIG. 118, the gate voltage of CCD1 becomes a low level compared to the gate voltage of CCD2, and the signal charge Q1 of the capacitor layer Cc1 is transferred to CCD2 (t7).

After the signal voltage corresponding to the signal charge Q2 is read out, the reset transistor RST is turned on again, and as illustrated in FIG. 119, the signal charge Q2 of the floating diffusion region FD is removed and the floating diffusion region FD is brought into a reset state (t8). Thus, the noise components of the PLS in the floating diffusion region FD can be removed. After the reset transistor RST is turned off, the signal voltage corresponding to the reset state of the floating diffusion region FD is output to the vertical signal line VSL via the source follower circuit SF1 (t8 to t9).

Next, as illustrated in FIG. 120, the gate voltage of the transfer transistor TG3 is set to the high level. At this time, the gate voltage of the CCD2 may be set to a low level. Thus, the transfer transistor TG3 is turned on, and the signal charge Q1 transferred to the CCD2 is further transferred to the floating diffusion region FD (t10 to t11).

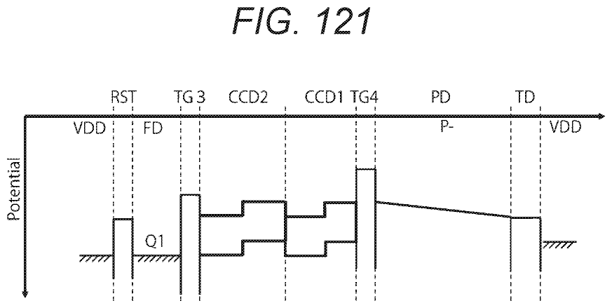

Next, as illustrated in FIG. 121, the transfer transistor TG3 is turned off (t11). At this time, the gate voltage of the CCD2 is set to a high level. Next, a signal voltage corresponding to the signal charge Q1 accumulated in the floating diffusion region FD is output to the vertical signal line VSL via the source follower circuit SF1 (t11 to t12).

Thereafter, the selection transistor SEL, the CCD1, and the charge discharge transistor TD are turned off, and the transfer transistor TG4 is turned on. Moreover, the reset transistor RST is turned on, and the signal charge Q1 of the floating diffusion region FD is removed and reset. Thereafter, the accumulation operation is repeated.

In this manner, the signal charges Q1 and 02 may be read out separately. In addition, the signal charge Q2 may be a signal charge overflowing from the capacitor layer Cc. Consequently, the detectable signal charge amount can be increased, so that the dynamic range of the pixel 10 can be increased.

In the present embodiment, after the reset state of the floating diffusion region FD is detected, the signal charges Q1 and Q2 of the capacitor layers Cc1 and Cc2 can be detected. Therefore, for reading of the signal charges Q1 and Q2, the CDS processing can be performed. Consequently, the S/N ratio is improved.

### 61st Embodiment

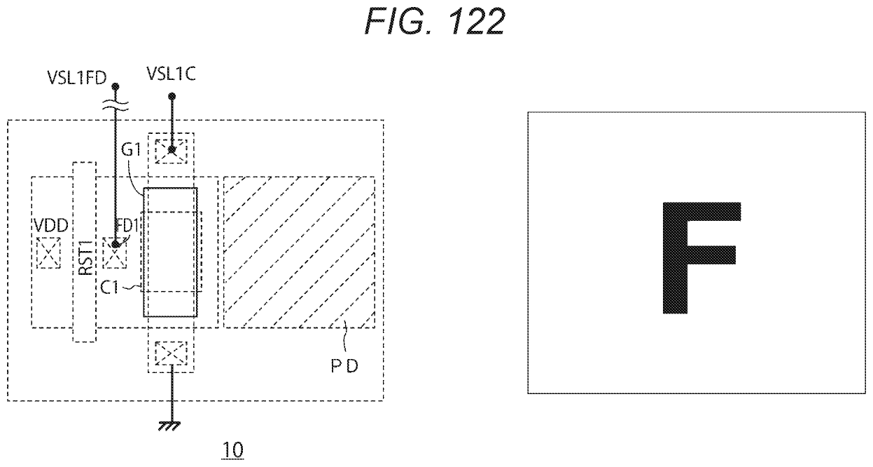

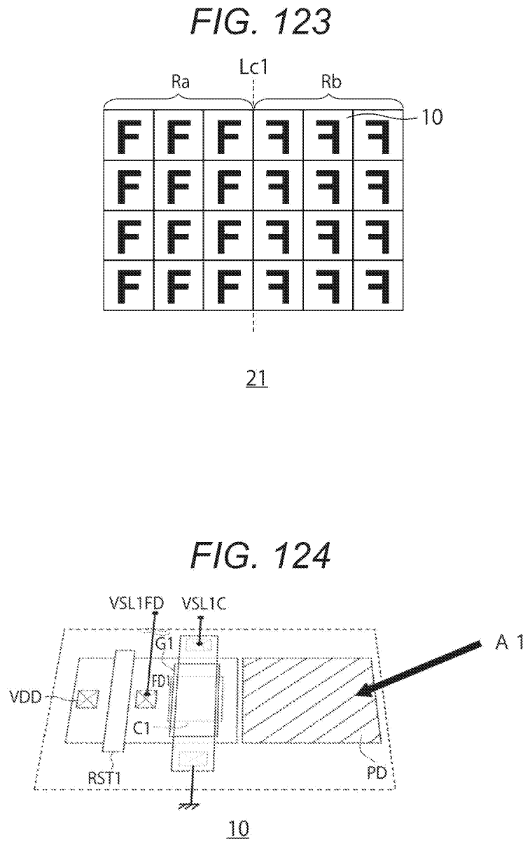

FIG. 122 is a layout diagram illustrating an example of the pixel 10 according to a 61st embodiment and a schematic diagram thereof. FIG. 123 is a schematic diagram illustrating an arrangement example of the pixels 10 in the pixel region 21 according to the 61st embodiment. FIG. 124 is a diagram illustrating an incident direction of light with respect to the pixel 10. The right side “F” in FIG. 122 indicates the layout of the left pixel 10. Hereinafter, a layout F illustrates the pixel 10 in FIG. 122 for convenience. Note that the layout F has the configuration illustrated in FIG. 71, but may be the pixel 10 of another embodiment.

In FIG. 123, in a region Ra with a center line Lc1 of the pixel region 21 as a boundary, the pixels 10 are arranged in the layout F of FIG. 122. On the other hand, in a region Rb, the pixels 10 are arranged in a mirror image layout obtained by horizontally inverting (mirror-inverting) the layout F in FIG. 122. The regions Ra and Rb are provided symmetrically on the left and right sides with respect to the center line Lc1 of the pixel region 21. Note that the number of pixels 10 is not particularly limited.

Normally, light is incident in a direction substantially perpendicular to a light incident surface of the pixel region 21 at the central portion of the pixel region 21. However, as the distance from the center of the pixel region 21 increases, the light is incident on the pixel region 21 while being inclined with respect to the light incident surface due to the influence of an on-chip lens (OCL). In this case, the incident light in the pixel region 21 causes concentric shading. Therefore, the light receiving angle changes depending on the distance and position from the center of the pixel 10 in the pixel region 21, and the sensitivity of each pixel 10 varies, or a problem of color mixing between the pixels 10 occurs.

For example, as illustrated in FIG. 122, in the pixel 10, the arrangement of the photodiodes PD may be locally biased. As described above, in the pixel region 21, light is incident on the pixel 10 in an inclined manner depending on the distance and position from the center of the pixel region 21. When the light is incident on the photodiode PD, the light is converted into signal charges. However, when the light is incident on the floating diffusion region FD or the like other than the photodiode PD, noise is caused. Therefore, it is preferable to allow as much light as possible to be incident on the photodiode PD.

However, since the arrangement of the photodiodes PD is uneven, in a case where the pixels 10 are arranged in the same direction, the amount of light incident on the photodiodes PD changes depending on the distance and position from the center of the pixel region 21.

On the other hand, in the present embodiment, as illustrated in FIG. 123, the pixels are arranged in a left-right symmetrical layout with the center line Lc1 of the pixel region 21 as a boundary. In each pixel 10 in both the regions Ra and Rb, the photodiode PD is arranged to be closer to the center line Lc1 than other configurations in the pixel 10. That is, each pixel 10 is arranged in such a direction that the photodiode PD is unevenly distributed on the center line Lc1 side. Thus, in both the regions Ra and Rb, the light is incident from the direction of arrow A1 in FIG. 124. Consequently, the incident light inclined from the center of the pixel region 21 is more likely to be incident on the photodiode PD than other transistors in the pixel 10 and the floating diffusion region FD. Thus, the pixel region 21 is less likely to be affected by the incident angle of light, and problems of shading, variation in sensitivity, and color mixing can be suppressed. Furthermore, with this arrangement, since the incidence of light on the floating diffusion region FD can be suppressed to some extent, noise due to the PLS can also be suppressed.

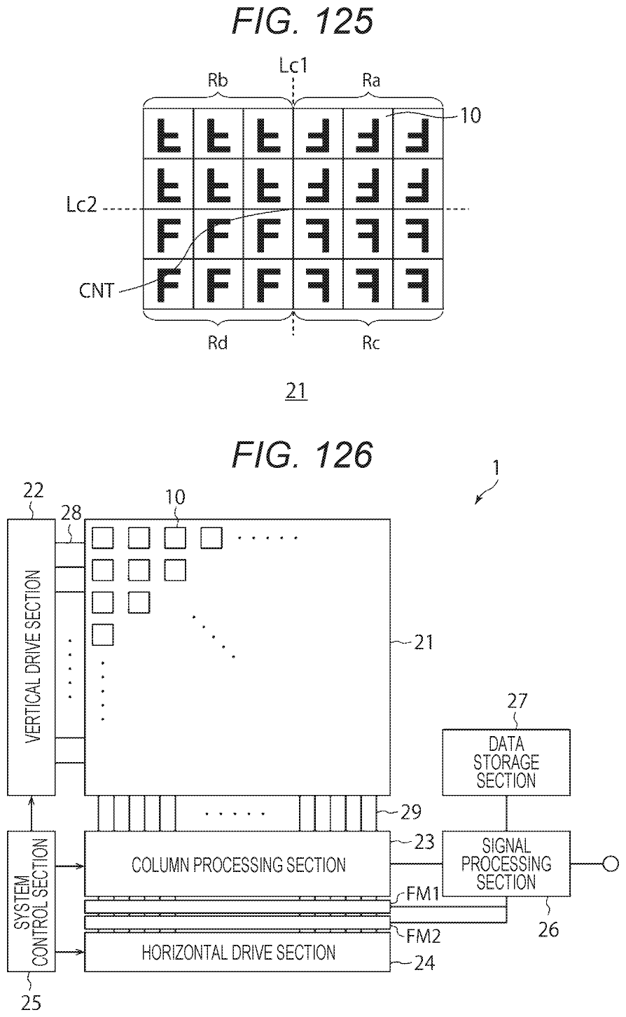

FIG. 125 is a schematic diagram illustrating another arrangement example of the pixels 10 in the pixel region 21 according to the 61st embodiment. In FIG. 124, in the light receiving surface of the pixel region 21, the pixel region 21 is divided into four regions Ra, Rb, Rc, and Rd by the center lines Lc1 and Lc2 of the pixel region 21. The center lines Lc1 and LC2 are center lines of the pixel region 21 substantially orthogonal to each other. In the pixel region 21, the plurality of pixels 10 is arranged symmetrically on the left and right sides with respect to the center line Lc1 as a boundary and symmetrically on the front and rear sides with respect to the center line Lc2 as a boundary. In this example, in each pixel 10 in the regions Ra to Rd, the photodiode PD is arranged so as to be closer to the center lines Lc1 and Lc2 (center CNT) than other configurations in the pixel 10. That is, each pixel 10 is arranged in such a direction that the photodiodes PD are unevenly distributed on the center lines Lc1 and Lc2 (center CNT) side. Thus, in any of the regions Ra to Rd, the light is incident from the direction of arrow A1 in FIG. 124.

Consequently, the incident light inclined from the center of the pixel region 21 is more likely to be incident on the photodiode PD than other transistors in the pixel 10 and the floating diffusion region FD. Thus, the pixel region 21 is less likely to be affected by the incident angle of light, and problems of shading, variation in sensitivity, and color mixing can be suppressed. Furthermore, with this arrangement, since the incidence of light on the floating diffusion region FD can be suppressed to some extent, noise due to the PLS can also be suppressed.

In the examples of FIGS. 123 and 125, the layout of the pixel 10 is divided into 2 quadrants or 4 quadrants, but may be divided into 3 quadrants, 5 quadrants, or more. In this case, it is preferable to be substantially equally divided by a line passing through the center CNT. Furthermore, in any quadrant, the photodiode PD of the pixel 10 is preferably arranged closer to the center CNT.

### 62nd Embodiment

FIG. 126 is a block diagram illustrating a configuration example of a light receiving element. The light receiving element 1 further includes frame memories FM1 and FM2 in contrast to the configuration of FIG. 2. The frame memories FM1 and FM2 are provided between the column processing section 23 and the horizontal drive section 24, and store digital signals after AD conversion in the column processing section 23. Each of the frame memories FM1 and FM2 stores a digital signal for one frame. The frame is data constituting an image, and a plurality of frames constitute a moving image. In a case where the frame rate is high, many frames are required per unit time. For example, an image is constituted of 60 frames or 120 frames per second. The number of frame memories is used to extend the dynamic range of the pixel 10. Note that the number of frame memories is not particularly limited.

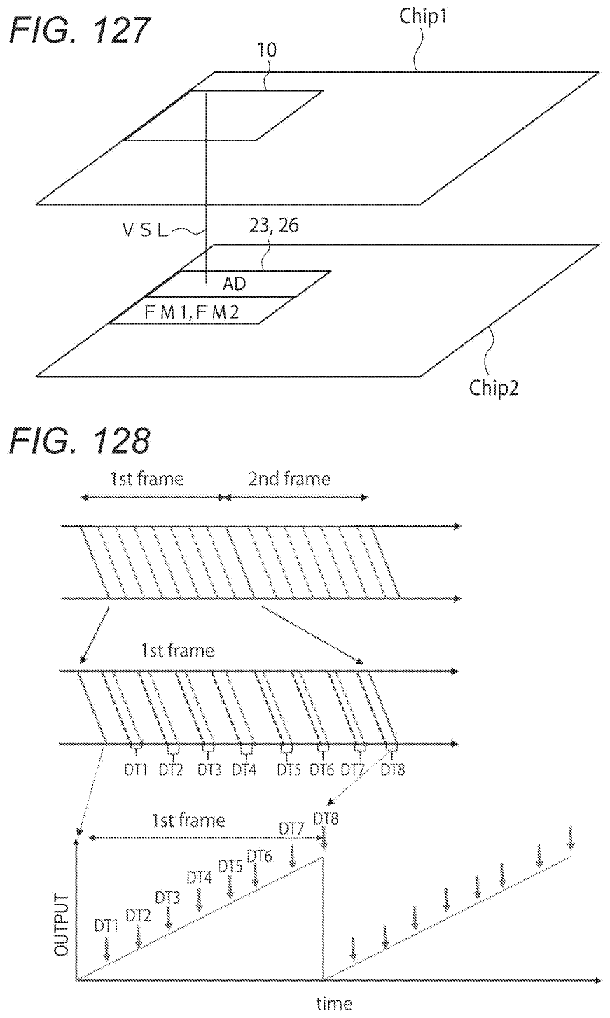

FIG. 127 is a perspective view illustrating a configuration example of a light receiving element capable of storing a digital signal corresponding to the signal charges Q1 and Q2.

The pixel 10 is provided in a first semiconductor chip Chip1. On the other hand, circuits such as the column processing section 23, the signal processing section 26, and the frame memories FM1 and FM2 are provided in a second semiconductor chip Chip2. The semiconductor chips Chip1 and Chip2 are bonded to each other, and wirings of the respective vertical signal lines VSL are bonded to each other (Cu—Cu bonding). Thus, the semiconductor chips Chip1 and Chip2 function as one light receiving element.

Note that a part of the circuits such as the column processing section 23, the signal processing section 26, and the frame memories FM1 and FM2 may be provided in the semiconductor chip Chip1.

### 63rd Embodiment

FIG. 128 is a conceptual diagram illustrating an example of a method of estimating the signal strength of each frame. In a period of one frame (for example, 1/60 seconds), the signal charge is accumulated in the photodiode PD in the pixel 10. However, in a case where the amount of incident light is very large, the signal charge may overflow from the pixel 10 in one frame period. In particular, when the pixel 10 is miniaturized, the capacitance (saturation charge amount) of the photodiode PD decreases, and the possibility of overflow increases. Therefore, according to the present embodiment, the photodiode PD in the pixel 10 accumulates a part of the signal charge in one frame period, and the signal processing section 26 estimates the signal charge of the entire one frame using the part of the signal charge.

For example, it is assumed that the light receiving element according to the present embodiment accumulates signal charges in eight shutter periods obtained by dividing one frame period into eight. Pieces of data DT1 to DT8 are signals corresponding to signal charges accumulated in eight shutter periods. In this case, if all the signal charges corresponding to the eight shutter periods are accumulated, the photodiode PD may overflow.

On the other hand, in the present embodiment, for example, the photodiode PD accumulates only the signal charges corresponding to the first two shutter periods, and the signal processing section 26 estimates the piece of data DT8 from the pieces of data DT1 and DT2 corresponding to the two signal charges. The piece of data DT8 may be estimated to be on a substantially linear extension line of the pieces of data DT1 and DT2. As the estimation method, it is only required to use a regression line of a mean square method. As described above, by estimating the signal of the entire frame from the signal of the shutter period of a part of one frame, the dynamic range of the detectable light amount can be substantially expanded even if the capacitance of the photodiode PD is small.

Note that the photodiode PD may accumulate signal charges corresponding to the shutters 3 to k times (k=3 to 7), and the signal processing section 26 may estimate the piece of data DT8 from the pieces of data DT1 to DTk corresponding to these signal charges. Thus, the accuracy of estimation according to the present embodiment is further improved. Furthermore, although one frame is divided into eight in the present embodiment, the number of divisions of one frame is not particularly limited. In a case where one frame is divided into more than 8 (for example, 16 divisions), the dynamic range of the pixel 10 can be further expanded.

### 64th Embodiment

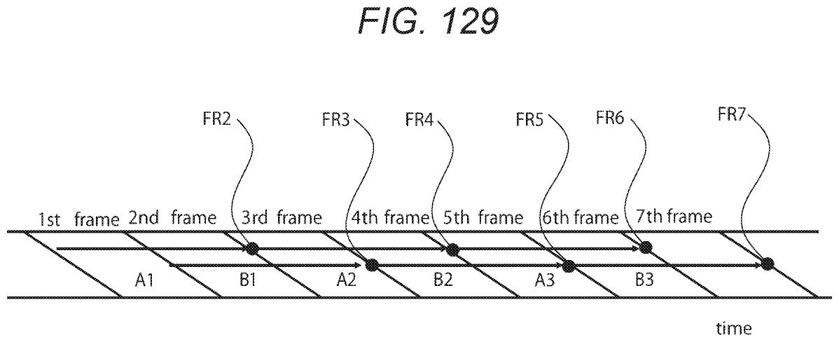

FIG. 129 is a conceptual diagram illustrating another example of the method of estimating the signal strength of each frame. In the present embodiment, the photodiode PD accumulates signal charges in a plurality of frame periods (for example, 2/60 seconds). In a case where the amount of incident light is very small, signal charges are not accumulated much in the photodiode PD in one frame period. In this case, photon shot noise cannot be suppressed. Accordingly, in the present embodiment, the photodiode PD collectively accumulates signal charges in a plurality of frame periods, and the signal processing section 26 estimates a signal of one frame using the signal charges.

For example, the accumulation period of frames A1 to B3 is constant. The photodiode PD accumulates signal charges of two consecutive frames A1 and B1. The signal processing section 26 averages the signals corresponding to the signal charges of the frames A1 and B1 to obtain a signal of the frame B1. Furthermore, the photodiode PD accumulates signal charges of two consecutive frames B1 and A2. The signal processing section 26 averages the signals corresponding to the signal charges of the frames B1 and A2 to obtain a signal of the frame A2. Similarly, the signal processing section 26 averages the signals of the frames A2 and B2 to obtain a signal of the frame B2, and averages the signals of the frames B2 and A3 to obtain an average value thereof as a signal of the frame A3.

Assuming that signal charges for one frame from one pixel include 10000 electrons, the S/N ratio is 20×log (10000 e⁻/√10000 e⁻)=40 dB. Note that e⁻ is the charge element amount of electrons. In the present embodiment, since the signal charge of one pixel is 20000 electrons, the S/N ratio is 20×log (20000 e⁻/√20000 e⁻)=46 dB. That is, as in the present embodiment, by estimating a signal of one frame on the basis of signal charges of two frames, the S/N ratio can be improved by about 6 dB. This means that photon shot noise is suppressed. Note that since the signal of the first frame A1 is detected using the signal charge of one frame A1, the S/N ratio is not improved.

As described above, except for the first frame A1, the signals of the subsequent frames are calculated by averaging the signals of the frame and the previous frame. For this purpose, the signals of the frames A1 to B3 each need to be accumulated in a plurality of nodes.

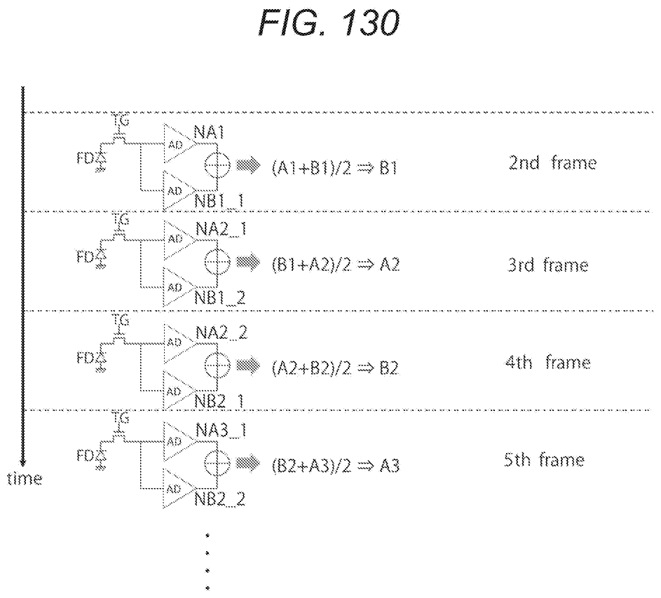

FIG. 130 is a conceptual diagram illustrating an example of a method of calculating a signal of each frame. First, the signal of the first frame A1 (hereinafter, also referred to as a signal A1) is held in the node NA1. The signal of the second frame B1 (hereinafter, also referred to as a signal B1) is held in two nodes NB1_1 and NB1_2. The signal processing section 26 averages the signal A1 of the node NA1 and the signal B1 of the node NB1_1 to obtain a signal B1.

Next, the signal of the third frame A2 (hereinafter, also referred to as a signal A2) is held in two nodes NA2_1 and NA2_2. The signal processing section 26 averages the signal B1 of the node NB1_2 and the signal A2 of the node NA2_1 to obtain a signal A2.

Similarly, the signal of the fourth frame B2 (hereinafter, also referred to as a signal B2) is held in the two nodes NB2_1 and NB2_2. The signal processing section 26 averages the signal A2 of the node NA2_2 and the signal B2 of the node NB2_1 to obtain a signal B2.

The signal of the fifth frame A3 (hereinafter, also referred to as a signal A3) is held in two nodes NA3_1 and NA3_2. The signal processing section 26 averages the signal B2 of the node NB2_2 and the signal B2 of the node NA3_1 to obtain a signal A3.

Thereafter, the signal processing section 26 calculates the signal of each frame by repeating a similar operation. Note that, in the present embodiment, the signal processing section 26 averages the signals of two frames, but may average the signals of three or more frames. Thus, photon shot noise can be further suppressed.

Furthermore, the signal processing section 26 may calculate a signal of one frame from a regression line of the mean square method using signals of a plurality of frames. For example, the signal processing section 26 may obtain a regression line of the mean square method using the signals A1, B1, A2, B2 . . . of the frame and calculate the signal A1 from an equation of the regression line.

The present embodiment can be applied to a case where it is dark and there is a small amount of light, or a case where the size of the photodiode PD is relatively large. In addition, the light receiving element may have a drive mode according to the present embodiment as one mode, and may perform imaging in this mode in a case where the light amount is smaller than a threshold value. Thus, even in a case where the subject is dark, the light receiving element can obtain an image with a good S/N ratio in which photon shot noise is reduced.

### Modification

The 63rd or 64th embodiment may be applied to some of the pixels 10 in the pixel region 21. The other pixel 10 of the pixel region 21 generates a signal of each frame on the basis of the signal charge of the frame.

For example, in a part of the pixel region 21, a part of the signal charges in one frame period is accumulated, and the signal processing section 26 estimates the signal charges of the entire one frame using the part of the signal charges. In another part of the pixel region 21, the signal processing section 26 calculates a signal of one frame using signals of a plurality of frames. The remaining pixels 10 in the pixel region 21 generate a signal of each frame on the basis of the signal charge of the frame. Thus, it is possible to locally expand the dynamic range or reduce photon shot noise for the pixel region 21.

Furthermore, the 63rd or 64th embodiment may be applied to each pixel 10. For example, in a certain pixel 10, a part of the signal charges in one frame period is accumulated, and the signal processing section 26 estimates the signal charges of the entire one frame using the part of the signal charges. In the other pixels 10, the signal processing section 26 calculates a signal of one frame using signals of a plurality of frames. The remaining pixels 10 generate a signal of each frame on the basis of the signal charge of the frame. Thus, the dynamic range can be expanded or photon shot noise can be reduced for each pixel 10.

Further, in a case where the 63rd embodiment is applied, the number of divisions of one frame may be set for each portion of the pixel region 21 or for each pixel 10. Furthermore, in a case where the 64th embodiment is applied, the number of frames used to calculate a signal of one frame may be set for each portion of the pixel region 21 or for each pixel 10. Thus, expansion of the dynamic range or reduction of photon shot noise can be set in more detail in the pixel region 21.

In a case where the 63rd embodiment is applied, the number of divisions of one frame may be randomly set for each portion of the pixel region 21 or for each pixel 10. Furthermore, in a case where the 64th embodiment is applied, the number of frames used to calculate a signal of one frame may be randomly set for each portion of the pixel region 21 or for each pixel 10. In this case, the charge accumulation start, accumulation period, and accumulation end can be randomly set for each portion of the pixel region 21 or for each pixel 10. Therefore, an image with an improved S/N ratio can be obtained. Such a light receiving element can be used for an event-driven sensor or the like.

Furthermore, the charge accumulation time may be started and ended at any timing, and it is only required to set an optimal start point, accumulation time, and end point for each pixel 10. In this operation, since it is necessary to collectively process the AD conversion processing in units of rows, there is a constraint that the accumulation time can be set only with an integral multiple of the AD conversion time. Therefore, the start time point and the end time point cannot be arbitrarily set. Thus, it is suitable for a method of performing AD conversion for each pixel 10. Moreover, the technology can be used for a moving sensor such as an event-driven sensor.

Note that, in a case where the 63rd or 64th embodiment is applied to each pixel, a method of performing AD change for each pixel is preferable.

### (Application Example to Mobile Body)

The technology according to the present disclosure (the present technology) can be applied to various products. For example, the technology according to the present disclosure may be achieved as a device mounted on any type of mobile body such as an automobile, an electric vehicle, a hybrid electric vehicle, a motorcycle, a bicycle, a personal mobility, an airplane, a drone, a boat, a robot, and the like.

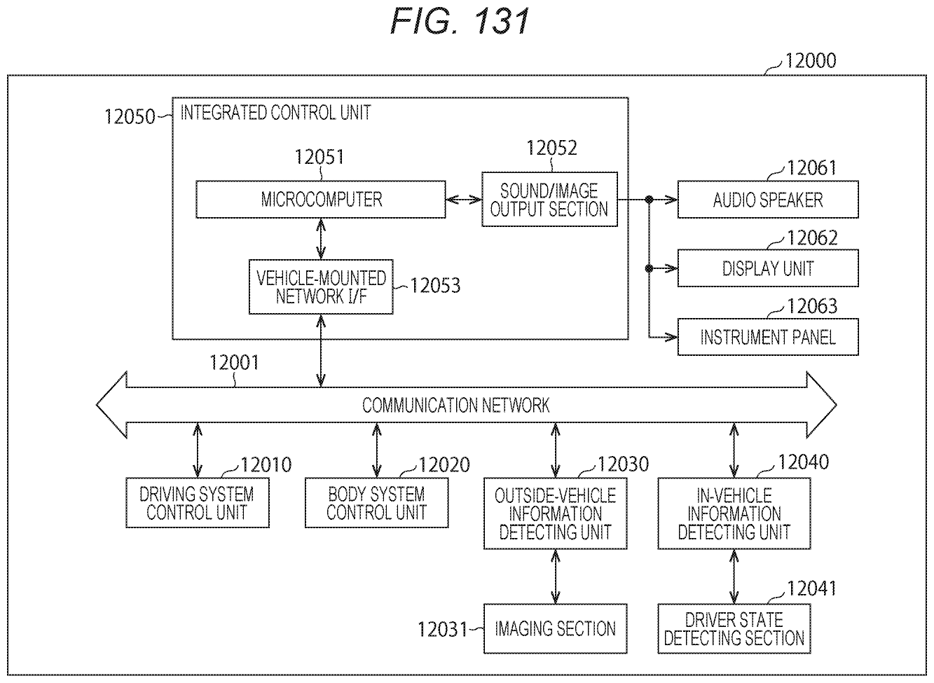

FIG. 131 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 131, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 131, an audio speaker 12061, a display section 12062, and an instrument panel 12063 are illustrated as the output device. The display section 12062 may, for example, include at least one of an on-board display and a head-up display.

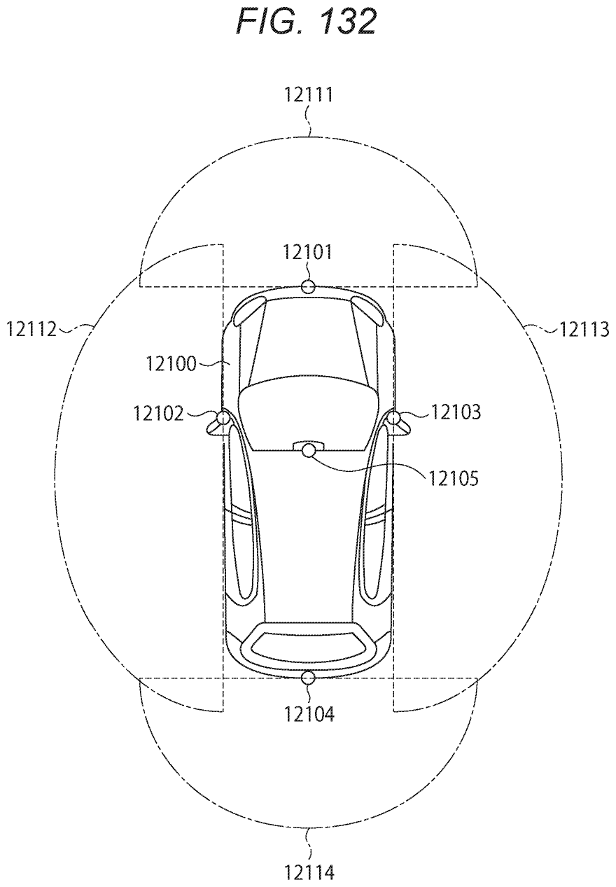

FIG. 132 is a diagram depicting an example of the installation position of the imaging section 12031.

In FIG. 132, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 132 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

The example of the vehicle control system to which the technology according to the present disclosure can be applied has been described above. The technology according to the present disclosure can be applied to the imaging section 12031 among the configurations described above. Thus, the imaging section 12031 can obtain the effects of the embodiment described above.

Note that the present technology can also employ the following configurations.

(1)

A sensor including a plurality of pixels, in which
each of the pixels includes
a semiconductor layer of a first conductivity type having a first surface,
a photoelectric conversion section that is provided in the semiconductor layer and converts light incident on the semiconductor layer into a charge,
a first channel layer of the first conductivity type that is provided on a side of the first surface in the semiconductor layer,
a first gate electrode provided above the first channel layer, and
a first capacitor layer of a second conductivity type that is provided below the first channel layer and accumulates the charge.
   (2)

The sensor according to (1), in which
the pixel further includes
a second channel layer of the first conductivity type that is provided on the side of the first surface in the semiconductor layer,
a second gate electrode provided above the second channel layer, and
a second capacitor layer of the second conductivity type that is provided below the second channel layer and accumulates the charge.
   (3)

The sensor according to (1), in which
the pixel further includes
a first amplification transistor that includes the first channel layer and the first gate electrode and is electrically connected to a first signal line, and
a threshold value of the first amplification transistor is modulated by an amount of the charge accumulated in the first capacitor layer.
   (4)

The sensor according to (3), in which
the pixel further includes
a second amplification transistor that includes the second channel layer and the second gate electrode and is electrically connected to a second signal line, and
a threshold value of the second amplification transistor is modulated by an amount of the charge accumulated in the second capacitor layer.
   (5)

The sensor according to any one of (1) to (4), in which
the pixel further includes
a first power supply diffusion layer of a second conductivity type provided on the side of the first surface in the semiconductor layer and connected to a power supply.
   (6)

The sensor according to any one of (5), in which
the pixel further includes
a second power supply diffusion layer of a second conductivity type provided on the side of the first surface in the semiconductor layer and connected to the power supply.
   (7)

The sensor according to any one of (1) to (6), in which
the pixel further includes
a charge discharge transistor that discharges a charge of the photoelectric conversion section.
   (8)

The sensor according to (4), in which
the pixel further includes
a first comparator connected to the first signal line,
a first current circuit that causes a current to flow through the first comparator,
a second comparator connected to the second signal line, and
a second current circuit that causes a current to flow through the second comparator.
   (9)

The sensor according to (4), in which
the pixel further includes
a first capacitive element that is connected to one end of the first amplification transistor and accumulates a charge from the first amplification transistor,
a first source follower circuit that is connected between the first capacitive element and the first signal line and transmits a voltage corresponding to a charge of the first capacitive element to the first signal line,
a second capacitive element that is connected to one end of the second amplification transistor and accumulates a charge from the second amplification transistor, and
a second source follower circuit that is connected between the second capacitive element and the second signal line and transmits a voltage corresponding to a charge of the second capacitive element to the second signal line.
   (10)

The sensor according to (4), in which
the first and second capacitor layers are arranged on one side and another side of the photoelectric conversion section, respectively, in plan view as viewed from an incident direction of light to the semiconductor layer, and
the first and second amplification transistors are also arranged on the one side and the another side of the photoelectric conversion section, respectively.
   (11)

The sensor according to any one of (1) to (10), in which light is incident from a second surface of the semiconductor layer opposite to the first surface.

(12)

The sensor according to (11), further including a light shielding film that is provided so as to overlap the first and second capacitor layers and does not overlap the photoelectric conversion section in plan view as viewed from an incident direction of light to the semiconductor layer.

(13)

The sensor according to (11) or (12), further including a reflecting portion that is provided so as to overlap the first and second capacitor layers in plan view as viewed from an incident direction of light to the semiconductor layer and reflects light to the photoelectric conversion section.

(14)

The sensor according to any one of (2) to (4), in which
the pixel includes
a first transfer transistor that transfers a charge from the photoelectric conversion section to the first capacitor layer, and
a second transfer transistor that transfers the charge from the photoelectric conversion section to the second capacitor layer.
   (15)

The sensor according to (4), in which
the pixel further includes
a first selection transistor connected between the first amplification transistor and the first signal line, and
a second selection transistor connected between the second amplification transistor and the second signal line.
   (16)

The sensor according to (6), in which
the pixel further includes
a first reset transistor provided between the first capacitor layer and the first power supply diffusion layer, and
a second reset transistor provided between the second capacitor layer and the second power supply diffusion layer.
   (17)

The sensor according to (4), further including:
a first semiconductor chip including the plurality of pixels; and
a second semiconductor chip including a first comparator connected to the first signal line, a first current circuit that causes a current to flow through the first comparator, a second comparator connected to the second signal line, and a second current circuit that causes a current to flow through the second comparator, in which
the first semiconductor chip and the second semiconductor chip are bonded together.
   (18)

The sensor according to (17), in which the first and second semiconductor chips are electrically connected by joining the respective first signal lines of the first and second semiconductor chips and joining the respective second signal lines of the first and second semiconductor chips.

(19)

The sensor according to any one of (1) to (18), in which the plurality of pixels includes a distance measuring pixel that measures a distance to a target by an imaging pixel that acquires an image of the target.

(20)

The sensor according to any one of (1) to (19), in which
the pixel transmits a signal voltage corresponding to a signal state in which signal charges are accumulated in the first and second capacitor layers to the first and second signal lines, and thereafter transmits a reset voltage corresponding to a reset state of the first and second capacitor layers from which the signal charges have been discharged to the first and second signal lines, and
the signal voltage and the reset voltage are subjected to correlated double sampling processing.
   (21)

The sensor according to (2), in which
the pixel further includes
a first floating diffusion region of a second conductivity type that is provided on the side of the first surface in the semiconductor layer and accumulates a charge from the first capacitor layer, and
a second floating diffusion region of a second conductivity type that is provided on the side of the first surface in the semiconductor layer and accumulates a charge from the second capacitor layer, and
the sensor further includes
a first signal line that transmits a signal corresponding to the accumulated charge of the first capacitor layer,
a second signal line that transmits a signal corresponding to the accumulated charge of the second capacitor layer,
a third signal line that transmits a signal corresponding to the accumulated charge of the first floating diffusion region, and
a fourth signal line that transmits a signal corresponding to the accumulated charge of the second floating diffusion region.
   (22)

The sensor according to (21), in which
the first floating diffusion region accumulates a charge having overflowed from the first capacitor layer, and
the second floating diffusion region accumulates a charge having overflowed from the second capacitor layer.
   (23)

The sensor according to (21), in which
the first and second capacitor layers accumulate charges from the photoelectric conversion section distributed at a first frequency, and then transfer the charges to the first and second floating diffusion regions, respectively, and
thereafter, the first and second capacitor layers accumulate charges from the photoelectric conversion section distributed at a second frequency.
   (24)

A sensor having a plurality of pixels, in which
each of the pixels includes
a photoelectric conversion section that converts incident light into a charge,
a first and a second distribution transistor that alternately distribute charges from the photoelectric conversion section and a first and a second memory section that accumulate charges distributed by the first and the second distribution transistor, respectively, and
a third and a fourth memory section that accumulate charges from the first and the second memory section, respectively.
   (25)

The sensor according to (24), further including:
a first floating diffusion region that individually or collectively accumulates the charges of the first and second memory sections;
a second floating diffusion region that individually or collectively accumulates the charges of the third and fourth memory sections;
a first amplification transistor that outputs a voltage corresponding to a charge of the first floating diffusion region to a first signal line; and
a second amplification transistor that outputs a voltage corresponding to a charge of the second floating diffusion region to a second signal line.
   (26)

The sensor according to (24), further including:
a common floating diffusion region that individually or collectively accumulates the charges of the first and second memory sections and individually or collectively accumulates the charges of the third and fourth memory sections; and
a common amplification transistor that outputs a voltage corresponding to a charge of the floating diffusion region to a signal line.
   (27)

The sensor according to (25) or (26), in which
the first and second memory sections are connected in series between the first distribution transistor and the first amplification transistor, and
the third and fourth memory sections are connected in series between the second distribution transistor and the second amplification transistor.
   (28)

The sensor according to any one of (24) to (26), in which
the first and second memory sections are connected in parallel, and
the third and fourth memory sections are connected in parallel.
   (29)

The sensor according to any one of (24) to (28), in which
the first and second memory sections transfer charges by CCD, and
the third and fourth memory sections transfer charges by CCD.
   (30)

The sensor according to (1), further including:
a first floating diffusion region of a second conductivity type that is provided on the side of the first surface in the semiconductor layer and accumulates charges from the first capacitor layer;
a first signal line that transmits a signal corresponding to the accumulated charge of the first capacitor layer; and
a third signal line that transmits a signal corresponding to the accumulated charge of the first floating diffusion region.
   (31)

The sensor according to (30), further including a source follower circuit provided between the first floating diffusion region and the third signal line.

(32)

The sensor according to (30) or (31), in which
the pixel further includes
a first transfer transistor that transfers a charge from the photoelectric conversion section to the first capacitor layer.
   (33)

The sensor according to any one of (30) to (32), in which
the pixel further includes
a first selection transistor connected between the first amplification transistor and the first signal line.
   (34)

The sensor according to any one of (30) to (33), in which
the pixel further includes
a first reset transistor provided between the first capacitor layer and the first floating diffusion region, and
a second reset transistor provided between the first floating diffusion region and a power supply.
   (35)

The sensor according to (30) or (31), in which
the pixel further includes
a first transfer transistor connected between the photoelectric conversion section and the first floating diffusion region, and an overflow transistor and a second transfer transistor connected in series between the photoelectric conversion section and the first floating diffusion region, and
a third capacitive element connected between a node between the overflow transistor and the second transfer transistor and a reference power supply.
   (36)

The sensor according to (30) or (31), in which
the pixel further includes
a first transfer transistor connected between the photoelectric conversion section and the first floating diffusion region, and an overflow transistor and a second transfer transistor provided between the photoelectric conversion section and the first floating diffusion region, and
a CCD element provided between the overflow transistor and the second transfer transistor.
   (37)

A sensor having a plurality of pixels, in which
each of the pixels includes
a photoelectric conversion section that converts incident light into a charge,
a first capacitor layer that accumulates a charge from the photoelectric conversion section,
a first charge transistor that is provided above the first capacitor layer and accumulates charges from the photoelectric conversion section to the first capacitor layer,
a first floating diffusion region that accumulates a charge from the first capacitor layer, and
a first transfer transistor provided between the first floating diffusion region and the first charge transistor.
   (38)

The sensor according to (37), further including:
a second capacitor layer that is provided between the first charge transistor and the first transfer transistor and accumulates a charge from the first capacitor layer; and
a second charge transistor that is provided above the second capacitor layer and sends a charge from the first capacitor layer to the second capacitor layer.
   (39)

The sensor according to (37) or (38), further including a second transfer transistor provided between the photoelectric conversion section and the first charge transistor.

(40)

The sensor according to any one of (1) to (39), in which the plurality of pixels is arranged in such a manner that the photoelectric conversion section is unevenly distributed to a center side of a pixel region.

(41)

A sensor that converts incident light into a charge and acquires an image according to the charge, the sensor including:
a photoelectric conversion section that accumulates a charge generated in a part of shutter periods among a plurality of shutter periods obtained by dividing an imaging period of one frame constituting the image; and
a signal processing section that estimates a signal of the entire frame from a charge in the part of the shutter period.
   (42)

The sensor according to (41), in which the signal processing section estimates that there is a signal of the entire frame on a substantially linear extension line from a signal corresponding to a charge in the part of the shutter periods.

(43)

A sensor that converts incident light into a charge and acquires an image according to the charge, the sensor including:
a photoelectric conversion section that accumulates charges generated in imaging periods of a plurality of frames constituting the image; and
a signal processing section that estimates a signal of a first frame of the plurality of frames from charges of the plurality of frames.
   (44)

The sensor according to (43), in which the signal processing section estimates an average value of signals corresponding to charges in the periods of the plurality of frames as the signal of the first frame.

Note that the present disclosure is not limited to the above-described embodiments, and various modifications can be made without departing from the gist of the present disclosure. Furthermore, the effects described in the present description are merely examples and are not limited, and other effects may be provided.

### REFERENCE SIGNS LIST

10 Pixel
PD Photodiode
AMP1, AMP2 Amplification transistor
C1, C2 Capacitor layer
VDD Power supply
VSL1, VSL2 Vertical signal line
TD Charge discharge transistor
TRS1, TRS2 Transfer transistor
C3, C4 Capacitor element
RST1, RST2 Reset transistor
SF1, SF2 Source follower circuit
SEL1, SEL2 Selection transistor
VSL1, VSL2 Vertical signal line
CS1, CS2 Current source

1. A sensor comprising a plurality of pixels, wherein
each of the pixels includes
a semiconductor layer of a first conductivity type having a first surface,
a photoelectric conversion section that is provided in the semiconductor layer and converts light incident on the semiconductor layer into a charge,
a first channel layer of the first conductivity type that is provided on a side of the first surface in the semiconductor layer,
a first gate electrode provided above the first channel layer, and
a first capacitor layer of a second conductivity type that is provided below the first channel layer and accumulates the charge.

2. The sensor according to claim 1, wherein
the pixel further includes
a second channel layer of the first conductivity type that is provided on the side of the first surface in the semiconductor layer,
a second gate electrode provided above the second channel layer, and
a second capacitor layer of the second conductivity type that is provided below the second channel layer and accumulates the charge.

3. The sensor according to claim 2, wherein
the pixel further includes
a first amplification transistor that includes the first channel layer and the first gate electrode and is electrically connected to a first signal line, and
a threshold value of the first amplification transistor is modulated by an amount of the charge accumulated in the first capacitor layer.

4. The sensor according to claim 3, wherein
the pixel further includes
a second amplification transistor that includes the second channel layer and the second gate electrode and is electrically connected to a second signal line, and
a threshold value of the second amplification transistor is modulated by an amount of the charge accumulated in the second capacitor layer.

5. The sensor according to claim 1, wherein
the pixel further includes
a first power supply diffusion layer of a second conductivity type provided on the side of the first surface in the semiconductor layer and connected to a power supply.

6. The sensor according to claim 5, wherein
the pixel further includes
a second power supply diffusion layer of a second conductivity type provided on the side of the first surface in the semiconductor layer and connected to the power supply.

7. The sensor according to claim 1, wherein
the pixel further includes
a charge discharge transistor that discharges a charge of the photoelectric conversion section.

8. The sensor according to claim 4, wherein
the pixel further includes
a first comparator connected to the first signal line,
a first current circuit that causes a current to flow through the first comparator,
a second comparator connected to the second signal line, and
a second current circuit that causes a current to flow through the second comparator.

9. The sensor according to claim 4, wherein
the pixel further includes
a first capacitive element that is connected to one end of the first amplification transistor and accumulates a charge from the first amplification transistor,
a first source follower circuit that is connected between the first capacitive element and the first signal line and transmits a voltage corresponding to a charge of the first capacitive element to the first signal line,
a second capacitive element that is connected to one end of the second amplification transistor and accumulates a charge from the second amplification transistor, and
a second source follower circuit that is connected between the second capacitive element and the second signal line and transmits a voltage corresponding to a charge of the second capacitive element to the second signal line.

10. The sensor according to claim 4, wherein
the first and second capacitor layers are arranged on one side and another side of the photoelectric conversion section, respectively, in plan view as viewed from an incident direction of light to the semiconductor layer, and
the first and second amplification transistors are also arranged on the one side and the another side of the photoelectric conversion section, respectively.

11. The sensor according to claim 1, wherein light is incident from a second surface of the semiconductor layer opposite to the first surface.

12. The sensor according to claim 11, further comprising a light shielding film that is provided so as to overlap the first and second capacitor layers and does not overlap the photoelectric conversion section in plan view as viewed from an incident direction of light to the semiconductor layer.

13. The sensor according to claim 11, further comprising a reflecting portion that is provided so as to overlap the first and second capacitor layers in plan view as viewed from an incident direction of light to the semiconductor layer and reflects light to the photoelectric conversion section.

14. The sensor according to claim 2, wherein
the pixel includes
a first transfer transistor that transfers a charge from the photoelectric conversion section to the first capacitor layer, and
a second transfer transistor that transfers the charge from the photoelectric conversion section to the second capacitor layer.

15. The sensor according to claim 4, wherein
the pixel further includes
a first selection transistor connected between the first amplification transistor and the first signal line, and
a second selection transistor connected between the second amplification transistor and the second signal line.

16. The sensor according to claim 6, wherein
the pixel further includes
a first reset transistor provided between the first capacitor layer and the first power supply diffusion layer, and
a second reset transistor provided between the second capacitor layer and the second power supply diffusion layer.

17. The sensor according to claim 4, further comprising:
a first semiconductor chip including the plurality of pixels; and
a second semiconductor chip including a first comparator connected to the first signal line, a first current circuit that causes a current to flow through the first comparator, a second comparator connected to the second signal line, and a second current circuit that causes a current to flow through the second comparator, wherein
the first semiconductor chip and the second semiconductor chip are bonded together.

18. The sensor according to claim 17, wherein the first and second semiconductor chips are electrically connected by joining the respective first signal lines of the first and second semiconductor chips and joining the respective second signal lines of the first and second semiconductor chips.

19. The sensor according to claim 1, wherein the plurality of pixels includes a distance measuring pixel that measures a distance to a target by an imaging pixel that acquires an image of the target.

20. The sensor according to claim 4, wherein
the pixel transmits a signal voltage corresponding to a signal state in which signal charges are accumulated in the first and second capacitor layers to the first and second signal lines, and thereafter transmits a reset voltage corresponding to a reset state of the first and second capacitor layers from which the signal charges have been discharged to the first and second signal lines, and
the signal voltage and the reset voltage are subjected to correlated double sampling processing.

21. The sensor according to claim 2, wherein
the pixel further includes
a first floating diffusion region of a second conductivity type that is provided on the side of the first surface in the semiconductor layer and accumulates a charge from the first capacitor layer, and
a second floating diffusion region of a second conductivity type that is provided on the side of the first surface in the semiconductor layer and accumulates a charge from the second capacitor layer, and
the sensor further comprises
a first signal line that transmits a signal corresponding to the accumulated charge of the first capacitor layer,
a second signal line that transmits a signal corresponding to the accumulated charge of the second capacitor layer,
a third signal line that transmits a signal corresponding to the accumulated charge of the first floating diffusion region, and
a fourth signal line that transmits a signal corresponding to the accumulated charge of the second floating diffusion region.

22. The sensor according to claim 21, wherein
the first floating diffusion region accumulates a charge having overflowed from the first capacitor layer, and
the second floating diffusion region accumulates a charge having overflowed from the second capacitor layer.

23. The sensor according to claim 21, wherein
the first and second capacitor layers accumulate charges from the photoelectric conversion section distributed at a first frequency, and then transfer the charges to the first and second floating diffusion regions, respectively, and
thereafter, the first and second capacitor layers accumulate charges from the photoelectric conversion section distributed at a second frequency.

24. A sensor comprising a plurality of pixels, wherein
each of the pixels includes
a photoelectric conversion section that converts incident light into a charge,
a first and a second distribution transistor that alternately distribute charges from the photoelectric conversion section and a first and a second memory section that accumulate charges distributed by the first and the second distribution transistor, respectively, and
a third and a fourth memory section that accumulate charges from the first and the second memory section, respectively.

25. The sensor according to claim 24, further comprising:
a first floating diffusion region that individually or collectively accumulates the charges of the first and second memory sections;
a second floating diffusion region that individually or collectively accumulates the charges of the third and fourth memory sections;
a first amplification transistor that outputs a voltage corresponding to a charge of the first floating diffusion region to a first signal line; and
a second amplification transistor that outputs a voltage corresponding to a charge of the second floating diffusion region to a second signal line.

26. The sensor according to claim 24, further comprising:
a common floating diffusion region that individually or collectively accumulates the charges of the first and second memory sections and individually or collectively accumulates the charges of the third and fourth memory sections; and
a common amplification transistor that outputs a voltage corresponding to a charge of the floating diffusion region to a signal line.

27. The sensor according to claim 25, wherein
the first and second memory sections are connected in series between the first distribution transistor and the first amplification transistor, and
the third and fourth memory sections are connected in series between the second distribution transistor and the second amplification transistor.

28. The sensor according to claim 24, wherein
the first and second memory sections are connected in parallel, and
the third and fourth memory sections are connected in parallel.

29. The sensor according to claim 24, wherein
the first and second memory sections transfer charges by CCD, and
the third and fourth memory sections transfer charges by CCD.

30. The sensor according to claim 1, further comprising:
a first floating diffusion region of a second conductivity type that is provided on the side of the first surface in the semiconductor layer and accumulates charges from the first capacitor layer;
a first signal line that transmits a signal corresponding to the accumulated charge of the first capacitor layer; and
a third signal line that transmits a signal corresponding to the accumulated charge of the first floating diffusion region.

31. The sensor according to claim 30, further comprising a source follower circuit provided between the first floating diffusion region and the third signal line.

32. The sensor according to claim 30, wherein
the pixel further includes
a first transfer transistor that transfers a charge from the photoelectric conversion section to the first capacitor layer.

33. The sensor according to claim 30, wherein
the pixel further includes
a first selection transistor connected between the first amplification transistor and the first signal line.

34. The sensor according to claim 30, wherein
the pixel further includes
a first reset transistor provided between the first capacitor layer and the first floating diffusion region, and
a second reset transistor provided between the first floating diffusion region and a power supply.

35. The sensor according to claim 30, wherein
the pixel further includes
a first transfer transistor connected between the photoelectric conversion section and the first floating diffusion region, and an overflow transistor and a second transfer transistor connected in series between the photoelectric conversion section and the first floating diffusion region, and
a third capacitive element connected between a node between the overflow transistor and the second transfer transistor and a reference power supply.

36. The sensor according to claim 30, wherein
the pixel further includes
a first transfer transistor connected between the photoelectric conversion section and the first floating diffusion region, and an overflow transistor and a second transfer transistor provided between the photoelectric conversion section and the first floating diffusion region, and
a CCD element provided between the overflow transistor and the second transfer transistor.

37. A sensor comprising a plurality of pixels, wherein
each of the pixels includes
a photoelectric conversion section that converts incident light into a charge,
a first capacitor layer that accumulates a charge from the photoelectric conversion section,
a first charge transistor that is provided above the first capacitor layer and accumulates charges from the photoelectric conversion section to the first capacitor layer,
a first floating diffusion region that accumulates a charge from the first capacitor layer, and
a first transfer transistor provided between the first floating diffusion region and the first charge transistor.

38. The sensor according to claim 37, further comprising:
a second capacitor layer that is provided between the first charge transistor and the first transfer transistor and accumulates a charge from the first capacitor layer; and
a second charge transistor that is provided above the second capacitor layer and sends a charge from the first capacitor layer to the second capacitor layer.

39. The sensor according to claim 37, further comprising a second transfer transistor provided between the photoelectric conversion section and the first charge transistor.

40. The sensor according to claim 1, wherein the plurality of pixels is arranged in such a manner that the photoelectric conversion section is unevenly distributed to a center side of a pixel region.

41. A sensor that converts incident light into a charge and acquires an image according to the charge, the sensor comprising:
a photoelectric conversion section that accumulates a charge generated in a part of shutter periods among a plurality of shutter periods obtained by dividing an imaging period of one frame constituting the image; and
a signal processing section that estimates a signal of the entire frame from a charge in the part of the shutter period.

42. The sensor according to claim 41, wherein the signal processing section estimates that there is a signal of the entire frame on a substantially linear extension line from a signal corresponding to a charge in the part of the shutter periods.

43. A sensor that converts incident light into a charge and acquires an image according to the charge, the sensor comprising:
a photoelectric conversion section that accumulates charges generated in imaging periods of a plurality of frames constituting the image; and
a signal processing section that estimates a signal of a first frame of the plurality of frames from charges of the plurality of frames.

44. The sensor according to claim 43, wherein the signal processing section estimates an average value of signals corresponding to charges in the periods of the plurality of frames as the signal of the first frame.
